(19) United States
(12) Patent Application Publication
(10) Pub. No.: US 2009/0097022 A1
(43) Pub. Date: Apr. 16, 2009

(54) DISCOVERY TOOL WITH INTEGRATED MICROFLUIDIC BIOMARKER OPTICAL DETECTION ARRAY DEVICE AND METHODS FOR USE

(75) Inventors: Paolin Shen, Moraga, CA (US); Li Jiang, Moraga, CA (US); Kejung Jiang, Moraga, CA (US); Zhongzhong Chen, Shanghai (CN)

Correspondence Address: BOZICEVIC, FIELD & FRANCIS LLP, 1900 UNIVERSITY AVENUE, SUITE 200, EAST PALO ALTO, CA, 94303, US

(73) Assignee: Dynamic Throughput Inc.

(21) Appl. No.: 12/191,812

(22) Filed: Aug. 14, 2008

Related U.S. Application Data
(60) Provisional application No. 60/957,984, filed on Aug. 24, 2007.

(51) Int. Cl. G01J 3/44; G01N 21/05; H01L 21/4763; H01L 21/477

(52) U.S. Cl. 356/301; 356/246; 438/667; 438/660; 257/E21.219; 257/E21.295; 257/E21.597

(57) ABSTRACT

The present disclosure relates to the fields of microchips with microfluidic optical chambers with enhanced Raman surfaces for multiplexed optical spectroscopy. Embodiments of the present invention allow for ultra small sample volume, as well as high detection speed and throughput, as compared to conventional cuvettes or devices used in optical spectroscopy. Particular embodiments relate to scientific and medical research, the diagnosis of diseases such as cancer, cardiovascular disease, diabetes, etc., and specifically to the detection of biomarkers and determination of protein activity with relevant scientific and medical applications.

### RELATED APPLICATIONS

This application claims the benefit of priority from Provisional U.S. Patent Application 60/957,984 “Integrated Microfluidic Optical Device for Sub-Micro Liter Liquid Sample Microspectroscopy,” by Shen, et al., filed on Aug. 24, 2007 (Attorney Docket No. DNMC-001PRV); Provisional U.S. Patent Application 60/797,525, “Detection of Protease and Protease Activity Using A Single Nanocrescent SERS Probe,” by Chen, et al., filed on May 3, 2006 (Attorney Docket NO. LBNL-P022WO) (International Application No.: PCT/US2007/010722, filed May 2, 2007); and Provisional U.S. Patent Application 60/______, “SERS-Based, Single Step, Real-Time Detection of Protein Kinase And/OR Phosphatase Activity,” by Chen, et al., filed on Jan. ______, 2008 (Attorney Docket NO. LBNL-P029P1), all of which are incorporated by reference herein in their entirety for all purposes noting that this application controls to the extent of any differences.

### TECHNICAL FIELD

Particular embodiments relate to scientific and medical research, the diagnosis of diseases such as cancer, cardiovascular disease, diabetes, renal disease, pulmonary diseases, infectious diseases of viral and microbial nature, as well as neurodegenerative, immunological, and metabolic diseases, etc. In particular, the detection of biomarkers and the measurement of protein and enzymatic activities, interactions, inhibition and activation with relevant scientific and medical applications are provided.

### BACKGROUND

Recent, rapid increases in the scientific understanding of molecular physiology have been driven by, among many reasons, the completion of the sequence of the human genome and the advent of both highly sensitive and massively parallel systems for detection of biologically or medically interesting analytes. In particular, such detection systems for biological analytes of interest, or biomarkers, are of growing importance in scientific research and, increasingly, for patients in clinical settings. Analytical methods that employ spectroscopic detection systems are frequently used in the detection and quantification of biomarkers, often providing information about the interaction of biomarkers with various test molecules. Such assay methods may be employed initially during the identification, characterization, and development of molecular diagnostics, and may also be employed as molecular diagnostic tests used to assay biological samples. Thus, these assay methods may be employed to measure the health status of patients or to provide information that may support medical decisions.

Raman spectroscopy is a spectroscopic technique that measures the inelastic scattering of monochromatic light (known as Raman Scattering) commonly used to interrogate molecular vibrational or rotational aspects of a sample. Typically, a laser in the range of visible, near infrared or near ultraviolet light is used to excite the sample/system. The energy of laser photons is then shifted up or down (known as the Raman effect or Raman shift), and this shift in energy (wavelength, frequency or wave number) provides information about molecular vibrational or rotational aspects of the system. The Raman effect occurs when light interacts with the electron cloud of the bonds of a molecule or a molecular complex with multiple molecules or atoms; the magnitude of deformation in the electron cloud caused by the incident light is a reflection of the polarizability of the molecule, which determines the intensity and frequency of the reflected energy and the characteristic, fingerprint-like Raman spectra.

Surface Enhanced Raman Spectroscopy (SERS) is a highly sensitive method that can enhance the signal intensity of low-probability or weak Raman spectra emitted from a small sample. SERS, in fact has been demonstrated to detect the Raman spectra of single molecules. SERS systems for the detection of biologically or medically interesting analytes typically immobilize or fix the analyte, substrate, or complex of interest onto or adjacent to a solid, usually metal or metal alloy surface, or metal complexed with other non-metal materials with Raman enhancing, dampening or tuning capabilities. This is often referred to as a SERS-active structure. Interactions between the analyte, substrate, or complex of interest and the metal surface and the metal surface derivatives, result in an increase or a modulation in the intensity and specific profiles of the Raman-scattered radiation. Accordingly, different binding events and chemical reactions, such as phosphorylation and de-phosphorylation may be detected and compared based on the characteristic, fingerprint-like Raman spectra they create.

The use of SERS in biological and medical applications has tremendous potential for directly measuring medically and scientifically interesting molecular interactions and protein and enzymatic activity. In particular, SERS may be employed to measure protein-substrate binding events and reactions, such as those involving protein-protein, protein-small molecule, small molecule-small molecule, nucleic acid-protein, and riboprotein-nucleic acid interactions, for example. The sensitivity of such applications, perhaps enabling single-molecule detection, thus offers the potential to detect very low copy-number proteins and components of lysates from rare cells. While recent advances have been made in high-throughput measurement of DNA (sequencing), RNA (gene expression technologies) and proteins (proteomics); to date, high-throughput measurement of protein activity, in particular enzyme activity, has remained technically out of reach. Such information is clearly valuable both medically and scientifically. For example, while the value is clear in knowing a patient's complete DNA sequence or the expression levels of all genes or proteins in a cell, understanding the activity of all proteins in a cell is actually more informative and represents a higher order of biological information. This is because proteomic-level information is directly tied to function and cell phenotype.

Microfluidic devices and systems of integrated microfluidics devices employ small capillaries or microchannels attached or integrated with a solid substrate to perform a variety of operations in a number of analytical, chemical and biochemical applications on a very small scale. For example, integrated microfluidic devices can first employ electrical fields to effectively separate nucleic acids, proteins or other macromolecules of interest and then use microscale detection systems for characterization and analysis of the separation products. Such microfluidic devices accomplish these operations using remarkably small reaction volumes that can be at least several orders of magnitude smaller than conventional methods. The small size of these systems allows for increased reaction rates that use less reagent volume and that take up far less laboratory, clinical, or industrial space. Microfluidic systems thus offer the potential for attractive efficiency gains, and consequently, substantial economic advantages.

Microfluidic devices are particularly well-suited to conduct analytical methods that employ spectroscopic detection systems. A variety of spectroscopic techniques can be employed in conjunction with microfluidic devices, including light scattering spectroscopy, such as Raman spectroscopy. In research or industrial settings, microfluidic devices are typically employed in biochemical or cell-based assays that use spectroscopic detection systems to quantify labeled or unlabeled molecules of interest. For example, such an assay measures the expression of green fluorescent protein in mammalian cells following treatment by a candidate small molecule or biologic drug of interest. Another example is the use of the quantitative polymer chain reaction technique (PCR) in microfluidics devices for gene amplification and analysis with intercalating fluorescence dye as the spectroscopic indicator. Other examples include, but are not limited to, enzymatic and biochemical reactions in general, chemical reactions, phase transition detections, etc.

Microfluidic devices typically employ networks of integrated microscale channels and reservoirs in which materials are transported, mixed, separated and detected, with various detectors and sensors embedded or externally arranged for quantification, as well as actuators and other accessories for manipulations of the fluidic samples. The development of sophisticated material transport systems has permitted the development of systems that are readily automatable and highly reproducible. Such operations are potentially automatable and can be incorporated into high-throughput systems with tremendous advantages for numerous industrial and research applications. Microfluidic devices often use plastics as the substrate. While polymeric materials offer advantages of easy fabrication, low cost and availability, they tend to be fluorescent. For example, when irradiating a sample with excitation light, light scatter may result in a significant background signal, particularly when the excitation pathway and emission pathway are the same. Other materials, such as glass, silicon, metal, and metal oxides may be used as well.

Analysis of biomarkers is fast becoming the preferred method for early detection of disease, patient stratification and monitoring efficacy of treatment. Rapid and highly sensitive detection of changes in a biomarker is often technically impossible, or may require a cumbersome procedure involving multiple processing steps, necessitating large sample volumes and a prolonged diagnosis/prognosis timeline. The sample from a patient is often of a limited volume and not amenable to processing or to procedures requiring multiple steps that extend the processing time. The devices of the current application provide considerable advantages that work to mitigate these problems, such that SERS spectral detection of biological and chemical samples may be performed in a real-time, microfluidic environment.

### SUMMARY

In one embodiment, the invention involves the integration of SERS substrates into microfluidics systems. The SERS substrates include various nanoscale structures such as nanopillars, nanorings, nanotriangles, nanobowties, nanospheres, nanorods, and/or nanospirrals.

In one embodiment, the invention provides a method for determining the activity of a target biomolecule using a surface enhanced Raman spectroscopy (SERS) system. The method comprises introducing a fluid sample into a microfluidic optical chamber wherein the optical chamber comprises a Raman active surface with a plurality of substrates extending therefrom. Passage of the fluid sample through the microfluidic optical chamber allows for specific binding and/or interaction between a biomolecule in the fluid sample and a plurality of said substrates. The enzymes or proteins in the fluidic sample exert an effect on the surface-immobilized biomolecule, either by cleavage or addition of chemical groups. These alteration effects can be detected by reading the Raman signal on the surface with SERS.

In one embodiment, the invention has minimal to no requirement for washing of the fluid sample. The change to the surface-bound biomolecules can be measured without significant interference from the molecules in the fluidic sample.

In some embodiments, a laser is directed at the fluid sample in the microfluidic optical chamber, wherein the interaction of the laser with the fluid sample produces a SERS signal that is specific for the interaction between the biomolecule and the substrate.

In some embodiments, the presence, quantity and/or activity of a biomolecule may be detected by recording a change in the Raman scattering spectrum of the biomolecule upon binding to the plurality of substrates.

In one embodiment, cells are lysed and the lysates are applied to target molecules on a SERS surface, without purification of enzymes from the lysates. The absence of the enzyme purification steps allows for direct and quick measurement of enzyme activity, and reduction of result variation due to sample manipulation.

In one embodiment, the labeling of target proteins with additional labels is not required.

In a further embodiment, a set of protease substrate peptides are immobilized on the surface in a microarray format, or in a linear row, or in a folded channel such as a serpentined channel, for example.

In another embodiment, Raman label molecules, metal ions, and/or nanocomposite are conjugated to the enzyme substrate to enhance the Raman signal. Organic solvent may also be added in the sample to enhance the Raman signal.

In one embodiment, a set of kinase substrate peptides are immobilized on the surface in a microarray format, or in a linear row, or a folded channel such as a serpentined channel, for example.

In one embodiment, the sample volume is 10 microliters or less, and in a preferred embodiment, the sample volume is less than 1 microliter. The concentration range required for detection may be 1 micromolar or less.

In one embodiment, the reaction dynamics and kinetics measurements may be detected in real-time, rather than in end-point fashion, as labeling methods in the art require. Multiple data points may be obtained from the reaction at a data rate of between about 1 millisecond to 1 minute per measurement, and at a time duration from between about 1 minute to 24 hours.

In a further embodiment, a washing step is not required in the real time measurement as the SERS detection is a near field optical detection method, and thus only molecular reaction events at the SERS substrate surface can be detected. Reactions taking place at roughly 100 nanometers distant from the surface will not contribute significantly to the signal. In this embodiment, the removal of noise generated from background compounds is realized by the natural or facilitated diffusion of the background compounds from the SERS substrate surface.

In another embodiment, multi-channel measurement can be performed by employing a multichannel microfluidic system. These measurements can be completed simultaneously without interfering with each other.

In one embodiment, a high speed optical scanning system can be used for scanning multiple channels in a timely manner. In a particular embodiment, the high speed optical system involves using a motorized galvo mirror to scan multiple samples.

In one embodiment, the microfluidic operation is fully automated including sample loading, sample mixing, reagent exchange, sample heating and temperature control, etc. The fluidic actuation methods include, but are not limited to, mechanical pumping, optical pumping, and thermal pumping.

In one embodiment, the liquid flow can be controlled during the optical measurement to facilitate reagent mixing, to increase diffusion of lytic reaction end products from the surface, and to prevent molecule precipitation, and so forth.

In a further embodiment, a polarized laser may be used as the excitation source, and molecular chirality may be measured with increased signal-to-noise ratio.

### BRIEF DESCRIPTION OF THE DRAWINGS

Particular embodiments are best understood from the following detailed description when read in conjunction with the accompanying drawings. It is emphasized that, according to common practice, the various features of the drawings may not necessarily be to-scale. In some cases, the dimensions of various features may be arbitrarily expanded or reduced for clarity.

FIGS. 1A-1F show an example fabrication process for a silicon based surface enhanced Raman scattering (SERS) substrate device in accordance with embodiments of the present invention.

FIGS. 2A-2F show process diagrams of printing various molecular probes on a SERS chip in accordance with embodiments of the present invention.

FIGS. 3A-3B show an example assembly process with a completed assembly of an example microfluidic molecular diagnostic device in accordance with embodiments of the present invention.

FIGS. 4A-4B show an example of use of microfabrication masks for making two-channel devices in accordance with embodiments of the present invention.

FIGS. 5A-5B show principles of protease and/or nuclease biomarker detections in an example microfluidic SERS chip in accordance with embodiments of the present invention.

FIGS. 6A-6B show principles of a phosphorylation event. Alterations in biomarkers are detected in an example microfluidic SERS chip in accordance with embodiments of the present invention.

FIGS. 7A-7B show example views of an integrated well plate and silicon microfluidic device structure in accordance with embodiments of the present invention.

FIG. 8 shows an example configuration of a fluorescence detection system for a microfluidic protease/nuclease biomarker diagnostic device in accordance with embodiments of the present invention.

FIG. 9 shows an example configuration of a Raman detection system for the microfluidic protease/nuclease biomarker diagnostic device in accordance with embodiments of the present invention.

FIG. 10 shows an example configuration of a high throughput Raman detection system for a microfluidic protease/nuclease biomarker diagnostic device in accordance with embodiments of the present invention.

FIG. 11 shows an example Raman signal enhancement of peptide probes in kinase biomarker detections in accordance with embodiments of the present invention.

FIG. 12 shows a flow diagram of an example method of fabricating a structure for a microfluidic optical device in accordance with embodiments of the present invention.

FIG. 13 shows a flow diagram of an example method of making a device for discovery of characteristics of a fluid sample in accordance with embodiments of the present invention.

FIG. 14 shows a flow diagram of an example method of using a discovery device for fluid sample analysis in accordance with embodiments of the present invention.

FIG. 15. shows a glavo mirror drawing. The motorized glavo mirror allows for the quick scan of multiple substrate coordinates.

### DETAILED DESCRIPTION

Before the methods and devices of embodiments of the present invention are described, it is to be understood that the invention is not limited to any particular embodiment described, as such may, of course, vary. It is also to be understood that the terminology used herein is with the purpose of describing particular embodiments only, and is not intended to limit the scope of the present invention which will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited. The present disclosure is controlling to the extent there is a contradiction between the present disclosure and a publication incorporated by reference.

It must be noted that as used herein and in the appended claims, the singular forms “a”, “and”, and “the” include plural referents unless the context clearly dictates otherwise. Thus, for example, reference to “a peptide” includes a plurality of such peptides and reference to “the method” includes reference to one or more methods and equivalents thereof known to those skilled in the art, and so forth.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

### DEFINITIONS

The terms “nucleic acid” and “polynucleotide” are used interchangeably herein to refer to deoxyribonucleotides or ribonucleotides, and polymers thereof, in either single- or double-stranded form. The terms generally encompass nucleic acids containing known nucleotide analogs or modified backbone residues or linkages, which are synthetic, naturally occurring, and non-naturally occurring, which have similar binding properties as the reference nucleic acid, and which are metabolized in a manner similar to the reference nucleotides. Examples of such analogs include, without limitation, phosphorothioates, phosphoramidates, methyl phosphonates, chiral-methyl phosphonates, 2-O-methyl ribonucleotides, peptide-nucleic acids (PNAs).

The term “amino acid” refers to naturally occurring and synthetic amino acids, as well as amino acid analogs and amino acid mimetics that function in a manner similar to the naturally occurring amino acids. Naturally occurring amino acids are those encoded by the genetic code, as well as those amino acids that are later modified, e.g., hydroxyproline, γ-carboxyglutamate, and O-phosphoserine. Amino acid analogs refers to compounds that have the same basic chemical structure as a naturally occurring amino acid, e.g., an α carbon that is bound to a hydrogen, a carboxyl group, an amino group, and an R group, e.g., homoserine, norleucine, methionine sulfoxide, methionine methyl sulfonium. Such analogs have modified R groups (e.g., norleucine) or modified peptide backbones, but retain the same basic chemical structure as a naturally occurring amino acid. Amino acid mimetics refers to chemical compounds that have a structure that is different from the general chemical structure of an amino acid, but that functions in a manner similar to a naturally occurring amino acid.

“Biological sample” as used herein is a sample of biological tissue or chemical fluid that is suspected of containing an analyte of interest. Samples include, for example, body fluids such as whole blood, serum, plasma, cerebrospinal fluid, urine, lymph fluids, and various external secretions of the respiratory, intestinal and genitourinary tracts such as tears, saliva, semen, milk, and the like; and other biological fluids such as cell culture suspensions, cell extracts, cell culture supernatants. Samples may also include tissue biopsies, e.g., from the lung, liver, brain, eye, tongue, colon, kidney, muscle, heart, breast, skin, pancreas, uterus, cervix, prostate, salivary gland, and the like. Samples may also be microbiopsies, small samples or even single cells extracted from patients and subsequently processed, for example, using laser capture microdisecction. A sample may be suspended or dissolved in, e.g., buffers, extractants, solvents, and the like. A sample can be from any naturally occurring organism or a recombinant organism including, e.g., viruses, prokaryotes or eukaryotes, and mammals (e.g., rodents, felines, canines, and primates). The organism may be a nondiseased organism, an organism suspected of being diseased, or a diseased organism. A mammalian subject from whom a sample is taken may have, be suspected of having, or have a disease such as, for example, cancer, autoimmune disease, or cardiovascular disease, pulmonary disease, gastrointestinal disease, musculoskeletal, disorders, central nervous system disorders, infectious disease (e.g., viral, fungal, or bacterial infection). The term biological sample also refers to research samples which have been deliberately created for the study of biological processes or discovery or screening of drug candidates. Such examples include, but are not limited to, aqueous samples that have been doped with bacteria, viruses, DNA, polypeptides, natural or recombinant proteins, metal ions, or drug candidates and their mixtures.

The terms “peptide” and “peptidic compound” are used interchangeably herein to refer to a polymeric form of amino acids of from about 10 to about 50 amino acids (may consist of at least 10 and not more than 50 amino acids), which can comprise coded and non-coded amino acids, chemically or biochemically modified or derivatized amino acids, L- or D-amino acids, peptides having modified peptide backbones, and peptides comprising amino acid analogs. The amino acid may be limited to only amino acids naturally occurring in humans. The peptidic compounds may be polymers of: (a) naturally occurring amino acid residues; (b) non-naturally occurring amino acid residues, e.g., N-substituted glycines, amino acid substitutes, etc.; or (c) both naturally occurring and non-naturally occurring amino acid residues/substitutes. In other words, the subject peptidic compounds may be peptides or peptoids. Peptoid compounds and methods for their preparation are described in WO 91/19735, the disclosure of which is hereby incorporated in its entirety by reference herein. A peptide compound of the invention may comprise or consist of 23 amino acids or from 18 to 28 amino acids or from 20 to 26 amino acids. The active amino acid sequence of the invention comprises or consists of three motifs which may be overlapping, which are: an integrin binding motif sequence, a glycosaminoglycan binding motif sequence, and a calcium-binding motif.

By “protein” is meant a sequence of amino acids for which the chain length is sufficient to produce the higher levels of tertiary and/or quaternary structure. This is to distinguish from “peptides” or other small molecular weight drugs that do not have such structure. Typically, a protein will have a molecular weight of about 15-20 kD to about 20 kD.

The terms “polypeptide,” “peptide” and “protein” are used interchangeably herein to refer to a polymer of amino acid residues. The terms apply to amino acid polymers in which one or more amino acid residue is an artificial chemical mimetic of a corresponding naturally occurring amino acid, as well as to naturally occurring amino acid polymers and non-naturally occurring amino acid polymer.

The term “substrate” when used in context of biochemistry, means a molecule upon which an enzyme acts. Enzymes catalyze chemical reactions involving substrates. A substrate binds to an enzyme's active site, and an enzyme-substrate complex is formed. The substrate is broken down into a product and is released from the active site.

The term “substrate” when used in context of material science, is used to describe the base material or surface on which processing is conducted to produce new film or layers of material such as deposited coatings, attachment of nucleic acids, peptides, sugars, and fatty acids, etc.

A “kinase” is an enzyme that catalyzes the transfer of a phosphate group (e.g., from ATP or GTP) to a target molecule such as a kinase substrate, leading to phosphorylation of the substrate.

A “kinase substrate” refers to a molecule that can be partially or completely phosphorylated by a kinase.

A “phosphatase” is an enzyme that catalyzes the removal of a phosphate group from a phosphatase substrate thereby resulting in the partial or complete dephosphorylation of that substrate.

A “phosphatase substrate” refers to a molecule that can be partially or completely dephosphorylated by a phosphate.

The terms “treatment,” “treating” and the like are used herein to refer to both therapeutic treatment and prophylactic or preventative measures. Those in need of treatment include those already with the disorder as well as those in which the disorder is to be prevented. In general, this encompasses obtaining a desired pharmacologic and/or physiologic effect, e.g., stimulation of angiogenesis. The effect may be prophylactic in terms of completely or partially preventing a disease or symptom thereof and/or may be therapeutic in terms of a partial or complete cure for a disease and/or adverse effect attributable to the disease. The terms as used herein cover any treatment of a disease in a mammal, particularly a human, and include: (a) preventing a disease or condition (e.g., preventing the loss of cartilage) from occurring in a subject who may be predisposed to the disease but has not yet been diagnosed as having it; (b) inhibiting the disease, e.g., arresting loss of cartilage; or (c) relieving the disease (e.g., enhancing the development of cartilage).

The terms “subject,” “individual,” “patient,” and “host” are used interchangeably herein and refer to any vertebrate, particularly any mammal and most particularly including human subjects, farm animals, and mammalian pets. The subject may be, but is not necessarily under the care of a health care professional such as a doctor.

“Mammal” for purposes of treatment refers to any animal classified as a mammal, including humans, domestic and farm animals, and zoo, sports, or pet animals, such as dogs, horses, cats, cows, etc. Preferably, the mammal is human.

A “disorder” is any condition that would benefit from treatment with the peptide. This includes chronic and acute disorders or diseases including those pathological conditions which predispose the mammal to the disorder in question. Non-limiting examples of disorders to be treated herein include skeletal loss or weakness and bone defects or breakage.

“Surface Enhanced Raman Spectroscopy”, or “Surface Enhanced Raman Scattering”, often abbreviated SERS, is a surface sensitive technique that results in the enhancement of Raman scattering by molecules adsorbed on rough metal surfaces. The enhancement factor can be as much as 10¹⁴-10¹⁵, which allows the technique to be sensitive enough to detect single molecules.

“Raman scattering” or “Raman effect” is the inelastic scattering of a photon. When light is scattered from an atom or molecule, most photons are elastically scattered. The scattered photons have the same energy (frequency) and wavelength as the incident photons. However, a small fraction of the scattered light is scattered by an excitation, with the scattered photons having a frequency different from, and usually lower than, the frequency of the incident photons.

### DESCRIPTION OF THE PREFERRED EMBODIMENTS

Certain embodiments of the invention include microchips with microfluidic sample flow channels, active nanostructured surfaces, optical windows, and attached molecular probe arrays for multiplexed optical detection. Advantages include ultra small sample volume, high detection speed, throughput, sensitivity, reliability and completeness over the conventional molecular diagnostic method and devices, as well as two to three orders of magnitude lower cost. This may be applied to the molecular-level disease diagnosis in laboratory and clinical environments with unprecedented sensitivity, accuracy and affordability.

Methods and devices are provided for a device for surface enhanced Raman scattering (SERS) detection from microchannels in silicon or plastic substrates. The silicon device can be formed by separately etching and machining different microstructures with appropriate masking and different protective coatings and layers, which may be individually removed prior to final etching to provide deep microstructures, and by chemical and physical surface roughening to generate unique nanostructures as SERS substrate. The device can accommodate parallel fluid streams, and allow focused laser light to illuminate the SERS substrate surface. For molding with polymeric materials, the silicon device may be replicated twice and used with polymers to obtain a desired result.

The present invention demonstrates an integrated microscale fluidic chamber with sub-micro liter volume and a nanostructured surface for SERS spectroscopy. The microscale optical chamber has one transparent surface which allows for light to be transmitted in the chamber and illuminated onto a SERS substrate surface. This also allows Raman scattering light to be transmitted out of the chamber and collected. Compared to the conventional optical chamber or cuvette used for Raman measurements, the volume of this Raman detection fluidic chamber may be smaller than 1 μL. The shorter or shallower microchannel can allow for further miniaturization of the detection module in the chip. The SERS signal can be detected by a spectrometer camera but the required volume can be more than 1000 times smaller than that used in conventional Raman spectroscopy. The microscale dimensions of the optical chamber can enable integration of multiple individual optical chambers in one chip, such that multiplexed SERS spectroscopy of 2, 3, 8, 16, 32, 48, 96, 192, 384, 768, and even 1536 samples can be accomplished using a single device which holds all the samples at once.

Accordingly, certain embodiments present high sensitivity biomolecule detection on a chip with simultaneous detection of SERS spectra. The fluidic sample flow and reaction temperature in the microscale chamber may be controlled by external electronics, and/or mechanical micro-pumps. Due to the relatively small volume of the microchip and the fluidic sample, the flow rate and heating/cooling rate can be orders of magnitude higher than bulk scale counterparts, which enable many special applications, such as on-chip PCR and fast fluidic exchange.

Particular embodiments include a monolithically fabricated nanostructured SERS substrate, also enclosed in a microfluidic chamber such that SERS spectral detection of a biological/chemical sample can be implemented in the microfluidic environment. The unique microfabrication, nanofabrication and packaging as described herein allows for the detection of SERS spectra in a simulated aqueous biological environment.

Multiple biological or enzymatic substrate extensions, such as small peptides and nucleotides may be attached on the SERS substrate in the microfluidics chamber, and may also be specific to multiple kinds of biomarkers, such as enzymes, for example, which are related to cancer, cardiovascular disease, diabetes and neurological diseases. Human and animal fluidic samples can be introduced into the microfluidic chamber and reacted with the attached probes. The chemical change of the probes can be detected by SERS spectral detection.

Conventionally, a chemical or biological sample is dropped on the SERS substrate and dried for Raman spectroscopic analysis. However, real time biological events may only occur in aqueous solutions. Particular embodiments of the present invention allow for the detection of biomolecule Raman signals in a simulated biofluidic environment for both static and dynamic biochemical reactions.

Nanostructures may be on the surface of the microfluidics channel to provide enhancement of optical signals or to anchor enzymatic substrate extensions to capture target molecules or particulates for detection. Substrate extensions, such as antibodies, aptamers, DNA or RNA oligonucleotides and longer extensions, including peptides, polysaccharides, polymers, small molecules, etc., can be chemically linked to the surfaces of the microfluidic chamber in the chip. Enzymatic substrate extensions may also be tethered to physically fabricated nanostructures to create nanobio-hybrid probes in the microfluidic chamber.

Particular embodiments as described herein have applications in, inter alia, diagnostic tests and molecular diagnostics. For example, molecular diagnostics, and in particular molecular diagnostics that detect biomarkers related to cancer, measure biomarkers including small molecule metabolites or metabolic intermediates, nucleic acids, carbohydrates, proteins, protein fragments, protein complexes and/or derivatives or combinations thereof. Chemical assays such as analytical methods that employ spectroscopic detection systems may be used in the detection and quantification of such biomarkers, and may provide information about the interaction of biomarkers with test molecules such as small molecules, enzymes, carbohydrates, nucleic acid probes, nucleic acid or protein aptamers, peptide nucleic acids, peptides, or polyclonal or monoclonal antibodies. Such assay methods may be employed initially during the identification, characterization, and development of molecular diagnostics, and may also be employed as molecular diagnostic tests used to assay biological samples and thus measure the health status of patients or to provide information that may support medical decisions.

Particular embodiments also have applications in, inter alia, molecular therapeutics. For example, identification and characterization of drug targets may involve detection and quantification of such drug targets in biological samples. Chemical assays and analytical methods that employ spectroscopic detection systems may be used to detect and quantify potential drug targets including proteins such as cell surface proteins, extracellular proteins, peptide hormones, transmembrane proteins, receptor proteins, signaling proteins, cytosolic proteins or enzymes, nuclear proteins, DNA-binding proteins, RNA molecules including messenger RNA or micro-RNAs, and/or DNA. Such assays and methods may also provide information about the interaction of drug targets with drugs such as small molecules, polyclonal or monoclonal antibodies, therapeutic proteins or therapeutic enzymes, antisense nucleic acids, small-interfering RNAs, nucleic acid or protein aptamers, peptide nucleic acids, or other drugs and potential drugs. Such assay methods may be employed initially during the identification, characterization, and development of molecular therapeutics, and may also be employed in tests to identify individual patients' responsiveness to treatment with drugs or potential drugs, and thus provide valuable information that may support medical decisions.

Silicon wafers are preferable to conventional antibody affinity binding assay substrates that can only detect concentration. Other semiconductor wafers (e.g., GaAs, InP, GaP, GaSb, InSb, InAs, CaF₂, LaAl2O3, LiGaO2, MgO, SrTiOq, YSZ and ZnO) can also be used in certain embodiments. Suitable semiconductor materials for the wafer include, but are not limited to, elements of Groups II-VI (ZnS, ZnSe, ZnTe, CdS, CdSe, CdTe, HgS, HgSe, HgTe, MgS, MgSe, MgTe, CaS, CaSe, CaTe, SrS, SrSe, SrTe, BaS, BaSe, BaTe, etc.) and III-V (GaN, GaP, GaAs, GaSb, InN, InP, InAs, InSb, etc.) and IV (Ge, Si, etc.) groups on the periodic table, and alloys or mixtures thereof. Suitable metals and metal oxides for the surface coating include, but are not limited to, Au, Ag, Co, Ni, Fe₂O₃, TiO₂, and the like. Suitable carbon nanoparticles for surface coating include, e.g., carbon nanospheres, carbon nano-onions, carbon nanotubes, and fullerene.

In particular embodiments, enzymatic activity, in addition to protein concentration may be detected. In the context of prostate tumors, for example, whereas prostate-specific antigen (PSA) concentration can now be detected, such assays do not necessarily clarify whether the antigen is active or not, and may provide a misleading measurement. An aspect of certain embodiments of the invention includes generating information regarding not only concentration, but also activity. Further, particular embodiments also include a detection system in lieu of a chip scanner.

A system for liquid sample microspectroscopy in certain embodiments may generally include a detection apparatus (e.g., instrumentation portion) coupled to a microfluidics optical device (e.g., a chip or integrated circuit (IC) portion). The detection apparatus can include a light source for sending light through a liquid sample to be characterized, and a spectrograph and/or analysis unit to analyze the light (e.g., fluorescence, absorbance, etc.), which is affected by the molecules of the sample. The microfluidic optical device can be fabricated using semiconductor processing techniques, and may be packaged to protect the semiconductor therein and to accommodate inlet/outlet ports for the liquid sample.

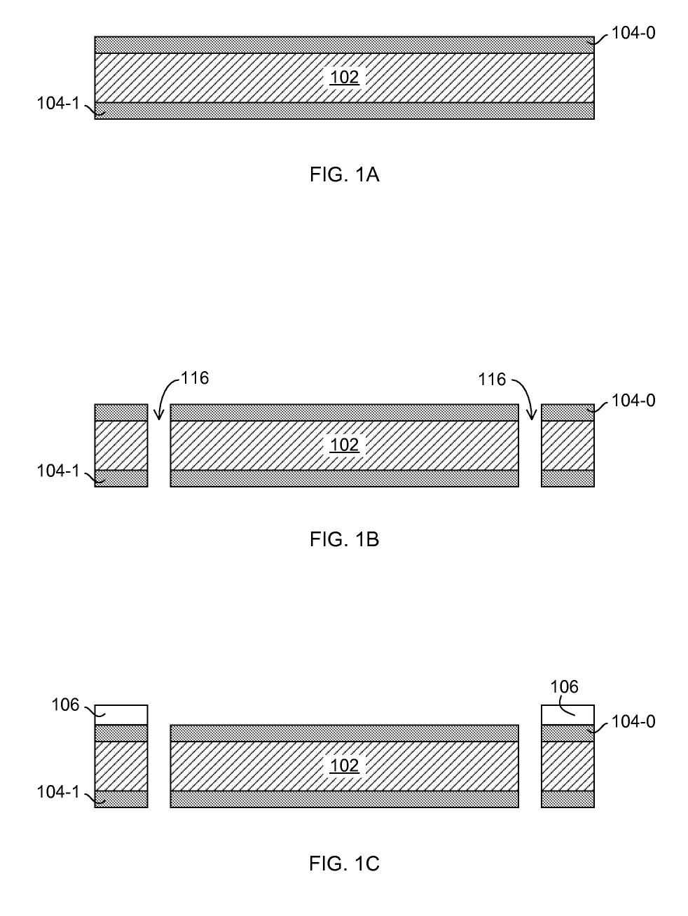

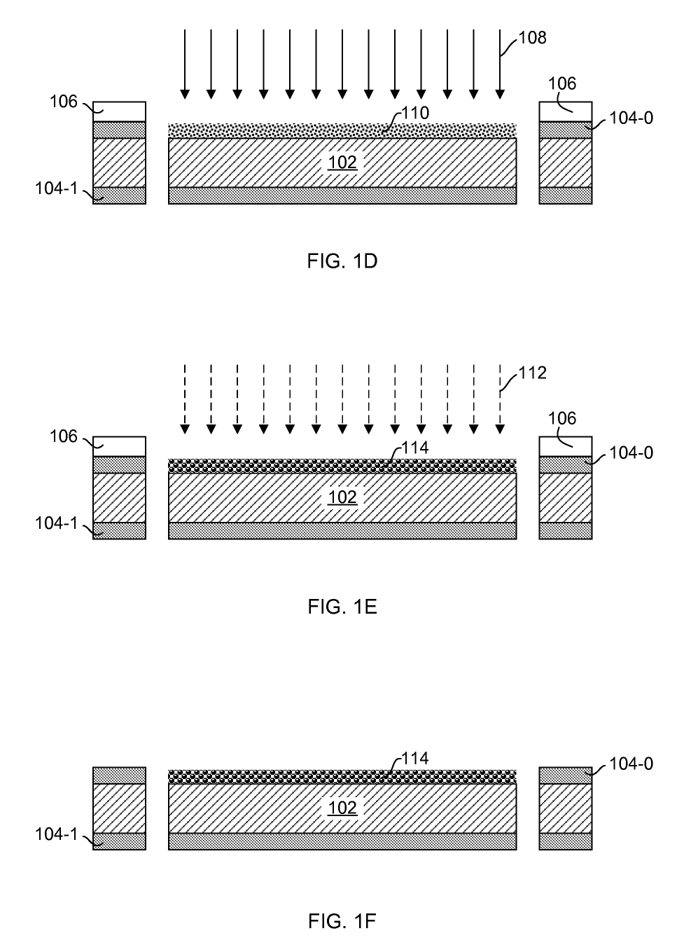

Referring now to FIGS. 1A-1F, shown is an example fabrication process for a silicon based surface enhanced Raman scattering (SERS) substrate device in accordance with embodiments of the present invention.

FIG. 1A shows thermal deposition of relatively thin layers of polycrystalline silicon 104-0 and 104-1 on top and bottom surfaces of single crystal wafer 102. For example, polycrystalline silicon layers 104-0 and 104-1 can be in a range of from about 100 nm to about 500 nm thick, such as from about 200 nm to about 400 nm, and more specifically about 300 nm.

FIG. 1B shows laser drilling or chemical etching of via-holes 116 through wafer 102 and polycrystalline silicon 104-0/104-1. The etchant may be hot potassium hydroxide and a 30 W carbon dioxide laser may be employed. In one embodiment, via-holes 116 may have a diameter/width of about 100 μm. Of course, any suitable width for these via-holes (e.g., within ranges of from about 80 μm to about 120 μm, or from about 50 μm to about 150 μm) can be utilized in particular embodiments. For example, these via-hole widths may also be configured to form a filtering function, such as by disallowing larger molecules from flowing into the microfluidic optical chamber, as will be discussed in more detail below.

FIG. 1C shows photoresist 106 applied on portions of polycrystalline silicon 104-0 to allow for photolithography patterning of to-be-etched areas.

FIG. 1D shows plasma etching 108 of polycrystalline layer 104-0 to form silicon nanostructures 110. Plasma etching 108 can include multiple steps in order to form geometric shapes or other suitable “roughness” on a surface of silicon nanostructure 110. For example, a nanopyramid array can be formed by application of a plasma treatment that includes HBr+O₂ for less than about 10 seconds. Plasma etching with HBr for from about 10 seconds to about 20 seconds can form nanopillar arrays. Oxide portions can then be removed from the pillars by plasma etching that includes, e.g., SF₆. Next, the surface can be plasma etched for from about 1 minute to about 2 minutes with HBr plasma. Such an approach can produce nanopyramids having a height of from about 50 nm to about 200 nm, and more specifically about 100 nm.

Any suitable type of nanostructures can be implemented in certain embodiments. Any shape that accommodates an enhancement of certain frequencies inherent or appearing after modification of the substrate, such as by enzymatic substrate accommodation discussed below in further detail, can be utilized. Other example nanostructure may include different geometries with enhancement properties, nano rings, nano squares, nano wires, parallel wires, nano grooves, etc., and these structures can be formed using e-beam, lithography, or any suitable processing method.

FIG. 1E shows metal deposition 112 of a thin film 114. For example, the deposited metal 114 can include gold, silver, platinum, palladium, or copper, etc., and the thickness of the thin film 114 can be from about 10 nm to about 80 nm, such as from about 20 nm to about 60 nm, and more specifically about 40 nm.

FIG. 1F shows the removal of photoresist 106 and annealing of thin metal nanoparticles 114 to form a smoothed metallic coating surface of layer 114. Suitable annealing temperatures may be from about 200-300° C., and more preferably 250° C.

A surface of layer 114 in particular embodiments may be relatively rough, or may contain other geometrical properties, e.g., of sharp edges/points to make enhanced electromagnetic fields around such edges.

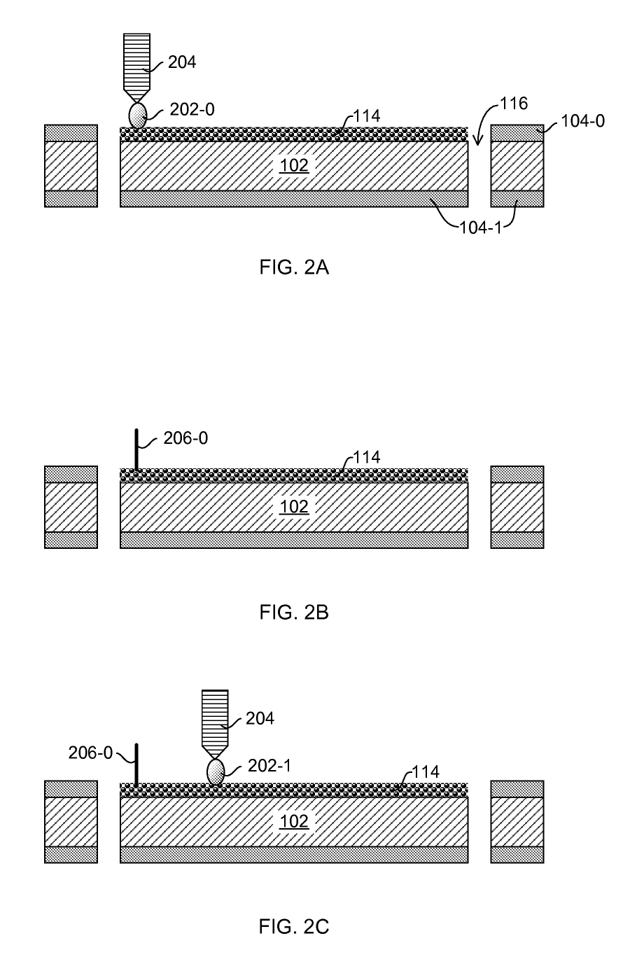

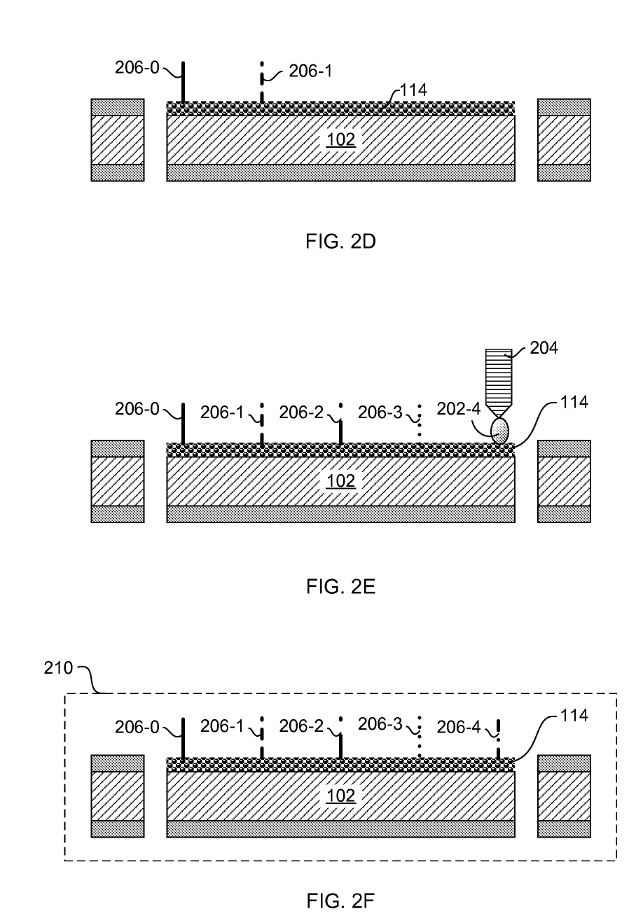

Referring now to FIGS. 2A-2F, shown are process diagrams of printing various molecular probes on a SERS chip in accordance with embodiments of the present invention. Different types of peptides or nucleotides may be dropped on a metallized nanostructure SERS substrate using microscale contact pins or injectors. Formed enzymatic substrate extensions can covalently bond to the SERS substrate surface.

FIG. 2A shows polycrystalline silicon 104-0 and 104-1 on either surface of single crystal wafer 102, with metal nanoparticles 114, and via-holes 116. Probe 204 can be positioned to apply a drop 202-0 of peptides or nucleotides. FIG. 2B shows enzymatic substrate extension 206-0 that is formed from a covalent bond between metal nanoparticles 114 and drop 202-0 of peptides/nucleotides.

FIG. 2C shows a repositioning of probe 204 with a different drop 202-1, and FIG. 2D shows a corresponding enzymatic substrate extension 206-1. Probe 204 can be repositioned a number of times to create a plurality of enzymatic substrate extensions bonded to metal nanoparticles 114.

FIG. 2E shows enzymatic substrate extensions 206-0, 206-1, 206-2, and 206-3. Probe 204 can then be repositioned to release drop 202-4 as shown. FIG. 2F shows a completed group of enzymatic substrate extensions in SERS substrate chip 210, including extension 206-4 corresponding to drop 202-4. In addition, an electromagnetic field around each enzymatic substrate extension may be altered, and metal 114 may serve as an enhancer for electromagnetic or photonic excitation of certain frequencies.

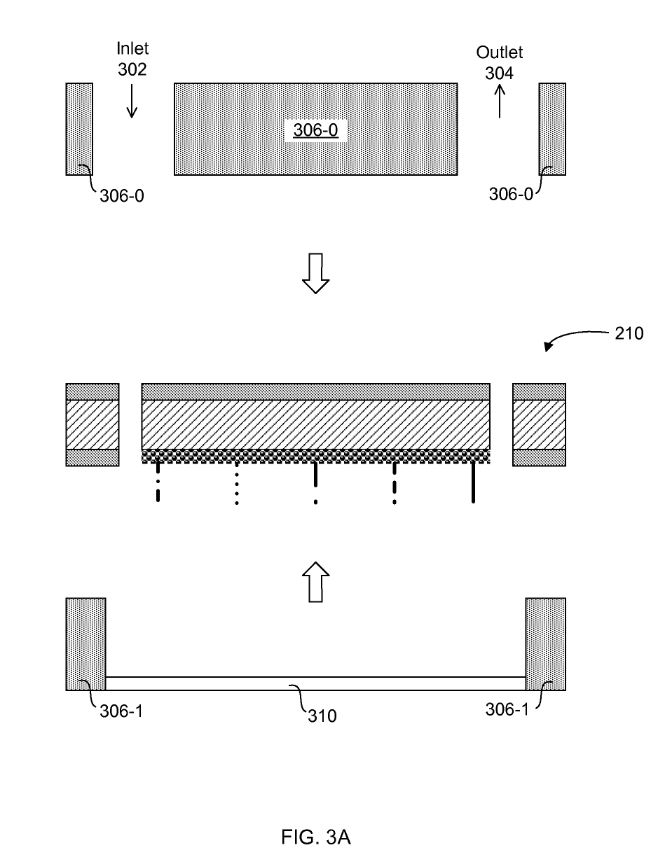

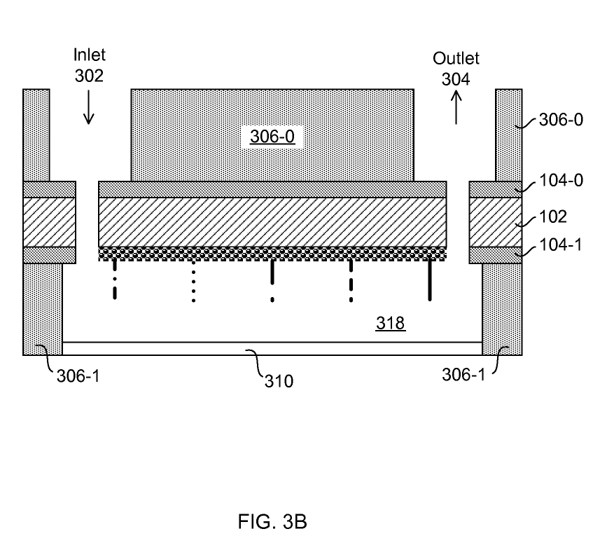

Referring now to FIGS. 3A and 3B, shown is an example assembly process with a completed assembly of an example microfluidic molecular diagnostic device in accordance with embodiments of the present invention. Generally, three separated units can be included in the assembly process. A top layer can be formed with polydimethylsiloxane (PDMS) portions 306-0 and liquid sample inlet 302 and outlet 304. Because the optical apparatus or instrumentation portion may be placed on an opposite chip side (e.g., the bottom side) relative to inlet/outlet channels (e.g., the top side), there is substantial leeway as to placing the inlet and outlet channels without interfering with the optical analysis aspects. A middle unit can include SERS substrate chip 210 with enzymatic substrate extensions. A bottom layer can include PDMS portions 306-1 and transparent window 310 to accommodate microfluidic channels therein.

In particular embodiments, transparent window 310 can generally be relatively thin such that optical loss due to absorption in the window can be minimized (e.g., to under about 10%). Typical window implementations can be in a range of about 1-3 mm thick, whereas particular embodiments can allow for such a window thickness of from about 200 μm to about 300 μm. Further, a transparent window in certain embodiments can be formed of any suitable material that is transparent to the spectrum of light (e.g., SiO₂, PDMS, cyclic olefin copolymer (COC) polymer, or any ultraviolet (UV) transparent plastics, etc.).

FIG. 3B shows an example assembled discovery tool device. Bonding the three separated units shown in FIG. 3A into the assembly of FIG. 3B can include using covalent bonding between silicon dioxide on silicon surface (e.g., polycrystalline silicon layers 104-0, 104-1) and active siloxane groups on PDMS surfaces (e.g., 306-0 and 306-1). The assembly can also include formation of microfluidic optical chamber 318 for analysis of a sample fluid received via inlet 302 and output via outlet 304.

Generally, certain embodiments can include an instrumentation portion discussed in more detail below, as well as an integrated circuit (IC) portion 210. Transparent window 310 may serve to isolate IC portion 210 from the instrumentation portion. The IC portion can include semiconductor material 102, with via-holes 116 therein to accommodate inlet 302 and outlet 304 ports as shown. Semiconductor material 102 can include any suitable semiconductor material, such as silicon (Si), germanium, silicon dioxide, gallium arsenide (GaAs), etc. Suitable semiconductor materials for the wafer include, but are not limited to, elements of Groups II-VI (ZnS, ZnSe, ZnTe, CdS, CdSe, CdTe, HgS, HgSe, HgTe, MgS, MgSe, MgTe, CaS, CaSe, CaTe, SrS, SrSe, SrTe, BaS, BaSe, BaTe, etc.) and III-V (GaN, GaP, GaAs, GaSb, InN, InP, InAs, InSb, etc.) and IV (Ge, Si, etc.) groups on the periodic table, and alloys or mixtures thereof.

In certain embodiments, mixing of a sample solution can be controlled for optical chamber 318 in order to observe real-time reactions of different chemicals and/or multiple components being pumped into the inlet at the same time. Further, inlet 302 and/or outlet 304 can be coupled to any suitable type of tubing (e.g., plastic tubing), and the diameter of the via-holes can range from about 100 μm to about 1 mm. Further, sizes of the inlet and outlet channels or ports can be varied, thus providing a filtering function by allowing for different sample volumes, molecule sizes, etc., depending upon the particular application.

In one embodiment, through-holes can provide ducts for a liquid sample flowing through microfluidic optical chamber 318, such that that liquid handling units can be installed on a side of the silicon chip other than the side where the microscale optical chambers are positioned. Without having the liquid handling units (e.g., reservoirs, connectors, tubings, or pumps) obstructing the microscale optical chamber, optical systems can have substantial exposure to chamber 318. Also, chamber 318 in certain embodiments may extend in length in a range of from about 10 μm to about 10 cm long, such as from about 500 μm to about 2 cm, and more specifically about 1 cm, to accommodate a variety of enzymatic substrate extensions 206. A depth of chamber 318 can range from about 10 μm to about 200 μm for providing a μL or sub-μL sample volume. For example, chamber 318 may hold a sample volume in a range of from about 0.10 μL to about 2 μL of fluid.

Inlet 302 and/or outlet 304 may be coupled to multiple channels, where these pathways can be routed, and may be arranged in an array format to allow easy loading via robots (e.g., to accommodate standard distances for such loading). A polymer bonding layer may also be used in the assembly, and may include any suitable layer of soft or hard plastic (e.g., PDMS, epoxy, adhesive rubber, a metal, etc.). The surface of the silicon device may also be oxidized by plasma enhanced chemical vapor deposition (PECVD), or electron beam evaporation. In addition, a liquid handling package can surround left and right edges of the structure, as well as covering the top portion along with a sealing material (e.g., epoxy, PDMS, rubber, glass, quartz, etc.).

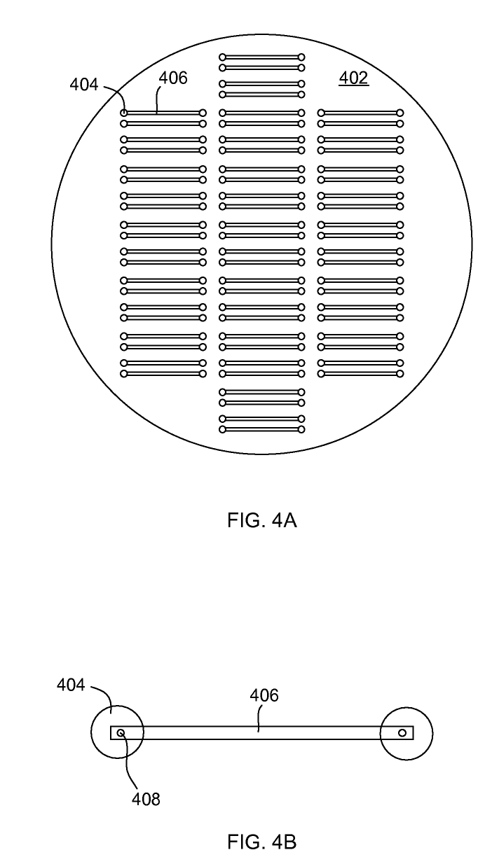

Referring now to FIG. 4A, an example top view of microfabrication masks for making two-channel devices in accordance with embodiments of the present invention is shown. In this example, a silicon wafer 402 can be defined with device masking, inlet/outlet reservoir 404 masking, microfluidic optical chamber 406 masking, and via-hole masking layers. As shown in the example close-up top view of the mask structures in FIG. 4B, via-hole masking layer 408 can be aligned with an edge of microfluidic optical chamber 406, and within the inlet/outlet reservoir 404 masking layer.

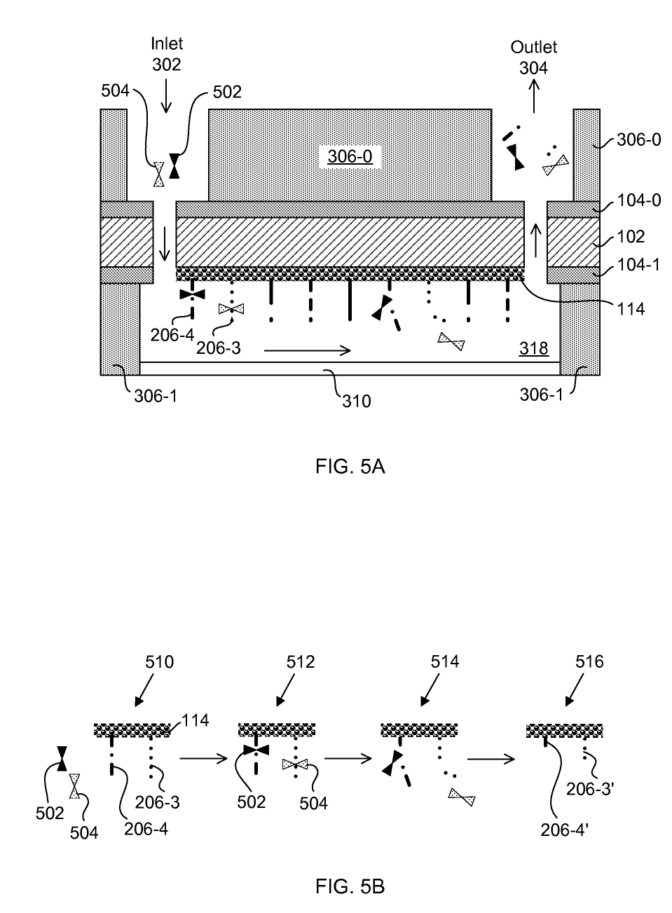

Referring now to FIGS. 5A and 5B, shown are principles of protease and nuclease biomarker detections in an exemplary microfluidic SERS chip in accordance with embodiments of the present invention. Different line types on the SERS substrate surface 114 represent exemplary peptide/nucleotide enzymatic substrate extensions, such as 206-3 and 206-4. The triangle pairs (e.g., 502 and 504) represent exemplary protease and/or nuclease biomarkers in biofluidic samples.

FIG. 5B shows decomposed procedures of biomarker enzymatic reactions, following a sequence of 510 (introduction of biomarker enzymes 502 and 504), 512 (specific binding of biomarker enzymes 502 and 504 with enzymatic substrate extensions 206-3 and 206-4), 514 (restrictive cleavage of enzymatic substrate extensions), and 516 (washing of reaction residues to leave modified enzymatic substrate extensions 206-3′ and 206-4′).

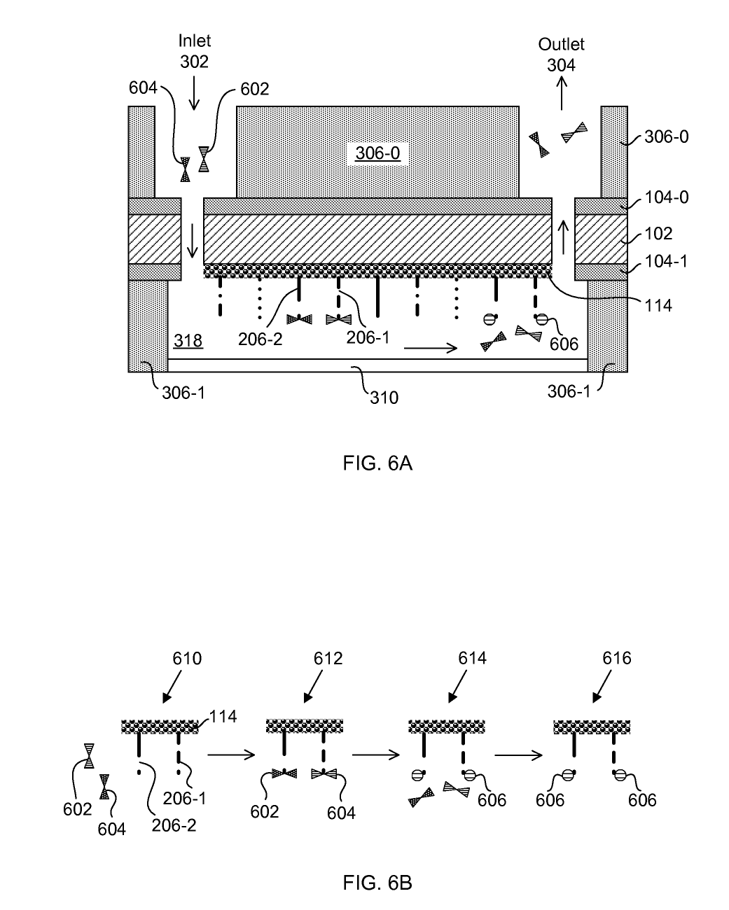

Referring now to FIGS. 6A and 6B, shown are principles of kinase biomarker detection in another exemplary microfluidic SERS chip in accordance with embodiments of the present invention. Different line types on the SERS substrate surface 114 represent exemplary enzymatic substrate extensions, such as 206-1 and 206-2. The triangle pairs (e.g., 602 and 604) represent kinase biomarkers in biofluidic samples. It is noted that the substrate extensions are not limited to enzymes, but may include various other molecules mentioned herein, such as, for example, antibodies, aptamers, DNA or RNA oligonucleotides and longer extensions, including non-enzymatic peptides, polysaccharides, polymers, small molecules, etc., all of which may be acted upon and/or modified by molecules in the incoming biofluidic sample. All such substrate extensions are capable of being chemically linked to the surfaces of the microfluidic chamber in the chip. Likewise, 602 and 604 do not necessarily represent enzymatic biomarkers in all embodiments of the invention. Rather, incoming biomarkers to be analyzed may include nucleic acids (DNA and RNA), other non-enzymatic proteins, peptides, sugars/carbohydrates, metabolites and small chemical compounds.

FIG. 6B shows decomposed procedures of exemplary biomarker enzymatic reactions, following a sequence of 610 (introduction of biomarker enzymes 602 and 604), 612 (specific binding biomarker enzymes 602 and 604 with enzymatic substrate extensions 206-1 and 206-2), 614 (phosphorylation 606 of enzymatic substrate extensions), and 616 (washing of reaction residues).

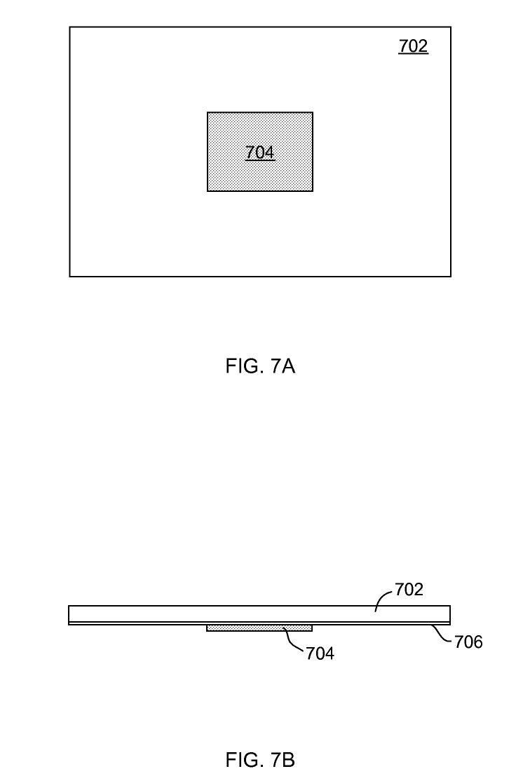

Referring now to FIG. 7A, an example top view of an integrated well plate and silicon microfluidic device structure in accordance with embodiments of the present invention is shown. FIG. 7B shows a cross-section view of the example structure of FIG. 7A. Silicon device 704 can be topped by microfluidic network layer (e.g., PDMS) 706, and well plate 702. Thus, such a multichannel version can have access holes through to the top of the structure for a microfluidic channel or routing layer. In this fashion, a microfluidics optical chip can be integrated with 96, 384, 1536, etc., micro well plates that may comply with standard micro well plate dimensions. The assembly of the microfluidics optical chip with the micro well plates may then be compatible with standard robotic liquid handling systems.

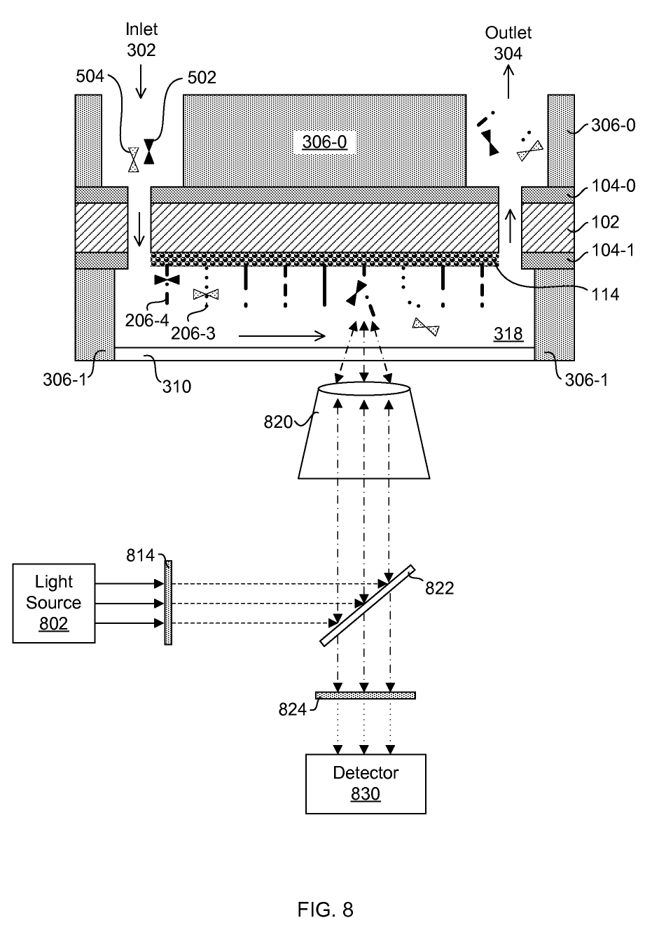

Referring now to FIG. 8, shown is an example configuration of a fluorescence detection system for a microfluidic protease/nuclease biomarker diagnostic device in accordance with embodiments of the present invention. The fluorescence enzymatic substrate extensions at a free end of each peptide/nucleotide may be removed with the proteolytic/nucleolytic reactions, and serve as optical beacons for biomarker diagnosis.

In this fashion, enzymatic substrate extensions can provide targets for enzymes in the sample solution, whereby proteases may attach in dynamic recognition followed by catalysis. Thus, in particular embodiments, a chemical reaction occurs on enzymatic substrate extensions (e.g., 206-3, 206-4, etc.). In contrast, conventional approaches typically include a DNA probe on the surface, which measures other DNA in the solution, but does not actually change the substrate, but instead provides a binding or recognition result. In certain embodiments, initial binding occurs, however, this may be followed by an observed catalysis. This is due to the fact that an enzyme in the solution for analysis effectively changes the substrate (e.g., by removing a phosphate group from the substrate, for example).

In FIG. 8, light source 802 can provide light beams that are filtered using fluorescence excitation filter 814. Filtered light beams can then be reflected by dichroic mirror 822, and passed via objective lens 820 for focusing and input to microfluidic optical chamber 318 through optically transparent window 310. Light source 802 can provide an illumination/excitation light beam that may be any suitable form of light, such as white light, laser light (e.g., visible laser, ultraviolet (UV) laser, near infrared (IR) laser, etc.), light emitting diode (LED), super luminescent diode, polarized light, halogen lamp-generated light, continuous or pulsed Xenon Lamp, Mercury light source, Argon light source, Deuterium light source, Tungsten light source and Deuterium-Tungsten-Halogen mixed light source, etc. Generally, microfluidic optical chamber 318 can be populated by molecules of a liquid or sample to be characterized, where the liquid is received via inlet port 302, and can also be discharged via outlet port 304.

Once the light is reflected in microfluidic optical chamber 318 off a selected enzymatic substrate extension, absorbance can occur via objective lens 820, pass off mirror 822, and be sent to fluorescence emission filter 824, for receipt in detector 830. Detector 830 may also include a charge coupled device (CCD) for analysis of the various wavelengths contained in the received light beam. In this fashion, one or more characteristics of the sample found in chamber 318 can be determined based on analysis of received fluorescence and/or absorbance light in detector 830. Further, and as will be discussed in more detail below, the microscale dimensions of the optical chamber presented herein can allow for integration of multiple individual optical chambers in one chip, such that the multiplexed optical spectroscopy of 2, 96, and even 384 samples, can be accomplished.

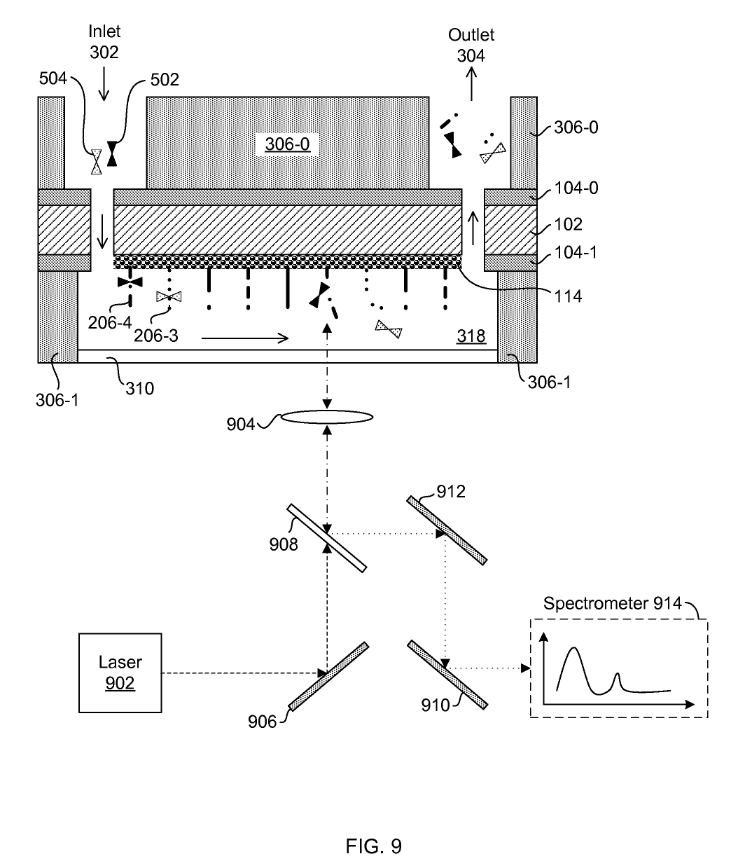

Referring now to FIG. 9, shown is an example configuration of a Raman detection system for an exemplary microfluidic protease/nuclease and/or kinase/phosphorylase biomarker diagnostic device in accordance with embodiments of the present invention. The Raman enzymatic substrate extensions at a free end of each peptide/nucleotide can be removed as a result of proteolytic/nucleolytic reactions. They may also be modified by phosphorylation/dephosphorylation reactions. As such, they may serve as optical beacons for biomarker diagnosis.

In this particular example, a point detection method allows for the detection of one enzymatic substrate extension at a time. Therefore, the microfluidic optical device and/or the associated instrumentation may be translated for detection of each enzymatic substrate extension. Further, other microfluidic optical devices (e.g., arranged as shown in FIG. 4A) can also be accessed by translating or stepping an instrumentation portion. Here, the instrumentation portion includes laser 902, which can provide a laser beam for reflection off mirror 906. Beam splitter 908 can receive reflected laser beam from mirror 906, and may provide a split beam via lens 904 for microfluidic optical chamber 318. Reflected light is returned via lens 904, passed via beam splitter 908, mirrors 912 and 910, and then provided for analysis to spectrometer 914.

In this example, spectrometer 914 shows a spectrum or range of wavelengths that show no reaction, while a different spectrum may show that there was a reaction on a particular enzymatic substrate extension. Determining whether a reaction has taken place, or determining another characteristic of the liquid sample, can include an appearance of a new peak, disappearance of an existing peak, shifting of an existing peak, merging of multiple peaks, splitting of peaks, or any alteration as can be measured by spectrometry. In this fashion, chemical alterations can be detected using optical and/or electromagnetic properties of enzymatic substrate extensions and surrounding regions. Thus, fluorescence labeling of the enzyme substrates may not be required in certain embodiments. In such embodiments, detection of chemical, electromagnetic, acoustic, or any suitable properties possessing complex information for observation is utilized.

Observable changes may be relatively subtle such that a combination of suitable nanostructures (e.g., nanopyramids on a surface of layer 114) may be added to enhance localized electromagnetic fields near the enzymatic substrate extensions (e.g., 206-3, 206-4, etc.) and thereby increase detection. In addition, the analysis in particular embodiments, while not necessarily utilizing a labeling step, may be performed in real-time. This is because the substrate may not need purification, and because time may not be needed to allow for any florescent reaction to take place.

In one example, a tumor may be metastasized in the blood, affecting kinase activity profiles as compared to normal cells. Measuring kinase activity can convey the particular group or stage of the cancer, so that it may be treated with appropriate chemo- and/or immunotherapy, for example. In cancer, certain proteases may be upregulated. They may also exhibit altered enzymatic profiles, which can be identified using particular embodiments of the claimed invention. A biopsy may be placed in solution, and mild detergents used to lyse the cells, providing μL-range volumes for analysis in a lysate. A lysate may contain numerous enzymes (e.g., proteases, nucleases, kinases, phosphatases, etc.). In order to observe different enzymes, correspondingly different enzymatic substrate extensions are placed on the microarray (see, e.g., arrangement of FIG. 4A). Distinct enzymatic substrate extensions may be situated on the microarray in order to measure multiple enzymatic reactions simultaneously. Further, particular embodiments of the claimed invention can also measure binding reactions in addition to enzymatic reactions. In such embodiments, protein:protein binding and/or interactions may be detected using surface plasmon resonance (SPR), for example.

Particular embodiments of the invention may also utilize an antibody array such that different antibodies can have different spectral signatures (e.g., peaks for different events, such as cleaving, different chemical reactions, binding and/or recognition events). Particular embodiments can analyze any plasma or fluid (e.g., saliva, urine, spinal fluid, etc.) that can be used without substantial processing or sample preparation. However, the measurement of processes in prepared samples may be improved relative to corresponding unprepared samples due to possibly interfering fluid constituents. Spectrometer 914 supports a relatively large range which allows for the isolation of measurable signals from disturbing background noise.

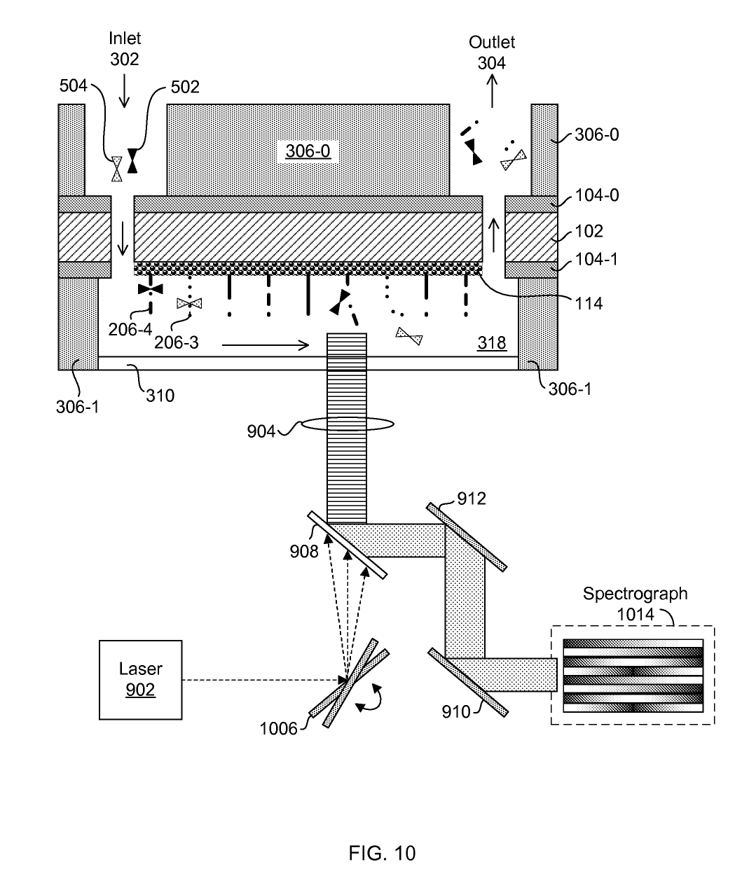

Referring now to FIG. 10, shown is an example configuration of a high throughput Raman detection system for a microfluidic protease/nuclease biomarker diagnostic device in accordance with embodiments of the present invention. A fast scanning mirror 1006 may be used in an optical path to convert a point-like laser excitation into a line-like laser excitation, such that multiple enzymatic substrate extensions on the SERS substrate surface can be excited and detected simultaneously by using a two-dimensional spectrograph 1014 to record the SERS spectra of the substrate extensions at a time.

As discussed above, particular embodiments may also include a scanning platform in order to scan different enzymatic substrate extensions one by one. A scanning mirror 1006, as well as a moving stage for one or more components of the instrumentation portion, are included; each of which may be motor-step driven for high precision. Further, certain embodiments can also include autofocusing and/or other pattern recognition for proper light beam positioning relative to enzymatic substrate extensions for analysis.

In certain embodiments, a digital light processing (“DLP”) device can be used for fine adjustments of the light incident angle with computerized feedback control. For example, such a DLP can replace scanning mirror 1006 in the example configuration shown in FIG. 10.

In addition to SERS, other spectroscopy modules and/or types of scattering may be employed, such as, for example, mechanical, electromagnetic and/or optical, etc.). For example, vibration of a molecule may change with different chemical reactions, where different frequencies of electromagnetic and acoustic ways, and IR may be used to measure rotation or tumbling as to an internal frequency for a molecule to be measured (e.g., from very low to very high, such as microwave frequencies).

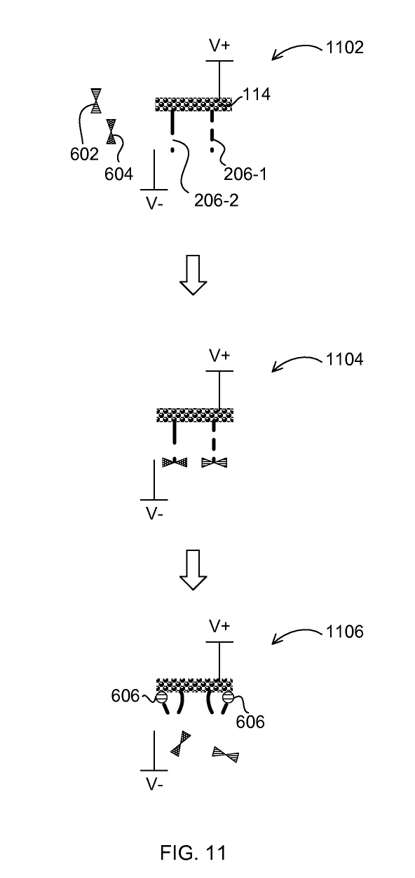

Referring now to FIG. 11, shown is an example Raman signal enhancement of peptide probes in kinase biomarker detection, in accordance with embodiments of the present invention. Because the SERS substrate in certain embodiments includes polysilicon and metal, the substrate with schematic substrate extensions is electrically conductive. For phosphorylation detection, a positive DC voltage may be applied on the SERS substrate (e.g., metal portion 114), and a DC negative voltage can be applied in an associated reaction buffer. In 1102, positively charged peptide extensions may be repelled and straightened, while the negatively charged kinase enzymes are brought closer to the peptides. In 1104, kinase enzymes can bind to the peptide due to their proximity. In 1106, after the phosphorylation reaction, the peptides carry a negatively charged phosphate group and can thus be attracted to the SERS substrate surface, while the kinase enzymes lose negative charges and may be repelled away. The relatively large conformational change of the peptide after the phosphorylation reaction will likely induce more dramatic changes in the SERS spectra for analysis.

In the detection or instrumentation module, absorbance and/or fluorescence of the supplied light can be analyzed. Typically, the fluorescence light is at higher wavelengths than the excitation light. Particular embodiments can also support photonic or multi-photonic excitation, where the excitation wavelengths are higher than the emission wavelengths, as well as epi-fluorescence applications that may utilize a separate filter.

Certain embodiments can also accommodate measurement of scattering light (e.g., X-ray small angle scattering spectroscopy). Measurements may also be taken using polarized light in circular dichrotomomy (CD) applications, which involves measurement of the response degree of angle movement of sample molecules. The fluorescence lifetimes can also be measured for Fourier transformed infrared (FTIR) applications, as well as Raman scattering, and luminescence.

SPR and nuclear magnetic resonance (NMR) spectroscopy can also be accommodated in particular embodiments. For such applications, the illumination window can receive optically pumped hyper-polarized light, and such optical pumping, as well as the optical realization, can generally occur in close proximity. NMR may typically utilize a homogeneous field for measurement because this approach usually makes use of a metal coil, where the magnetic field can be reversed, and the optical pumping can be through chamber 318, where the magnetic field is around chamber 318. In this fashion, the microfluidic optical chamber can be optically activated.

Other electromagnetic sources can also be incorporated for manipulating the material sample in the microfluidic optical chamber. For example, particular embodiments can allow for manipulation of sample physical properties using thermal, electromagnetic, optical, dielectric, inhomogeneality, etc.

Another aspect of a particular embodiment of the invention involves the relatively strong thermal conducting nature of silicon material 102, thus allowing the temperature of chamber 318 to be controlled by coupling to a thermal device (heating and/or cooling). For example, a metal block or junction can be used to measure sample material not only at room temperature, but as low as from about 0° C. up to about 300° C., or as otherwise determined by the limits of the sample material itself. Thus, if a protein is active and in order to prevent denaturing at higher temperature, a sample measurement can be performed at about 37° C. In another embodiment, thermostable enzymes (e.g., Taq polymerase, and other thermal stable enzymes isolated or engineered from thermophilic microbes) can allow higher temperature (e.g., up to about 99° C.) measurements. This type of measurement may not be possible with standard cuvettes without relatively bulky heating/cooling elements being coupled thereto.

In particular embodiments, such temperature control and an associated sensing unit can be integrated with the microfluidics optical device. For example, such an integrated temperature control and sensing unit can be a Peltier junction heater or metal line resistance heater. This approach can allow for thermocycling analysis of samples at varying temperatures, such as relatively low temperatures to prevent heat-denaturation of proteins, and higher temperatures for real-time genetic amplification using polymerase chain reactions (PCR).

In this fashion, measurement of chemical, biological, and/or physical reactions to temperature can be accommodated in chamber 318. Any temperature dependent characteristic can be isolated, such as measurement of the melting point of chemicals for assessing chemical purity. Further, some applications may also include a camera. PCR can include a cycling temperature (e.g., between about 55° C. and about 95° C.), with observance of fluorescence in the reaction (e.g., about 10 ms per frame to about one second per frame) in order to observe a real-time PCR signal. In addition, the concentration and activities of any number of different enzymes such as, but not limited to, nucleases, proteases, kinases, polymerases, glycosylases, topoisomerases, ligases, and phosphatasess can be measured using the microfluidic optical chambers of particular embodiments of the invention.

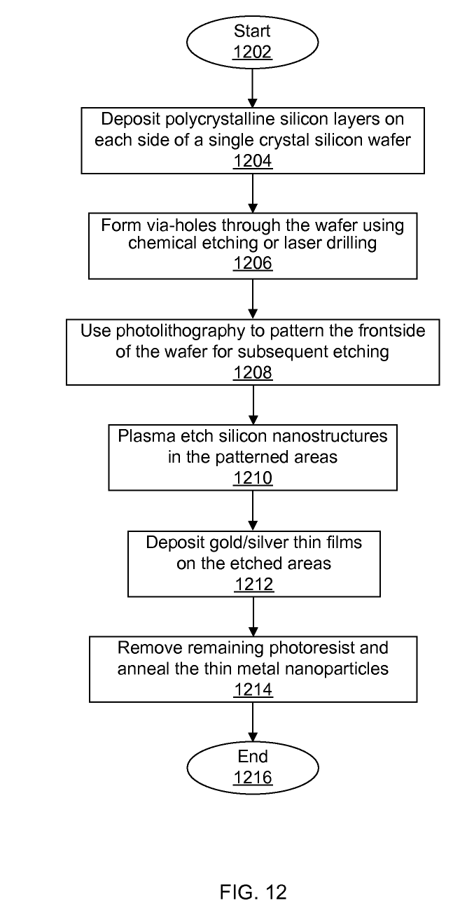

Referring now to FIG. 12, shown is a flow diagram of an example method of fabricating a structure for a microfluidic optical device in accordance with embodiments of the present invention. The flow begins (1202), and polycrystalline silicon layers may be deposited on each side of a single crystal silicon wafer (1204). Via-holes can then be formed, such as by chemical etching or laser drilling (1206). Areas for subsequent etching on the front side of the wafer can then be pattern using photolithography (1208). Silicon nanostructures can then be etched (e.g., using plasma) in the patterned areas (1210). For example, such nanostructures can provide a surface roughness of any suitable shape, such as nanopyramidal arrays. Metal (e.g., gold, silver, etc.) can then be deposited on the etched areas (1212). Remaining photoresist can be removed, and the thin metal nanoparticles can be annealed (1214), completing the flow (1216).

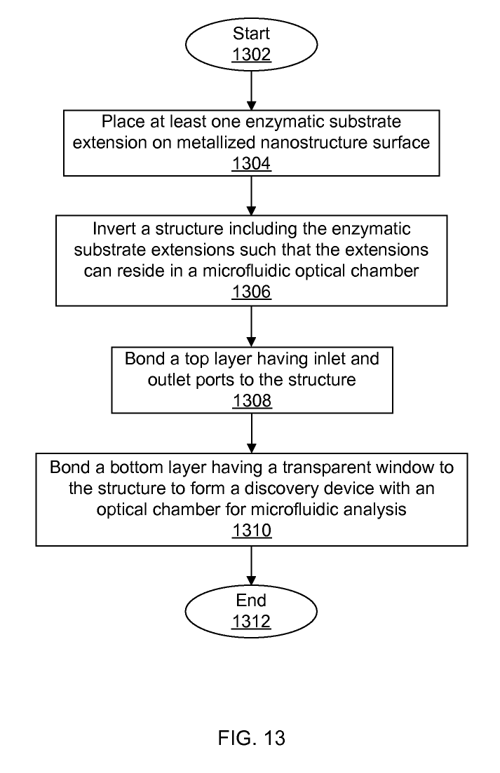

Referring now to FIG. 13, shown is a flow diagram of an example method of making a device for discovery of characteristics of a fluid sample in accordance with embodiments of the present invention. The flow begins (1302), and at least one enzymatic substrate extension may be placed on a metallized nanostructure surface (1304). A structure including the enzymatic substrate extensions can be inverted such that the extensions can reside in a microfluidic optical chamber (1306). A top layer having inlet and outlet ports can then be bonded to the structure (1308). A bottom layer having a transparent window to the structure to form a discovery device with an optical chamber for microfluidic analysis can then be bonded thereto (1310), completing the flow (1312).

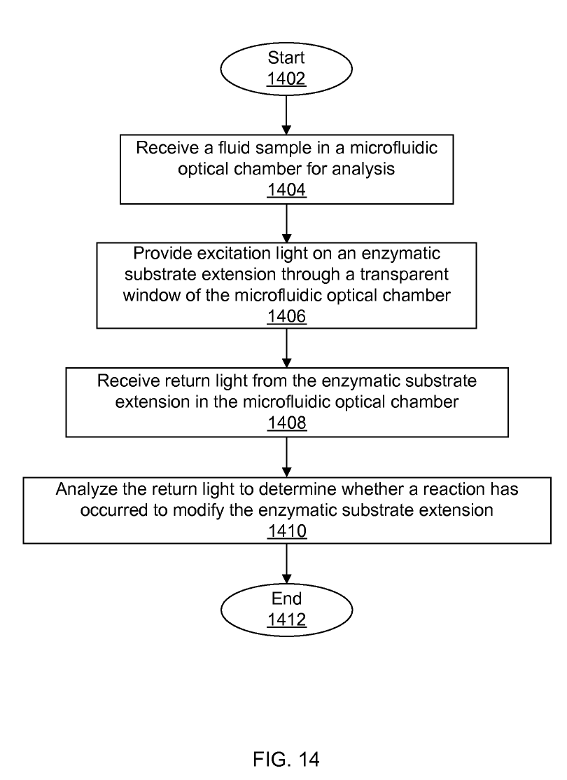

Referring now to FIG. 14, shown is a flow diagram of an example method of using a discovery device for fluid sample analysis in accordance with embodiments of the present invention. The flow begins (1402), and a fluid sample can be received in a microfluidic optical chamber for analysis (1404). Excitation light (e.g., from a laser) can then be provided on an enzymatic substrate extension through a transparent window of the microfluidic optical chamber (1406). Return light from the enzymatic substrate extension can then be received (1408). For example, lenses, mirrors, and splitters can be employed to collect such return light. The return light can then be analyzed (e.g., using a spectrometer or spectrograph) to determine whether a reaction has occurred to modify the enzymatic substrate extension (1410), completing the flow (1412).

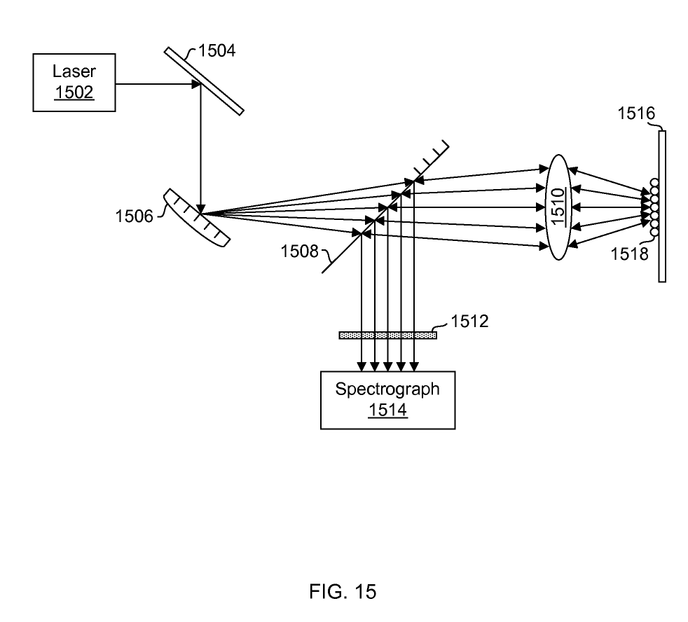

Referring now to FIG. 15, shown is a flow diagram of an example method using a high speed system in accordance with embodiments of the invention. A motorized, rotating, glavo mirror (1506) allows for a quick scan of multiple coordinates on a SERS surface. Each coordinate may be bound by a different biomolecule (1518), which may be targeted by an enzyme or other molecule of interest, for example. Excitation light, e.g., from a laser (1502) contacts a mirror (1504) and is redirected to a rotating, glavo mirror (1506). Light passes from here to a dichroic mirror (1508) and through to an objective lens (1510). A Raman filter (long pass) (1512) precedes a spectrograph (1514). Each biomolecule (1518) is tethered to a chip surface (1516).

As depicted in FIG. 15, particular embodiments involve biomolecules that are tethered to the surface. For example, such biomolecules can include nucleic acids (DNA and RNA), proteins, peptides, sugar/carbohydrates, metabolites and small chemical compounds. Further, the surface-tethered biomolecules and chemical molecules may be patterned to form a microscale array of a biochemical assay. Various biochemical libraries may also be deposited on the surface of the microfluidics optical chamber for combinatorial detection. Functional groups can include reactive groups. Functional groups can also include bifunctional crosslinkers having two reactive groups capable of forming a bond with two or more different functional targets (e.g., peptides, proteins, macromolecules, surface coating/surface, etc.). In some embodiments, the bifunctional crosslinkers are heterobifunctional crosslinkers with two different reactive groups. To allow covalent conjugation of biomolecule to the surface, suitable reactive groups include, e.g., thiol (—SH), carboxylate (COOH), carboxyl (—COOH), carbonyl, amine (NH₂), hydroxyl (—OH), aldehyde (—CHO), alcohol (ROH), ketone (R₂CO), active hydrogen, ester, sulfhydryl (SH), phosphate (—PO₃), or photoreactive moieties. Amine reactive groups can include, e.g., isothiocyanates, isocyanates, acyl azides, NHS esters, sulfonyl chlorides, aldehydes and glyoxals, epoxides and oxiranes, carbonates, arylating agents, imidoesters, carbodiimides, and anhydrides. Thiol-reactive groups include, e.g., haloacetyl and alkyl halide derivates, maleimides, aziridines, acryloyl derivatives, arylating agents, and thiol-disulfides exchange reagents. Carboxylate reactive groups include, e.g., diazoalkanes and diazoacetyl compounds, such as carbonyldiimidazoles and carbodiimides. Hydroxyl reactive groups include, e.g., epoxides and oxiranes, carbonyldiimidazole, oxidation with periodate, N,N′-disuccinimidyl carbonate or N-hydroxylsuccimidyl chloroformate, enzymatic oxidation, alkyl halogens, and isocyanates. Aldehyde and ketone reactive groups include, e.g., hydrazine derivatives for schiff base formation or reduction amination. Active hydrogen reactive groups include, e.g., diazonium derivatives for mannich condensation and iodination reactions. Photoreactive groups include, e.g., aryl azides and halogenated aryl azides, benzophenones, diazo compounds, and diazirine derivatives.

In one embodiment, a heterobifunctional crosslinker includes two different reactive groups that form a heterocyclic ring that can interact with a substrate peptide. For example, a heterobifunctional crosslinker, such as cysteine, may include an amine reactive group and a thiol-reactive group that interacts with an aldehyde on a derivatized peptide. Additional combinations of reactive groups for heterobifunctional crosslinkers include, e.g., amine and sulfhydryl reactive groups, carbonyl and sulfhydryl reactive groups, amine and photoreactive groups, sulfhydryl and photoreactive groups, carbonyl and photoreactive groups, carboxylate and photoreactive groups, and arginine and photoreactive groups.

Also in particular embodiments, the microfluidic optical chip can be automatically transported and aligned with an associated spectroscopic imaging system. For example, such transportation and/or alignment may be controlled by a computer using optimization algorithms. Also, special markers can be included on the microfluidic chips, and may be used in automated pattern recognition.

Certain embodiments can also provide electrodes integrated into the channels such that a voltage potential can be applied across the microfluidics optical chamber to form a capillary electrophoresis system. For example, DNA and protein separation using electrophoresis and isoelectrical focusing can then be realized, and the optical spectra of the biomolecules can be monitored in real-time.

Also in certain embodiments, the content within the microfluidic optical chamber can be gas phase material, rather than liquid. The optical properties of gas can be measured or monitored continuously in real-time. For example, concentration of particulates in the air can be monitored.

In certain embodiments, antibodies are tethered to the chip surface. The presence and/or concentration of the corresponding antigen in a sample may be measured. Antibodies specific for a certain cancer biomarker are tethered to the surface in embodiments directed to cancer diagnosis. Among receptor tyrosine kinases, the EGF receptor gene family including EGFR and erb B2, which are most frequently implicated in human cancers. For example, amplification of EGFR and erb B2 genes for human gastric cancers has been determined at around 3-5% and 10-20% respectively (Albino et al., (1995) Eur. J. Surg. Oncol., 21:56-60; Sato et al., (1997) Pathol. Int., 47, 179-182; Hung and Lao, (1999) Semin. Oncol., 26:51-59). Coamplification of gastrin and erb B2 has been reported for intestinal-type gastric cancers (Vidgren et al., (1999) Genes Chromosomes Cancer, 24, 24-29). Thus, an increase in levels of EGFR and erb B2 proteins accompanied by elevated levels of gastrin is indicative of intestinal cancer. The sensitivity of the instant invention facilitates detection of marginal increases in levels of these proteins. This improved sensitivity is significant as most gastric cancer is not diagnosed until the cancer has advanced to more serious stages. Moreover, measurement of the protein levels in the method of the invention requires minute sample volumes, making it suitable for testing biopsy samples. A multitude of antibodies suitable for use in the present invention are commercially available from vendors such as AbCam, BioMol, Sigma, etc.

In particular embodiments, enzymatic activity and concentration may also be detected. The substrate for an enzyme is tethered to the nanostructure of the surface and a test sample comprising the enzyme passed over/incubated with the substrate in the conditions conducive to the occurrence of the catalytic reaction. The substrates can be those for proteases, kinases, phosphatases, nucleases, methyltransferases, acetyltransferases, acyltransferases, transaminases, glycosyltransferases, and the like.

The substrates typically range in length from at least about four residues to up to about 10, 30, 50, 200 or 500 residues. Thus, the substrate for a protease is about four amino acids, and may be up to about 50, 200 or 500 amino acids. Such a substrate may have one or more recognition sequences recognized by the enzyme. Such a substrate may additionally be comprised of non-naturally occurring amino acid, nucleotide, and/or sugar residues. In addition, such a substrate may be modified by enzyme or chemical processes to add or remove functional groups.

### Detection of Protease Activity

In particular embodiments, the present invention is used to detect protease activity. Proteases are required not only for maintenance of normal cellular functions but are often central to pathogenesis of a variety of human diseases. Parasitic, fungal, viral infections, cancer, inflammatory, respiratory, cardiovascular, and neurodegenerative diseases require proteolytic activity for progression. Detection of protease concentration and/or activity is valuable as a diagnostic/prognostic marker for the presence or likelihood of the disease. Further, detection of inhibition of protease activity is useful in screening for protease inhibitors for treatment of a number of pathologies.

A “protease” that can be detected and/or quantitated according to the invention is an enzyme that typically hydrolyzes a peptide bond between a pair of amino acids in a protein/peptide, producing a shorter protein/peptide. This activity also referred to as proteolysis. Proteolysis of the protein/peptide substrate is detectable by changes in spectrum obtained by SERS, electromagnetic resonance measurement or acoustic measurement. Proteases are typically defined by reference to the nucleophile in the catalytic center of the enzyme. The most common nucleophiles arise from the side chains of serine, aspartic acid and cysteine. Accordingly, proteases are classified into protease families such as serine proteases (Paetzel et al. (1997) Trends Biochem. Sci. 22:28-31), aspartyl proteases (Spinelli et al. (1991) Biochemie 73: 1391-1396), and cysteine proteases (Altschuh et al. (1994) Prot. Eng. 7:769-75, 1994). Metalloproteases usually contain a zinc catalytic metal ion at the catalytic center (Klimpel et al. (1994) Mol. Microbiol. 13: 1093-1100).

A “protease recognition site” is a sequence of amino acids in a peptide or protein that contain a pair of amino acids that are hydrolyzed by a particular protease. The specific sequence of amino acids in the protease recognition site typically depends on the catalytic mechanism of the protease, which is defined by the nature of the functional group at the protease's active site. Thus, a protease such as trypsin hydrolyzes peptide bonds whose carbonyl function is donated by either a lysine or arginine residue, regardless of the length or amino acid sequence of the peptide/protein. Other proteases have a higher specificity, e.g., Factor Xa recognizes the sequence Ile-Glu-Gly-Arg and hydrolyses peptide bonds on the C-terminal side of the Arg.

Various preferred protease recognition site include, but are not limited to protease recognition sites for proteases from the serine protease family, or from metallopproteases, or from cysteine proteases, and/or the aspartic acid protease family, and/or the glutamic acid protease family.

Protease recognition sites are well known to those of skill in the art. Recognition sites have been identified for virtually all known proteases. Thus, for example, recognition sites (peptide substrates) for caspases are described by Earnshaw et al. (1999) Annu. Rev. Biochem. 68: 383-424, which is incorporated herein by reference.

In certain embodiments, substrates for kinases or phosphatases are attached to the nanostructure surface of the device. The attachment is achieved via contact pins, injectors or covalent bonds. Different kinase or phosphatase substrates can be localized at specific locations on the surface, thereby providing an array for the detection of one or more kinases and/or phosphatases and/or the quantitation of the activity of one or more kinases and/or phosphatases. It will be recognized that while the apparatus, methods and compositions are described with respect to detecting phosphorylation of a substrate, these apparatus, methods and compositions are also useful in detecting dephosphorylation of a substrate.

### Kinase/Phosphatase Activity Detection

Phosphorylation is a common posttranslational modification of proteins and plays a key role on protein structure and function and in all aspects of cell physiology. Protein kinases contain well conserved motifs and constitute the largest family of proteins in the human genome. Mutations of protein kinases are involved in carcinogenesis and several other pathological conditions. Phosphorylations of other biomolecules also play a critical role in the physiology and pathology of cells. Lipid kinases such as the phosphoinositide-3 kinase family members are key modulators of the cellular response to growth factors, hormones, and neurotransmitters and are involved in cancer. Nucleotide and nucleoside kinases regulate the intracellular levels of phosphate donors and nucleic acid precursors and are involved in the cellular response to injury and ischemia. Sugar kinases regulate the rates of sugar metabolism, energy generation, and transcription activation and are involved in the process of cellular transformation and apoptosis. Thus detecting and/or measuring kinase activity is useful in detecting changes in cell/tissue homeostasis, physiology, diagnosing disease conditions and the like.

Any molecule that can be phosphorylated by a kinase and/or dephosphorylated by a phosphatase can be used as a kinase/phosphatase substrate in the apparatus, methods and compositions described herein. These molecules include proteins, peptides, sugars (e.g., hexose, glucose, fructose etc.), nucleic acids, acetate, butyrate, lipids, ceramide and the like. Table 1 provides an exemplary list of known kinases and their Enzyme Commission numbers (EC numbers), which can be detected by employing the methods of the invention. The name of the kinase usually identifies the substrate the enzyme acts upon. It is well known that most substrates that are modified by phosphorylation can be dephosphorylated by a phosphatase. Thus, a surface on which kinase substrates are attached can be used in a phosphatase assay by first modifying the substrates by phosphorylating them.

TABLE 1
Illustrative kinases and corresponding Enzyme Commission (EC)
Numbers

| E.C. No. | Kinase | E.C.No. | Kinase |
|---|---|---|---|
| 2.7.1.32 | Choline kinase | 2.7.1.90 | Diphosphate fructose- |
| | | | 6-phosphate 1- |
| | | | phosphotransferase |
| 2.7.1.37 | Phosphorylase kinase | 2.7.1.91 | Sphinganine kinase |
| 2.7.1.39 | Homoserine kinase | 2.7.1.107 | Diacylglycerol kinase |
| 2.7.1.67 | 1-phosphatidylinositol 4- | 2.7.1.138 | Ceramide kinase |
| | kinase | | |
| 2.7.1.72 | Streptomycin 6-kinase | 2.7.1.2 | Glucokinase |
| 2.7.1.82 | Ethanolamine kinase | 2.7.1.3 | Ketohexokinase |
| 2.7.1.87 | Streptomycin 3″-kinase | 2.7.1.4 | Fructokinase |
| 2.7.1.95 | Kanamycin kinase | 2.7.1.11 | 6-phosphofructokinase |
| 2.7.1.100 | 5-methylthioribose | 2.7.1.15 | Ribokinase |
| | kinase | | |
| 2.7.1.103 | Viomycin kinase | 2.7.1.20 | Adenosine kinase |
| 2.7.1.109 | [Hydroxymethylglutaryl- | 2.7.1.35 | Pyridoxal kinase |
| | CoA reductase | | |
| | (NADPH2)] kinase | | |
| 2.7.1.112 | Protein-tyrosine kinase | 2.7.1.45 | 2-dehydfo-3- |
| | | | deoxygluconokinase |
| 2.7.1.116 | [Isocitrate | 2.7.1.49 | Hydroxymethyl- |
| | dehydrogenase | | pyrimidine |
| | (NADP+)] kinase | | kinase |
| 2.7.1.117 | [Myosin light-chain] | 2.7.1.50 | Hydroxyethylthiazole |
| | kinase | | kinase |
| 2.7.1.119 | Hygromycin-B kinase | 2.7.1.56 | 1-phosphofructokinase |
| 2.7.1.123 | Calcium/calmodulin | 2.7.1.73 | Inosine kinase |
| | dependent protein kinase | | |
| 2.7.1.125 | Rhodopsin kinase | 2.7.1.92 | 5-dehydro-2- |
| | | | deoxygluconokinase |
| 2.7.1.126 | [Beta-ad renergic- | 2.7.1.144 | Tagatose-6-phosphate |
| | receptor] kinase | | kinase |
| 2.7.1.129 | [Myosin heavy-chain] | 2.7.1.146 | ADP-dependent |
| | kinase | | phosphofructokinase |
| 2.7.1.135 | [Tau protein] kinase | 2.7.1.147 | ADP-dependent |
| | | | glucokinase |
| 2.7.1.136 | Macrolide 2′-kinase | 2.7.4.7 | Phosphomethyl- |
| | | | pyrimidine |
| | | | kinase |
| 2.7.1.137 | 1-phosphatidylinositol 3- | 2.7.6.2 | Thiamin pyrophospho- |
| | kinase | | kinase |
| 2.7.1.141 | [RNA-polymerase]- | 2.7.1.31 | Glycerate kinase |
| | subunit kinase | | |
| 2.7.1.153 | Phosphatidylinositol- | 2.7.4.6 | Nucleoside- |
| | 4,5-bisphosphate 3- | | diphosphate |
| | kinase | | kinase |
| 2.7.1.154 | Phosphatidylinositol-4- | 2.7.6.3 | 2-amino-4-hydroxy-6- |
| | phosphate 3-kinase | | hydroxymethyldi- |
| | | | hydropteridine |
| | | | pyrophosphokinase |
| 2.7.1.68 | 1-phosphatidylinositol- | 2.7.3.1 | Guanidoacetate kinase |
| | 4-phosphate 5-kinase | | |
| 2.7.1.127 | ID-myo-inositol- | 2.7.3.2 | Creatine kinase |
| | trisphosphate 3-kinase | | |
| 2.7.1.140 | Inositol- | 2.7.3.3 | Arginine kinase |
| | tetrakisphosphate 5- | | |
| | kinase | | |
| 2.7.1.149 | 1-phosphatidylinositol 5- | 2.7.3.5 | Lombricine kinase |
| | phosphate 4-kinase | | |
| 2.7.1.150 | 1-phosphatidylinositol 3- | 2.7.1.37 | Protein kinase |
| | phosphate 5-kinase | | (Histidine |
| | | | kinase) |
| 2.7.1.151 | Inositol-polyphosphate | 2.7.1.99 | [Pyruvate |
| | multikinase | | dehydrogenase(Kpo- |
| | | | amide)]kinase |
| 2.7.4.21 | Inositol- | 2.7.1.115 | [3-methyl-2-oxobutan- |
| | hexakisphosphate kinase | | oate dehydrogenase |
| | | | (lipoamide)] |
| | | | kinase |
| 2.7.1.134 | Inositol- | 2.7.1.1 | Hexokinase |
| | tetrakisphosphate 1- | | |
| | kinase | | |
| 2.7.9.1 | Pyravate, phosphate | 2.7.1.2 | Glucokinase |
| | dikinase | | |
| 2.7.9.2 | Pyravate, water dikinase | 2.7.1.4 | Fructokinase |
| 2.7.1.12 | Gluconokinase | 2.7.1.5 | Rhamnulokinase |
| 2.7.1.19 | Phosphoribulokinase | 2.7.1.7 | Mannokinase |
| 2.7.1.21 | Thymidine kinase | 2.7.1.12 | Gluconokinase |
| 2.7.1.22 | Ribosylnicotinamide | 2.7.1.16 | L-ribulokinase |
| | kinase | | |
| 2.7.1.24 | Dephospho-CoA kinase | 2.7.1.17 | Xylulokinase |
| 2.7.1.25 | Adenylylsulfate kinase | 2.7.1.27 | Erythritol kinase |
| 2.7.1.33 | Pantothenate kinase | 2.7.1.30 | Glycerol kinase |
| 2.7.1.37 | Protein kinase (bacterial) | 2.7.1.33 | Pantothenate kinase |
| 2.7.1.48 | Uridine kinase | 2.7.1.47 | D-ribulokinase |
| 2.7.1.71 | Shikimate kinase | 2.7.1.51 | L-fuculokinase |
| 2.7.1.74 | Deoxycytidine kinase | 2.7.1.53 | L-xylulokinase |
| 2.7.1.76 | Deoxyadenosine kinase | 2.7.1.55 | Allose kinase |
| 2.7.1.78 | Polynucleotide 5′- | 2.7.1.58 | 2-dehydro-3- |
| | hydroxylkinase | | deoxygalactonokinase |
| 2.7.1.105 | 6-phosphofructo-2- | 2.7.1.59 | N-acetylglucosamine |
| | kinase 2.7.1.113 | | kinase |
| | Deoxyguanosine kinase | | |
| 2.7.1.130 | Tetraacyldisaccharide 4′- | 2.7.1.60 | N-acylmannosamine |
| | kinase | | kinase |
| 2.7.1.145 | Deoxynucleoside kinase | 2.7.1.63 | Polyphosphate-glucose |
| | 2.7.1.156 | | phosphotransferase |
| | Adenosylcobinamide | | |
| | kinase | | |
| 2.7.4.1 | Polyphosphate kinase | 2.7.1.85 | Beta-glucoside kinase |
| | 2.7.4.2 | | |
| | Phosphomevalonate | | |
| | kinase | | |
| 2.7.4.3 | Adenylate kinase | 2.7.2.1 | Acetate kinase |
| 2.7.4.4 | Nucleoside-phosphate | 2.7.2.7 | Butyrate kinase |
| | kinase | | |
| 2.7.4.8 | Guanylate kinase | 2.7.2.14 | Branched-ehain-fatty- |
| | | | acid kinase |
| 2.7.4.9 | Thymidylate kinase | 2.7.2. | Propionate kinase |
| 2.7.4.10 | Nucleoside-triphosphate- | 2.7.1.40 | Pyravate kinase |
| | adenylate kinase | | |
| 2.7.4.13 | (Deoxy)nucleoside- | 2.7.1.36 | Mevalonate kinase |
| | phosphate kinase | | |
| 2.7.4.14 | Cytidylate kinase | 2.7.1.39 | Homoserine kinase |
| 2.7.4. | Uridylate kinase | 2.7.1.46 | L-arabinokinase |
| 2.7.1.37 | Protein kinase (HPr | 2.7.1.52 | Fucokinase |
| | kinase/phosphatase) | | |
| 4.1.1.32 | Phosphoenolpyruvate | 2.7.1.71 | Shikimate kinase |
| | carboxykinase (GTP) | | |
| 4.1.1.49 | Phosphoenolpyruvate | 2.7.1.148 | 4-(cytidine 5′- |
| | carboxykinase (ATP) | | diphospho)-2- |
| | | | Cmethyl-D-erythritol |
| | | | kinase |
| 2.7.2.3 | Phosphoglycerate kinase | 2.7.4.2 | Phosphoraevalonate |
| | | | kinase |

The substrate and/or the substrate consensus sequence for a majority of kinases and phosphatases are known. Short synthetic peptides based on consensus motifs are typically excellent substrates for kinases and phosphatases. Table 2 summarizes some of the known data about specific motifs for various well-studied protein kinases, along with examples of known phosphorylation sites in specific proteins, which can be detected by employing the methods of the invention. A more extensive list is present in Pearson and Kemp (1991) Meth. Enzymol., 200:68-82, which is incorporated herein by reference.

TABLE 2

Recognition motifs and substrate sequences for some known kinases are
listed. The amino acid phosphorylated by the corresponding kinase is
underlined. Slash (/) indicates amino acids that can functionally sub-
stitute each other. Amino acids not contributing to the substrate
recognition sequence are indicated by “X”.

| | Recognition | | |
|---|---|---|---|
| Kinase | Motif(s) | Phosphorylation Sites | Protein substrate |
| cAMP- | R-X-S/T | Y₇LRRASLAQLT | pyruvate kinase |
| dependent | (SEQ ID NO:1) | (SEQ ID NO: 3) | |
| Protein Kinase | R-R/K-X-S/T | F₁RRLSIST | phosphorylase kinase |
| (PKA, cAPK) | (SEQ ID NO: 2) | (SEQ ID NO: 4) | α-chain |
| | | A₂₉GARRKASGPP | histone HI, bovine |
| | | (SEQ ID NO: 5) | |
| Casein Kinase I | S(P)-X-X-S/T | R₄TLS(P)VSSLPGL | glycogen synthase, |
| (CKI, CK-1) | (SEQ ID NO: 6) | (SEQ ID NO: 7) | |
| | | D₄₃IGS(P)ES(P)TEDQ | rabbit muscle (αsi- |
| | | (SEQ ID NO: 8) | casein |
| Casein Kinase n | S/T-X-X-E | A₇₂DSESEDEED | PKA regulatory |
| (CKII, CK-2) | (SEQ ID NO: 9) | (SEQ ID NO: 10) | subunit, R₁₁ |
| | | L₃₇ESEEEGVPST | p34^{cdc2}, human |
| | | (SEQ ID NO: 11) | |
| | | E₂₆DNSEDEISNL | acetyl-CoA carboxylase |
| | | (SEQ ED NO: 12) | |
| Glycogen | S-X-X-X-S(P) | S₆₄₁VPPSPSLS(P) | glycogen synthase, |
| Synthase Kinase | (SEQ ID NO: 13) | (SEQ ID NO: 14) | human (site 3b) |
| 3 (GSK-3) | | S₆₄₁VPPS (P)PSLS(P) | glycogen synthase, |
| | | (SEQ ID NO: 15) | human (site 3a) |
| Cdc2 Protein | S/T-P-X-R/K | P₁₃AKUPVK | histone HI, calf thymus |
| Kinase; CDK2- | (SEQ ID NO: 16) | (SEQ ID NO: 17) | |
| cyclin A | | H₁₂₂STPPKKKRK | large T antigen |
| | | (SEQ ED NO: 18) | |
| Calmodulin- | R-X-X-S/T R-X- | N₂YLRRRLSDSN | synapsin (site 1) |
| dependent | X-S/T-V | (SEQ ID NO: 19) | |
| Protein Kinase II | | K₁₉₁MARVFSVLR | calcineurin |
| (CaMKH) | | (SEQ ID NO: 20) | |
| Mitogen- | P-X-S/T-P | P₂₄4LSP | c-Jun |
| activated Protein | (SEQ ID NO: 21) | (SEQ ID NO: 23) | |
| Kinase | X-X-S/T-P | P₉₂SSP | cyclin B |
| (Extracellular | (SEQ ID NO: 22) | (SEQ ED NO: 24) | |
| Signal-regulated | | V₄₂oLSP | Elk-1 |
| Kinase) (MAPK, | | (SEQ ID NO: 25) | |
| Erk) | | | |
| Abl Tyrosine | I/V/L-Y-X-X-P/F | | |
| Kinase | (SEQ ED NO: 26) | | |

Many kinase substrates are commercially available from various vendors such as Sigma, BioMol International, Bio-Rad, etc. Preferred kinase substrates include but are not limited to substrates for histidine, serine, threonine, and tyrosine kinases and/or the corresponding phosphatases. Multiple substrates for these kinases are well known in the art. In addition, methods are known for identification of substrates. For example, the program PREDIKIN is used to predict substrates for serine/threonine protein kinases based on the primary sequence of the kinase catalytic domain. Methods for using PREDIKIN to design substrates are described by Ross et al. (2003) PNAS, USA, 100 (1):74-79, which is incorporated herein by reference. Other programs serving the same function are well known in the art.

A number of substrates specific to a type of protein kinase are known. Table 3 lists well known tyrosine kinase substrates.

TABLE 3
Partial list of known tyrosine kinase substrates and the position
of the phosphorylated tyrosine residue is indicated. Shown
are other post-translational protein modifications that can
be detected by the methods of the invention.

| | Phosphorylation | | Phosphorylation |
|---|---|---|---|
| Substrate | Site | Substrate | Site |
| KDR | Tyr996 | PLCg | Tyr771/775 |
| STAT3 | Tyr705 | T-cell activation | Tyr217 |
| | | antigen | |
| cdc2 | Tyrl5 | T-cell Receptor | Tyrl52 |
| | | Zeta chain | |
| JAK1 | Tyrl022/1023 | ERK5 | Tyr215/220 |
| KDR | Tyrl054/1059 | GSK3 | Tyr284 |
| Paxillin | TyrSl | JNK1 | Tyrl90 |
| Pyk2 | Tyr402 | TrkC | Tyr705 |
| She | Tyr317 | Zinc Finger | Tyr70 |
| | | Protein 145 | |
| STAT1 | Tyr701 | TIF | Tyr495 |
| TrkA | Tyr490 | c-Kit (Y900) | 64 |
| TrkA | Tyr785 | PTP1B | Tyr66 |
| Tyk2 | Tyrl054/1055 | SHP-2 (Try542) | 63 |
| Zap70 | Tyr493 | PI3K | Tyr688 |
| STAT6 | Tyr641 | Src | Tyr416 |
| HER2 | Tyrl248 | c-FGR | Tyr412 |
| STAT5 | Tyr694 | EGFR | Tyrll73 |
| CTD | Tyr | ERa | Tyr537 |
| FAK | Tyr577 | IRS1 | Tyr891 |
| STAT4 | Tyr693 | ER.S2 | Tyr766 |
| PDGFR | Tyr775 | JAK2 | TyrlOOS |
| STAT2 | Tyr690 | PTEN | Tyr315 |
| JAK1 | Tyrl023 | c-Cbl | Tyr700 |
| Liver Glycogen | Tyr637 | Dynaminl/n | Tyr231 |
| Synthase | | | |
| NLK-1 | TyrlSl | P62Dok | Tyr398 |
| PDGFR | Tyr771 | R-Ras | Tyr66 |
| Signal | Tyrl60 | PTEN | Tyr336 |
| Transduction | | | |
| Protein | | | |
| TLE2 | Tyr226 | VEGFR1 | Tyr 12 13 |
| beta-adrenergic | Tyr350 | VEGFR2 | Tyrl212 |
| receptor | | | |
| CSBP1 | Tyr 182 | Zap70 | Tyr319 |
| doublecortin | Tyr345 | c-Cbl | Tyr774 |
| HER2 | Tyrl248 | Met | Tyr 1349 |
| Insulin | Tyr992 | Met | Tyrl356 |
| Receptor | | | |
| Precursor | | | |

The foregoing kinase/phosphatase substrates are intended to be illustrative and not limiting. Using teachings provided herein and those well known in the art, other kinase substrates will be readily available to one of skill in the art for use in the apparatus, methods and compositions described herein.

### Attachment of Kinase/Phosphatase Substrates to the SERS Substrate Device

The kinase and/or phosphatase substrates may be attached to nanoparticle(s) or to features present on a surface (e.g., a Raman active surface) by any of a number of methods well known to those of skill in the art. Such methods include but are not limited to using microscale contact pins or injectors or covalent bonds.

For example, in certain embodiments that include a gold nanostructure, the kinase and/or phosphatase substrates are tethered onto a gold nanostructure by a covalent bond formed by a gold-thiol reaction between a cysteine group at the terminus of the substrate (e.g., peptide) and the gold surface. In various embodiments, the array surface and/or the kinase and/or phosphatase substrate can be derivatized with, for example, amine, carboxyl groups, alkyl groups, alkylene groups, hydroxyl groups, or other functional groups so that the peptide (or other substrate) can be linked directly to the surface or coupled through a linker. In other embodiments, the surface can be functionalized, e.g., with amine, carboxyl, or other functional groups for attachment to the kinase and/or phosphatase substrate(s).

Suitable linkers include, but are not limited to hetero- or homo-bifunctional molecules that contain two or more reactive sites that may each form a covalent bond with the respective binding partner (kinase/phosphatase substrate, surface, or functional group thereon, etc.). Linkers suitable for joining such moieties are well known to those of skill in the art. For example, a protein molecule can readily be linked by any of a variety of linkers including, but not limited to a peptide linker, a straight or branched chain carbon chain linker, or by a heterocyclic carbon linker. Heterobifunctional cross-linking reagents such as active esters of N-ethylmaleimide have been widely used to link proteins to other moieties (see, e.g., Lerner et al. (1981) Proc. Nat. Acad. Sci. (USA), 78: 3403-3407; Kitagawa et al. (1976) J. Biochem., 79: 233-236; Birch and Lennox (1995) Chapter 4 in Monoclonal Antibodies: Principles and Applications, Wiley-Liss, N.Y., and the like).

In certain embodiment, the kinase and/or phosphatase substrate can be attached to the surface utilizing a biotin/avidin interaction. In certain embodiments, biotin or avidin, e.g., with a photolabile protecting group can be affixed to the surface and/or to the kinase/phosphatase substrate(s). Irradiation of the surface in the presence of the desired kinase and/or phosphatase substrate bearing the corresponding avidin or streptavidin, or biotin, results in coupling of the substrate to the surface.

In various embodiments, multiple kinase and/or phosphatase substrates, usually at least about five, preferably at least ten, or at least 20, 50, 100, 500, 1000, 10,000 or 100, 1000 are attached to the surface. The kinase/phosphatase substrate can be a single substrate attached in multiple copies on to the surface or attached in varying densities across the surface. Varying the density of the substrate will facilitate quantitation of the kinase/phosphatase activity. Thus, if a new peak appears upon the occurrence of a phosphorylation reaction, the amplitude of the peak corresponding to different locations of the nanostructure surface will increase in accordance with the increase in density of the attached substrate. Alternatively, pluralities of substrates are attached at different locations on the surface. Thus, several positions are tethered with positive control substrates, at various densities and at other positions, negative control substrates, also at various densities.

In certain embodiments, the surface provides a high density array of kinase and/or phosphatase substrates. In various embodiments, such an array can comprise at least 100 or at least 200 different substrates/cm², preferably at least 300, 400, 500, or 1000 different substrates/cm², and more preferably at least 1,500, 2,000, 4,000, 10,000, or 50,000, or 100,000 different substrates/cm².

Methods for patterning molecules on surfaces at high density are well known to those of skill in the art. Such methods include, for example, the use of high density microarray printers (See, e.g., Heller (2002) Ann. Rev. Biomed. Eng. 4: 129-153). Other microarray printers utilize “on-demand” piezoelectric droplet generators (e.g., inkjet printers) (see, e.g., U.S. Pat. Nos. 6,395,562; 6,365,378; 6,228,659; and WO 95/251116 and WO/2003/028868) which are incorporated herein by reference. Other approaches involve de novo synthesis (see, e.g., Fodor et al. (1991) Science, 251:767-773 and U.S. Pat. Nos. 6,269,846, 6,271,957 and 6,480,324 which are incorporated herein by reference). A number of printers are commercially available (see e.g., VERSA Mini Spot-printing workstation from Aurora Biomed, BIOODYSSEY CALLIGRAPHER MiniArrayer from Bio-Rad, OmniGrid Accent from Genomic Solutions and the like).

### Substrate Phosphorylation/Dephosphorylation Assay

Where it is desirable to detect and/or measure the activity of a single type of kinase and/or phosphatase in a sample, a single type of substrate is tethered to the SERS surface of the microfluidic device. In embodiments pertaining to detection of a plurality of kinases and/or phosphatases in a sample, a plurality of substrates is tethered to the SERS surface of the microfluidic device.

The kinase and/or phosphatase activity detection/measurement described herein can be performed on any of a number of different samples. For example, in screening systems for the identification of kinase antagonists or agonists, cells/cell lines and/or lysates thereof, or appropriate buffer systems comprising the kinase(s) of interest can be contacted/administered as one or more test compounds. The samples derived therefrom can then be screened for kinase activity by identifying which test compounds show activity, e.g., as kinase inhibitors and/or phosphatase agonists, and which kinase/phosphatase enzymes they inhibit and/or agonize.

In various diagnostic embodiments, the existence of the kinase and/or phosphatase enzyme(s), and/or concentration, and/or activity thereof, is determined in a biological sample. The biological sample can include essentially any biomaterial that is to be assayed. Such biomaterials include, but are not limited to biofluids such as blood or blood fractions, plasma, lymphatic fluid, tears, spinal and pulmonary fluid, cerebrospinal fluid, seminal fluid, urine, saliva and the like, tissue samples, cell samples, tissue or organ biopsies or aspirates, histological specimens, and the like.

In certain embodiments the raw cell lysate can be directly introduced into the microfluidic device and the measurement can be done during the incubation. Samples are introduced into the reaction chamber through microfluidic channels. The total sample volume may be reduced to sub-microliter volume.

Phosphorylation of a kinase substrate or dephosphorylation of a phosphatase substrate is detectable by changes in the spectrum obtained by SERS, electromagnetic resonance measurement, or acoustic measurement. Changes in the spectrum of the SERS surface compared to a control (no sample or control sample) may be indicative of kinase/phosphatase activity. The change in the spectrum could be appearance of a new peak accompanied by the disappearance of an existing peak, a shifting of peaks, as well as the merging and/or splitting of peaks.

Such a surface provides an effective tool for real-time screening for the concentration and/or activity of one or a plurality of kinases and/or phosphatases and/or for quantification of the kinetics of one or more kinases and/or phosphatases. Such a surface can also be readily used to screen for kinase and/or phosphatase inhibitor activity of one or a plurality of test agents (e.g. a chemical library).

In certain embodiments the kinase/phosphatase activity detection and/or measurements can be used in personalized molecular diagnostics for cancers by physicians and hospital personnel. In one embodiment, the instant invention is used to detect the presence of molecular markers specific to a particular type of cancer.

### Example 1

### Detection of Altered Protease Activity

Real-time in situ detection of proteases is crucial for early-stage cancer screening as well as for assessing the efficacy of a treatment method. In one illustrative example, the instant invention is used to detect activity of a protease, prostate-specific antigen (PSA), in a biological sample. PSA levels are increased in prostate cancer. Thus, PSA serves as a biomarker for prostate cancer. Measurement of plasma PSA concentration does not differentiate prostate cancer patients from those with benign prostatic hyperplasia, leading to a high false-positive rate. Efforts to enhance the clinical value of PSA as an early detection marker for prostate cancer have included the characterization of various molecular isoforms of PSA. Among the various isoforms, the proteolytically active subpopulation of PSA is accepted as a more useful tumor marker and malignancy predictor than the serum PSA concentration (Wu et al. (2004) Prostate 58: 345-353; Wu et al. (2004) Clin. Chem., 50: 125-129).

The peptide substrate used for detection of PSA protease activity incorporates the amino acid sequence of the active site of PSA-specific peptides with serine residues and flanking sequences that can be recognized by PSA. Thus, the peptide includes the sequence HSSKLQ-LAAAC which is known to have a very high specificity for proteolytically active PSA (Denmeade et al., (1997) Cancer Res 57:4924-4930). It has also been shown that HSSKLQ-L is cleaved by PSA but not by any other proteases in vivo in a mouse model (Denmeade et al., (2003) J. Natl. Cancer Inst. 95: 990-1000). Thus, a screen may be performed wherein multiple peptides are attached to the nanostructure of a SERS substrate surface, each having a random or known sequence portion, and the PSA specific sequence HSSKLQ-LAAAC or HSSKLQ-L. The PSA hydrolysis site is between Q and L. Proteolysis results in shortening of the peptide, which is detectable by changes in the spectrum associated with the peptides. This may then be observed in the resulting spectrograph.

In this particular example, a SERS substrate surface has a gold nanostructure. The peptides are attached to the surface via a gold-thiol covalent bond formed between cysteine at the carboxyl terminus of the peptide and the gold nanostructure. The sample to be tested is introduced into the microfluidic chamber where the temperature is maintained at 37° C. The sample is maintained in contact with the peptide substrates on the SERS surface in the device for about 2 hours. The spectrum obtained from the plasma sample from a patient with suspected prostate cancer is compared to that of an age matched non-afflicted person. Purified PSA is used as a positive control for the detection assay.

Further, proteolysis dynamics may be monitored in real-time by time-resolved spectra acquisitions. Thus, the disappearance, appearance, shifting, merging, or splitting in peaks can be followed real-time.

The use of a nanostructure facilitates the detection of changes in spectra associated with a particular molecule attached to the SERS surface. Thus, the fusion of an enzyme substrate to fluorescent or radioactive tags is not necessary.

### Example 2

### Detection of Altered Kinase Activity

Protein kinases represent approximately 1.7% of all human genes and not surprisingly are important cellular regulatory proteins (Manning et al. (2002) Science 298: 1912-1934). Most of the 30 known tumor suppressor genes and more than 100 dominant oncogenes are protein kinases (Futreal et al. (2001) Nature 409: 850-852). Tyrosine-kinase receptors are key molecules in signaling pathways leading to growth and differentiation of normal cells. Mutations leading to inactivation of certain tyrosine kinases and increased activity of others is a hallmark of tumor cells. The instant invention may be used to provide a tyrosine kinase activity profile associated with a certain tissue of interest. In this example, the tissue is a biopsy sample of the colon obtained from a person free of colon cancer (for obtaining a normal kinase activity profile) and from a patient afflicted with colon cancer (for obtaining a kinase activity profile from a positive control). Once the tyrosine kinase activity profile for normal tissue and control tissue is obtained, the same procedure is performed with a colon biopsy sample from a patient suspected of having colon cancer. A significant departure from the normal kinase activity profile spectrum and/or similarity to the positive control kinase activity profile spectrum is indicative of colon cancer.

Biopsy samples are transferred to ceramic beads-containing special centritubes (Roche, Penzberg, Germany) with 0.1 mL of pre-chilled TLysis buffer. The tissue may be subjected to oscillation made by the MagNA Lyser machine at 6500 r/min for 120 seconds. The lysate is then centrifuged at 100,000 g for 1 h at 4° C., and the supernatant is saved and assayed for protein concentration (Lowry method).

Tyrosine kinase substrates of Table 3 are tethered to the nanostructure surface of the instant invention. The tissue lysate may be introduced into the microfluidic chamber, which is maintained at 37° C. The lysate is incubated with tyrosine kinase substrates for 1 hour. The spectrum associated with the enzyme substrates attached to the nanostructure surface is measured before the introduction of the lysate, during the incubation and after washing away of the lysate. Thus, phosphorylation dynamics are monitored in real-time by time-resolved spectra acquisitions. This time-dependent tyrosine kinase activity profile increases the accuracy of data interpretation.

### Example 3

### Transcription Factor Activity Profiling

Gene expression profiling is increasingly used to characterize cell samples such as tumor biopsies. By measuring the levels of selected messenger RNAs in a sample, inferences may be drawn concerning the subtype or molecular profile of the sample, providing information that may support medical decisions, including treatment alternatives. A potentially more informative alternative to measuring RNA levels is to directly measure the activity of proteins in a tumor biopsy or other cell sample. DNA binding transcription factors are a class of proteins that are particularly informative for molecular profiling, providing information about the detailed transcriptional state of cells in a sample.

In this example, the activity of DNA binding transcription factors in a cell sample are dynamically measured using a microfluidic SERS detection apparatus. The apparatus is prepared such that one or potentially many individually addressed oligonucleotide probes are attached to the nanostructure of the SERS substrate surface, with each oligonucleotide having a sequence comprising a binding site for a particular transcription factor of interest. For example, a 25-mer double stranded DNA oligonucleotide including the E-box hexamer sequence CACGTG may be used to interrogate the activity of a subclass of basic helix-loop-helix transcription factors. Mismatch oligonucleotides may also be used as controls for nonspecific binding, and identical sequences may be redundantly arrayed to increase measurement accuracy. Evaluation of SERS spectra provides dynamic information about the binding of transcription factors to the oligonucleotide probes as well as the formation of DNA-transcription factor super-complexes that may include additional transcription cofactors and TAF proteins.

A needle biopsy containing 1×10⁴ cells is taken and the nuclear extract isolated at 4° C. using Sigma NXTRACT CELLYTIC NUCLEAR extraction kit. The nuclear extract is then resuspended in 19 μl cold 10 mM Tris-HCL buffer containing 1 mM DTT. 11 Sigma protease inhibitor cocktail P8340 is added, and the solution is transferred to the microfluidic SERS detection apparatus. At 25° C., the sample enters the microscale chamber and DNA binding events are measured in real-time using incident laser light and detection of transmitted SERS spectra. Transcription factor binding activity profiles are developed or calculated from one or more of the following measurements, for each oligonucleotide sequence: (1) the occupancy of bound oligonucleotides as a fraction of total available sites; (2) the average stability of DNA-protein complexes in seconds; and (3) the total number of binding events per unit time. Comparison of transcription factor binding activity profiles across tissue types and across diseased versus normal tissues characterize the molecular pathology of a tissue sample and are potentially diagnostic for treatment alternatives.

TABLE 4
Additional proteases are presented, the concentration and activity of
which may be detected and quantitated using embodiments of the methods of the invention.

| | | | | Map Location ID | |
|---|---|---|---|---|---|
| Protease | | Entrez Gene | enzyme | (cytogenetic or | |
| Gene Name | Family | ID | ID | genetic location) | Descriptive Name (or default name) |
| PGA3 | A01.001 | 643834 | 3.4.23.1 | 11q12.2 | pepsinogen 3, group I (pepsinogen A) |
| PGA@ | A01.001 | 5219 | — | 11q13 | pepsinogen A gene cluster |
| PGC | A01.003 | 5225 | 3.4.23.3 | 6p21.3-p21.1 | progastricsin (pepsinogen C) |
| BACE1 | A01.004 | 23621 | — | 11q23.2-q23.3 | beta-site APP-cleaving enzyme 1 |
| CYMP | A01.006 | 1542 | — | 1p13.3 | chymosin pseudogene |
| REN | A01.007 | 5972 | 3.4.23.15 | 1q32 | renin |
| CTSD | A01.009 | 1509 | 3.4.23.5 | 11p15.5 | cathepsin D (lysosomal aspartyl |
| | | | | | protease) |
| CTSE | A01.010 | 1510 | 3.4.23.5 | 1q31 | cathepsin E |
| BACE2 | A01.041 | 25825 | — | 21q22.3 | beta-site APP-cleaving enzyme 2 |
| NAPSA | A01.046 | 9476 | — | 19q13.33 | napsin A aspartic peptidase |
| PGA5 | A01.071 | 5222 | 3.4.23.1 | 11q13 | pepsinogen 5, group I (pepsinogen A) |
| NAPSB | A01.P01 | 256236 | — | 19q13.33 | napsin B aspartic peptidase |
| | | | | | pseudogene |
| SASP | A02.059 | 151516 | — | 2p13.3 | hypothetical protein FLJ25084 |
| DDI1 | A02.xxx | AK093336 | — | — | — |
| DDI2 | A02.xxx | BN000122 | — | — | — |
| NRIP2 | A02.xxx | 83714 | — | 12p13.33 | nuclear receptor interacting protein 2 |
| NRIP3 | A02.xxx | 56675 | — | 11p15.3 | nuclear receptor interacting protein 3 |
| PSEN1 | A22.001 | 5663 | — | 14q24.3 | presenilin 1 (Alzheimer disease 3) |
| PSEN2 | A22.002 | 5664 | — | 1q31-q42 | presenilin 2 (Alzheimer disease 4) |
| HM13 | A22.003 | 81502 | — | 20q11.21 | histocompatibility (minor) 13 |
| PSH4 | A22.004 | 56928 | — | 19p13.3 | signal peptide peptidase-like 2B |
| PSH1 | A22.005 | 121665 | — | 12q24.31 | signal peptide peptidase 3 |
| IMP5 | A22.006 | 162540 | — | 17q21.31 | intramembrane protease 5 |
| PSH5 | A22.007 | 84888 | — | 15q21.2 | putative intramembrane cleaving |
| | | | | | protease |
| PIP | Ax1.xxx | 5304 | — | 7q34 | prolactin-induced protein |
| CTSL2 | C01.009 | 1515 | — | 9q22.2 | cathepsin L2 |
| CTSZ | C01.013 | 1522 | — | 20q13 | cathepsin Z |
| CTSLL2 | C01.014 | 1517 | — | 10q | cathepsin L-like 2 |
| CTSLL3 | C01.015 | 1518 | — | 10q22.3-q23.1 | cathepsin L-like 3 |
| CTSF | C01.018 | 8722 | — | 11q13 | cathepsin F |
| CTSL | C01.032 | 1514 | 3.4.22.15 | 9q21-q22 | cathepsin L |
| CTSS | C01.034 | 1520 | 3.4.22.27 | 1q21 | cathepsin S |
| CTSO | C01.035 | 1519 | — | 4q31-q32 | cathepsin O |
| CTSK | C01.036 | 1513 | — | 1q21 | cathepsin K (pycnodysostosis) |
| CTSW | C01.037 | 1521 | — | 11q13.1 | cathepsin W (lymphopain) |
| CTSH | C01.040 | 1512 | 3.4.22.16 | 15q24-q25 | cathepsin H |
| CTSB | C01.060 | 1508 | 3.4.22.1 | 8p22 | cathepsin B |
| CTSC | C01.070 | 1075 | — | 11q14.1-q14.3 | cathepsin C |
| BLMH | C01.084 | 642 | — | 17q11.2 | bleomycin hydrolase |
| TINAG | C01.973 | 27283 | — | 6p11.2-p12 | tubulointerstitial nephritis antigen |
| LCN7 | C01.975 | 64129 | — | 1p35.2 | lipocalin 7 |
| CTSLL1 | C01.P02 | 1516 | — | 10q | cathepsin L-like 1 |
| CAPN1 | C02.001 | 823 | 3.4.22.17 | 11q13 | calpain 1, (mu/I) large subunit |
| CAPN2 | C02.002 | 824 | 3.4.22.17 | 1q41-q42 | calpain 2, (m/II) large subunit |
| CAPN3 | C02.004 | 825 | 3.4.22.17 | 15q15.1-q21.1 | calpain 3, (p94) |
| CAPN9 | C02.006 | 10753 | — | 1q42.11-q42.3 | calpain 9 |
| CAPN8 | C02.007 | AA043093 | — | — | — |
| CAPN7 | C02.008 | 23473 | — | 3p24 | calpain 7 |
| SOLH | C02.010 | 6650 | — | 16p13.3 | small optic lobes homolog |
| | | | | | (Drosophila) |
| CAPN5 | C02.011 | 726 | — | 11q14 | calpain 5 |
| CAPN11 | C02.013 | 11131 | — | 6p12 | calpain 11 |
| CAPN12 | C02.017 | 147968 | — | 19q13.2 | calpain 12 |
| CAPN10 | C02.018 | 11132 | — | 2q37.3 | calpain 10 |
| CAPN13 | C02.020 | 92291 | — | 2p22-p21 | calpain 13 |
| CAPN14 | C02.021 | 440854 | — | 2p13.1-p21 | calpain 14 |
| CAPN6 | C02.971 | 827 | — | xq23 | calpain 6 |
| C6orf103 | C02.972 | 79747 | — | 6q24.3 | chromosome 6 open reading frame |
| | | | | | 103 |
| UCHL1 | C12.001 | 7345 | 3.4.19.12 | 4p14 | ubiquitin carboxyl-terminal esterase |
| | | | | | L1 (ubiquitin thiolesterase) |
| UCHL3 | C12.003 | 7347 | 3.2.1.15 | 13q22.2 | ubiquitin carboxyl-terminal esterase |
| | | | | | L3 (ubiquitin thiolesterase) |
| BAP1 | C12.004 | 8314 | — | 3p21.31-p21.2 | BRCA1 associated protein-1 |
| | | | | | (ubiquitin carboxy-terminal |
| | | | | | hydrolase) |
| UCHL5 | C12.005 | 51377 | — | 1q32 | ubiquitin carboxyl-terminal hydrolase |
| | | | | | L5 |
| LGMN | C13.004 | 5641 | — | 14q32.1 | legumain |
| PIGK | C13.005 | 10026 | — | 1p31.1 | phosphatidylinositol glycan, class K |
| LGMN2P | C13.P01 | 122199 | — | 13q21.31 | legumain 2 pseudogene |
| CASP1 | C14.001 | 834 | — | 11q23 | caspase 1, apoptosis-related cysteine |
| | | | | | protease (interleukin 1, beta, |
| | | | | | convertase) |
| CASP3 | C14.003 | 836 | — | 4q34 | caspase 3, apoptosis-related cysteine |
| | | | | | protease |
| CASP7 | C14.004 | 840 | — | 10q25 | caspase 7, apoptosis-related cysteine |
| | | | | | protease |
| CASP6 | C14.005 | 839 | — | 4q25 | caspase 6, apoptosis-related cysteine |
| | | | | | protease |
| CASP2 | C14.006 | 835 | — | 7q34-q35 | caspase 2, apoptosis-related cysteine |
| | | | | | protease (neural precursor cell |
| | | | | | expressed, developmentally down- |
| | | | | | regulated 2) |
| CASP4 | C14.007 | 837 | — | 11q22.2-q22.3 | caspase 4, apoptosis-related cysteine |
| | | | | | protease |
| CASP5 | C14.008 | 838 | — | 11q22.2-q22.3 | caspase 5, apoptosis-related cysteine |
| | | | | | protease |
| CASP8 | C14.009 | 841 | — | 2q33-q34 | caspase 8, apoptosis-related cysteine |
| | | | | | protease |
| CASP9 | C14.010 | 842 | — | 1p36.3-p36.1 | caspase 9, apoptosis-related cysteine |
| | | | | | protease |
| CASP10 | C14.011 | 843 | — | 2q33-q34 | caspase 10, apoptosis-related cysteine |
| | | | | | protease |
| CASP14 | C14.018 | 23581 | — | 19p13.1 | caspase 14, apoptosis-related cysteine |
| | | | | | protease |
| MALT1 | C14.026 | 10892 | — | 18q21 | mucosa associated lymphoid tissue |
| | | | | | lymphoma translocation gene 1 |
| CFLAR | C14.971 | 8837 | — | 2q33-q34 | CASP8 and FADD-like apoptosis |
| | | | | | regulator |
| CASP14L | C14.975np | 197350 | — | 16p13.3 | hypothetical protein LOC197350 |
| CASP12P1 | C14.P01 | 120329 | — | 11q22.3 | caspase 12 pseudogene 1 |
| PGPEP1 | C15.010 | 54858 | 3.4.19.3 | 19p13.11 | pyroglutamyl-peptidase I |
| PGPEP2 | C15.011 | 145814 | — | 15q26.3 | hypothetical protein LOC145814 |
| USP5 | C19.001 | 8078 | — | 12p13 | ubiquitin specific protease 5 |
| | | | | | (isopeptidase T) |
| USP6 | C19.009 | 9098 | — | 17q11 | ubiquitin specific protease 6 (Tre-2 |
| | | | | | oncogene) |
| USP4 | C19.010 | 7375 | — | 3p21.3 | ubiquitin specific protease 4 (proto- |
| | | | | | oncogene) |
| USP8 | C19.011 | 9101 | — | 15q21.2 | ubiquitin specific protease 8 |
| USP13 | C19.012 | 8975 | — | 3q26.2-q26.3 | ubiquitin specific protease 13 |
| | | | | | (isopeptidase T-3) |
| USP2 | C19.013 | 9099 | — | 11q23.3 | ubiquitin specific protease 2 |
| USP11 | C19.014 | 8237 | — | xp11.23 | ubiquitin specific protease 11 |
| USP14 | C19.015 | 9097 | — | 18p11.32 | ubiquitin specific protease 14 (tRNA- |
| | | | | | guanine transglycosylase) |
| USP7 | C19.016 | 7874 | — | 16p13.3 | ubiquitin specific protease 7 (herpes |
| | | | | | virus-associated) |
| USP9X | C19.017 | 8239 | — | xp11.4 | ubiquitin specific protease 9, X-linked |
| | | | | | (fat facets-like, Drosophila) |
| USP10 | C19.018 | 9100 | — | 16q24.1 | ubiquitin specific protease 10 |
| USP1 | C19.019 | 7398 | — | 1p32.1-p31.3 | ubiquitin specific protease 1 |
| USP12 | C19.020 | 9959 | — | 5q33-q34 | ubiquitin specific protease 12 |
| | | | | | pseudogene 1 |
| USP16 | C19.021 | 10600 | — | 21q22.11 | ubiquitin specific protease 16 |
| USP15 | C19.022 | 9958 | — | 12q14 | ubiquitin specific protease 15 |
| USP17 | C19.023 | 391627 | — | 4p15 | ubiquitin specific peptidase 17 |
| USP19 | C19.024 | 10869 | — | 3p21.31 | ubiquitin specific protease 19 |
| USP20 | C19.025 | 10868 | — | 9q34.11 | ubiquitin specific protease 20 |
| USP3 | C19.026 | 9960 | — | 15q22.3 | ubiquitin specific protease 3 |
| USP9Y | C19.028 | 8287 | — | yq11.2 | ubiquitin specific protease 9, Y-linked |
| | | | | | (fat facets-like, Drosophila) |
| USP18 | C19.030 | 11274 | — | 22q11.21 | ubiquitin specific protease 18 |
| USP21 | C19.034 | 27005 | — | 1q22 | ubiquitin specific protease 21 |
| USP22 | C19.035 | 23326 | — | 17p11.2 | ubiquitin specific protease 22 |
| USP33 | C19.037 | 23032 | — | 1p13.1 | ubiquitin specific protease 33 |
| USP29 | C19.040 | 57663 | — | 19q13.43 | ubiquitin specific protease 29 |
| USP25 | C19.041 | 29761 | — | 21q11.2 | ubiquitin specific protease 25 |
| USP36 | C19.042 | 57602 | — | 17q25.3 | ubiquitin specific protease 36 |
| USP32 | C19.044 | 84669 | — | 17q23.2 | ubiquitin specific protease 32 |
| USP26 | C19.046 | 83844 | 3.1.2.15 | xq26.2 | ubiquitin specific protease 26 |
| USP24 | C19.047 | 23358 | — | 1p32.3 | ubiquitin specific protease 24 |
| USP42 | C19.048 | 84132 | — | 7p22.1 | ubiquitin specific protease 42 |
| USP46 | C19.052 | 64854 | — | 4q12 | ubiquitin specific protease 46 |
| USP37 | C19.053 | 57695 | — | 2q35 | ubiquitin specific protease 37 |
| USP28 | C19.054 | 57646 | — | 11q23 | ubiquitin specific protease 28 |
| USP47 | C19.055 | 55031 | — | 11p15.3 | ubiquitin specific protease 47 |
| USP38 | C19.056 | 84640 | — | 4q31.1 | ubiquitin specific protease 38 |
| USP44 | C19.057 | 84101 | — | 12q22 | ubiquitin specific protease 44 |
| USP50 | C19.058 | 373509 | — | 15q21.1 | ubiquitin specific protease 50 |
| USP50 | C19.058np | AI990110 | — | — | — |
| USP35 | C19.059 | 57558 | — | 11q14.1 | ubiquitin specific protease 35 |
| USP30 | C19.060 | 84749 | — | 12q24.11 | ubiquitin specific protease 30 |
| USP45 | C19.064 | 85015 | — | 6q16.3 | ubiquitin specific protease 45 |
| USP51 | C19.065 | 158880 | — | xp11.22 | ubiquitin specific protease 51 |
| USP51 | C19.065 | BF741256 | — | — | — |
| USP34 | C19.067 | 9736 | — | 2p15 | ubiquitin specific protease 34 |
| USP48 | C19.068 | 84196 | — | 1p36.12 | ubiquitin specific protease 48 |
| USP40 | C19.069 | 55230 | — | 2q37.1 | ubiquitin specific protease 40 |
| USP41 | C19.070 | 150200 | — | 22q11.21 | ubiquitin specific peptidase 41 |
| USP31 | C19.071 | 57478 | — | 16p12.1 | ubiquitin specific protease 31 |
| USP49 | C19.073 | 25862 | — | 6p21 | ubiquitin specific protease 49 |
| USP27X | C19.075 | 373504 | — | xp11 | ubiquitin specific protease 27, X- |
| | | | | | linked |
| USP27 | C19.075 | AW851065 | — | — | — |
| USP54 | C19.080 | 159195 | — | 10q22.2 | ubiquitin specific protease 54 |
| USP53 | C19.081 | 54532 | — | 4q26 | ubiquitin specific protease 53 |
| USP39 | C19.972 | 10713 | — | 2p11.2 | ubiquitin specific protease 39 |
| USP43 | C19.976 | 124739 | — | 17p13.1 | ubiquitin specific protease 43 |
| USP52 | C19.978 | 9924 | — | 12q13.2-q13.3 | ubiquitin specific protease 52 |
| USP8P | C19.980 | 394216 | — | 6p21 | ubiquitin specific protease 8 |
| | | | | | pseudogene |
| UBADC1 | C19.M01 | 10422 | — | 9q34.3 | ubiquitin associated domain |
| | | | | | containing 1 |
| NEK2P | C19.P01 | 326302 | — | 14q11.2 | NEK2 pseudogene |
| USP17L | C19.xxx | BN000116 | — | — | — |
| GGH | C26.001 | 8836 | 3.4.19.9 | 8q12.3 | gamma-glutamyl hydrolase |
| | | | | | (conjugase, folylpolygammaglutamyl |
| | | | | | hydrolase) |
| GMPS | C26.950 | 8833 | 6.3.5.2 | 3q24 | guanine monphosphate synthetase |
| PPAT | C44.001 | 5471 | 2.4.2.14 | 4q12 | phosphoribosyl pyrophosphate |
| | | | | | amidotransferase |
| GFPT1 | C44.970 | 2673 | 2.6.1.16 | 2p13 | glutamine-fructose-6-phosphate |
| | | | | | transaminase 1 |
| GFPT2 | C44.972 | 9945 | — | 5q34-q35 | glutamine-fructose-6-phosphate |
| | | | | | transaminase 2 |
| ASNS | C44.974 | 440 | 6.3.5.4 | 7q21.3 | asparagine synthetase |
| SHH | C46.002 | 6469 | — | 7q36 | sonic hedgehog homolog (Drosophila) |
| IHH | C46.003 | 3549 | — | 2q33-q35 | Indian hedgehog homolog |
| | | | | | (Drosophila) |
| DHH | C46.004 | 50846 | — | 12q12-q13.1 | desert hedgehog homolog |
| | | | | | (Drosophila) |
| SENP1 | C48.002 | 29843 | — | 12q13.1 | SUMO1/sentrin specific protease 1 |
| SENP3 | C48.003 | 26168 | — | 17p13 | SUMO1/sentrin/SMT3 specific |
| | | | | | protease 3 |
| SENP6 | C48.004 | 26054 | — | 6q13-q14.3 | SUMO1/sentrin specific protease 6 |
| SENP2 | C48.007 | 59343 | — | 3q27.2 | SUMO1/sentrin/SMT3 specific |
| | | | | | protease 2 |
| SENP5 | C48.008 | 205564 | — | 3q29 | SUMO1/sentrin specific protease 5 |
| SENP7 | C48.009 | 57337 | — | 3q12 | SUMO1/sentrin specific protease 7 |
| SENP8 | C48.011 | 123228 | — | 15q23 | SUMO/sentrin specific protease |
| | | | | | family member 8 |
| ESPL1 | C50.001 | 9700 | 3.4.22.49 | 12q | extra spindle poles like 1 (S. cerevisiae) |
| ATG4A | C54.002 | 115201 | — | xq22.1-q22.3 | APG4 autophagy 4 homolog A (S. cerevisiae) |
| ATG4B | C54.003 | 23192 | — | 2q37.3 | APG4 autophagy 4 homolog B (S. cerevisiae) |
| ATG4C | C54.004 | 84938 | — | 1p31.3 | APG4 autophagy 4 homolog C (S. cerevisiae) |
| ATG4D | C54.005 | 84971 | — | 19p13.2 | APG4 autophagy 4 homolog D (S. cerevisiae) |
| PARK7 | C56.002 | 11315 | — | 1p36.33-p36.12 | Parkinson disease (autosomal |
| | | | | | recessive, early onset) 7 |
| PFAS | C56.972 | 5198 | 6.3.5.3 | 17p13.1 | phosphoribosylformylglycinamidine |
| | | | | | synthase (FGAR amidotransferase) |
| ZA20D1 | C64.001 | 56957 | — | 1q21.2 | zinc finger, A20 domain containing 1 |
| C15orf16 | C64.002 | 161725 | — | 15q13.3 | chromosome 15 open reading frame |
| | | | | | 16 |
| TNFAIP3 | C64.003 | 7128 | — | 6q23 | tumor necrosis factor, alpha-induced |
| | | | | | protein 3 |
| ZRANB1 | C64.004 | 54764 | — | 10q26.13 | zinc finger, RAN-binding domain |
| | | | | | containing 1 |
| OTUB1 | C65.001 | 55611 | — | 11q13.1 | OTU domain, ubiquitin aldehyde |
| | | | | | binding 1 |
| OTUB2 | C65.002 | 78990 | — | 14q32.13 | OTU domain, ubiquitin aldehyde |
| | | | | | binding 2 |
| CYLD | C67.001 | 1540 | — | 16q12.1 | cylindromatosis (turban tumor |
| | | | | | syndrome) |
| SCRN1 | C69.003 | 9805 | — | 7p14.3-p14.1 | secernin 1 |
| SCRN2 | C69.004 | 90507 | — | 17q21.32 | secernin 2 |
| SCRN3 | C69.005 | 79634 | — | 2q31.1 | secernin 3 |
| OTUD4 | Cx1.xxx | 54726 | — | 4q31.21 | HIV-1 induced protein HIN-1 |
| HSHIN1L | Cx1.xxx | BN000160 | — | — | — |
| CXorf45 | Cx1.xxx | 79868 | — | xq23 | chromosome X open reading frame 45 |
| HSHIN3 | Cx1.xxx | 23252 | — | 1p36.13 | KIAA0459 protein |
| OTUD1 | Cx1.xxx | 220213 | — | 10p12.31 | OTU domain containing 1 |
| OTUD5 | Cx1.xxx | 55593 | — | xp11.23 | hypothetical protein DKFZp761A052 |
| OTUD6A | Cx1.xxx | 139562 | — | xq13.1 | HIN-6 protease |
| HSHIN7 | Cx1.xxx | BI829009 | — | — | — |
| OTUD6B | Cx1.xxx | 51633 | — | 8q21.3 | CGI-77 protein |
| TTC28 | Cx2.xxxnp | 23331 | — | 22q12.1 | KIAA1043 protein |
| ANPEP | M01.001 | 290 | 3.4.11.2 | 15q25-q26 | alanyl (membrane) aminopeptidase |
| | | | | | (aminopeptidase N, aminopeptidase |
| | | | | | M, microsomal aminopeptidase, |
| | | | | | CD13, p150) |
| ENPEP | M01.003 | 2028 | 3.4.11.7 | 4q25 | glutamyl aminopeptidase |
| | | | | | (aminopeptidase A) |
| LTA4H | M01.004 | 4048 | 3.3.2.6 | 12q22 | leukotriene A4 hydrolase |
| TRHDE | M01.008 | 29953 | 3.4.19.6 | 12q15-q21 | thyrotropin-releasing hormone |
| | | | | | degrading ectoenzyme |
| NPEPPS | M01.010 | 9520 | — | 17q21 | aminopeptidase puromycin sensitive |
| LNPEP | M01.011 | 4012 | 3.4.11.3 | 5q15 | leucyl/cystinyl aminopeptidase |
| RNPEP | M01.014 | 6051 | 3.4.11.6 | 1q32 | arginyl aminopeptidase |
| | | | | | (aminopeptidase B) |
| ERAP1 | M01.018 | 51752 | — | 5q15 | type 1 tumor necrosis factor receptor |
| | | | | | shedding aminopeptidase regulator |
| RNPEPL1 | M01.022 | 57140 | — | 2q37.3 | arginyl aminopeptidase |
| | | | | | (aminopeptidase B)-like 1 |
| ERAP2 | M01.023 | 64167 | — | 16 | leukocyte-derived arginine |
| | | | | | aminopeptidase |
| AQPEP | M01.027 | BG623101 | — | — | — |
| C9orf3 | M01.028 | 84909 | — | 9q22.32 | chromosome 9 open reading frame 3 |
| TAF2 | M01.972 | 6873 | — | 8q24.12 | TAF2 RNA polymerase II, TATA box |
| | | | | | binding protein (TBP)-associated |
| | | | | | factor, 150 kDa |
| ACE2 | M02.006 | 59272 | 3.4.15.1 | xp22 | angiotensin I converting enzyme |
| | | | | | (peptidyl-dipeptidase A) 2 |
| THOP1 | M03.001 | 7064 | 3.4.24.15 | 19q13.3 | thimet oligopeptidase 1 |
| NLN | M03.002 | 57486 | 3.4.24.16 | 5q12.3 | neurolysin (metallopeptidase M3 |
| | | | | | family) |
| MIPEP | M03.006 | 4285 | 3.4.24.59 | 13q12 | mitochondrial intermediate peptidase |
| LMLN | M08.003 | 89782 | 3.4.24.36 | 3q29 | leishmanolysin-like (metallopeptidase |
| | | | | | M8 family) |
| MMP1 | M10.001 | 4312 | 3.4.24.7 | 11q22.3 | matrix metalloproteinase 1 (interstitial |
| | | | | | collagenase) |
| MMP8 | M10.002 | 4317 | 3.4.24.34 | 11q22.3 | matrix metalloproteinase 8 (neutrophil |
| | | | | | collagenase) |
| MMP2 | M10.003 | 4313 | 3.4.24.24 | 16q13-q21 | matrix metalloproteinase 2 (gelatinase |
| | | | | | A, 72 kDa gelatinase, 72 kDa type IV |
| | | | | | collagenase) |
| MMP9 | M10.004 | 4318 | 3.4.24.35 | 20q11.2-q13.1 | matrix metalloproteinase 9 (gelatinase |
| | | | | | B, 92 kDa gelatinase, 92 kDa type IV |
| | | | | | collagenase) |
| MMP3 | M10.005 | 4314 | 3.4.24.17 | 11q22.3 | matrix metalloproteinase 3 |
| | | | | | (stromelysin 1, progelatinase) |
| MMP10 | M10.006 | 4319 | 3.4.24.22 | 11q22.3 | matrix metalloproteinase 10 |
| | | | | | (stromelysin 2) |
| MMP11 | M10.007 | 4320 | — | 22q11.23 | matrix metalloproteinase 11 |
| | | | | | (stromelysin 3) |
| MMP7 | M10.008 | 4316 | 3.4.24.23 | 11q21-q22 | matrix metalloproteinase 7 |
| | | | | | (matrilysin, uterine) |
| MMP12 | M10.009 | 4321 | — | 11q22.3 | matrix metalloproteinase 12 |
| | | | | | (macrophage elastase) |
| MMP13 | M10.013 | 4322 | — | 11q22.3 | matrix metalloproteinase 13 |
| | | | | | (collagenase 3) |
| MMP14 | M10.014 | 4323 | — | 14q11-q12 | matrix metalloproteinase 14 |
| | | | | | (membrane-inserted) |
| MMP15 | M10.015 | 4324 | — | 16q13-q21 | matrix metalloproteinase 15 |
| | | | | | (membrane-inserted) |
| MMP16 | M10.016 | 4325 | — | 8q21 | matrix metalloproteinase 16 |
| | | | | | (membrane-inserted) |
| MMP17 | M10.017 | 4326 | — | 12q24.3 | matrix metalloproteinase 17 |
| | | | | | (membrane-inserted) |
| MMP20 | M10.019 | 9313 | — | 11q22.3 | matrix metalloproteinase 20 |
| | | | | | (enamelysin) |
| MMP19 | M10.021 | 4327 | — | 12q14 | matrix metalloproteinase 19 |
| MMP23B | M10.022 | 8510 | — | 1p36.3 | matrix metalloproteinase 23B |
| MMP24 | M10.023 | 10893 | — | 20q11.2 | matrix metalloproteinase 24 |
| | | | | | (membrane-inserted) |
| MMP25 | M10.024 | 64386 | — | 16p13.3 | matrix metalloproteinase 25 |
| MMP21 | M10.026 | 118856 | — | 10q26.2 | matrix metalloproteinase 21 |
| MMP27 | M10.027 | 64066 | — | 11q24 | matrix metalloproteinase 27 |
| MMP26 | M10.029 | 56547 | — | 11p15 | matrix metalloproteinase 26 |
| MMP28 | M10.030 | 79148 | — | 17q11-q21.1 | matrix metalloproteinase 28 |
| MMP23A | M10.037 | 8511 | — | 1p36.3 | matrix metalloproteinase 23A |
| MMPL1 | M10.973 | 4328 | — | 16p13.3 | matrix metalloproteinase-like 1 |
| MEP1A | M12.002 | 4224 | 3.4.24.18 | 6p12-p11 | meprin A, alpha (PABA peptide |
| | | | | | hydrolase) |
| MEP1B | M12.004 | 4225 | 3.4.24.18 | 18q12.2-q12.3 | meprin A, beta |
| BMP1 | M12.005 | 649 | 3.4.24.19 | 8p21 | bone morphogenetic protein 1 |
| TLL1 | M12.016 | 7092 | — | 4q32-q33 | tolloid-like 1 |
| TLL2 | M12.018 | 7093 | — | 10q23-q24 | tolloid-like 2 |
| ADAMTS9 | M12.021 | 56999 | — | 3p14.3-p14.2 | a disintegrin-like and metalloprotease |
| | | | | | (reprolysin type) with |
| | | | | | thrombospondin type 1 motif, 9 |
| ADAMTS14 | M12.024 | 140766 | — | 10q2 | a disintegrin-like and metalloprotease |
| | | | | | (reprolysin type) with |
| | | | | | thrombospondin type 1 motif, 14 |
| ADAMTS15 | M12.025 | 170689 | — | 11q25 | a disintegrin-like and metalloprotease |
| | | | | | (reprolysin type) with |
| | | | | | thrombospondin type 1 motif, 15 |
| ADAMTS16 | M12.026 | 170690 | — | 5p15 | a disintegrin-like and metalloprotease |
| | | | | | (reprolysin type) with |
| | | | | | thrombospondin type 1 motif, 16 |
| ADAMTS17 | M12.027 | 170691 | — | 15q24 | a disintegrin-like and metalloprotease |
| | | | | | (reprolysin type) with |
| | | | | | thrombospondin type 1 motif, 17 |
| ADAMTS18 | M12.028 | 170692 | — | 16q23 | a disintegrin-like and metalloprotease |
| | | | | | (reprolysin type) with |
| | | | | | thrombospondin type 1 motif, 18 |
| ADAMTS19 | M12.029 | 171019 | — | 5q31 | a disintegrin-like and metalloprotease |
| | | | | | (reprolysin type) with |
| | | | | | thrombospondin type 1 motif, 19 |
| ADAM1 | M12.201 | 8759 | — | 12q24.12-q24.13 | a disintegrin and metalloproteinase |
| | | | | | domain 1 (fertilin alpha) pseudogene |
| ADAM8 | M12.208 | 101 | — | 10q26.3 | a disintegrin and metalloproteinase |
| | | | | | domain 8 |
| ADAM9 | M12.209 | 8754 | — | 8p11.23 | a disintegrin and metalloproteinase |
| | | | | | domain 9 (meltrin gamma) |
| ADAM10 | M12.210 | 102 | — | 15q22 | a disintegrin and metalloproteinase |
| | | | | | domain 10 |
| ADAM12 | M12.212 | 8038 | — | 10q26.3 | a disintegrin and metalloproteinase |
| | | | | | domain 12 (meltrin alpha) |
| ADAM19 | M12.214 | 8728 | — | 5q32-q33 | a disintegrin and metalloproteinase |
| | | | | | domain 19 (meltrin beta) |
| ADAM15 | M12.215 | 8751 | — | 1q21.3 | a disintegrin and metalloproteinase |
| | | | | | domain 15 (metargidin) |
| ADAM17 | M12.217 | 6868 | — | 2p25 | a disintegrin and metalloproteinase |
| | | | | | domain 17 (tumor necrosis factor, |
| | | | | | alpha, converting enzyme) |
| ADAM20 | M12.218 | 8748 | — | 14q24.1 | a disintegrin and metalloproteinase |
| | | | | | domain 20 |
| ADAMDEC1 | M12.219 | 27299 | — | 8p21.2 | ADAM-like, decysin 1 |
| ADAMTS3 | M12.220 | 9508 | — | 4q13.3 | a disintegrin-like and metalloprotease |
| | | | | | (reprolysin type) with |
| | | | | | thrombospondin type 1 motif, 3 |
| ADAMTS4 | M12.221 | 9507 | — | 1q21-q23 | a disintegrin-like and metalloprotease |
| | | | | | (reprolysin type) with |
| | | | | | thrombospondin type 1 motif, 4 |
| ADAMTS1 | M12.222 | 9510 | — | 21q21.2 | a disintegrin-like and metalloprotease |
| | | | | | (reprolysin type) with |
| | | | | | thrombospondin type 1 motif, 1 |
| ADAM28 | M12.224 | 10863 | — | 8p21.2 | a disintegrin and metalloproteinase |
| | | | | | domain 28 |
| ADAMTS5 | M12.225 | 11096 | — | 21q21.3 | a disintegrin-like and metalloprotease |
| | | | | | (reprolysin type) with |
| | | | | | thrombospondin type 1 motif, 5 |
| | | | | | (aggrecanase-2) |
| ADAMTS8 | M12.226 | 11095 | — | 11q25 | a disintegrin-like and metalloprotease |
| | | | | | (reprolysin type) with |
| | | | | | thrombospondin type 1 motif, 8 |
| ADAMTS6 | M12.230 | 11174 | — | 5q12 | a disintegrin-like and metalloprotease |
| | | | | | (reprolysin type) with |
| | | | | | thrombospondin type 1 motif, 6 |
| ADAMTS7 | M12.231 | 11173 | — | 15q24.2 | a disintegrin-like and metalloprotease |
| | | | | | (reprolysin type) with |
| | | | | | thrombospondin type 1 motif, 7 |
| ADAM30 | M12.232 | 11085 | — | 1p13-p11 | a disintegrin and metalloproteinase |
| | | | | | domain 30 |
| ADAM21 | M12.234 | 8747 | — | 14q24.1 | a disintegrin and metalloproteinase |
| | | | | | domain 21 |
| ADAMTS10 | M12.235 | 81794 | — | 19p13.3-p13.2 | a disintegrin-like and metalloprotease |
| | | | | | (reprolysin type) with |
| | | | | | thrombospondin type 1 motif, 10 |
| ADAMTS12 | M12.237 | 81792 | — | 5q35 | a disintegrin-like and metalloprotease |
| | | | | | (reprolysin type) with |
| | | | | | thrombospondin type 1 motif, 12 |
| ADAMTS13 | M12.241 | 11093 | — | 9q34 | a disintegrin-like and metalloprotease |
| | | | | | (reprolysin type) with |
| | | | | | thrombospondin type 1 motif, 13 |
| ADAM33 | M12.244 | 80332 | — | 20p13 | a disintegrin and metalloproteinase |
| | | | | | domain 33 |
| ASTL | M12.245 | 431705 | 3.4.24.21 | 2q11.1 | astacin-like metalloendopeptidase |
| | | | | | (M12 family) |
| HAMET | M12.245 | AJ537600 | — | — | — |
| ADAMTS20 | M12.246 | 80070 | — | 12q12 | a disintegrin-like and metalloprotease |
| | | | | | (reprolysin type) with |
| | | | | | thrombospondin type 1 motif, 20 |
| ADAMTS2 | M12.301 | 9509 | — | 5qter | a disintegrin-like and metalloprotease |
| | | | | | (reprolysin type) with |
| | | | | | thrombospondin type 1 motif, 2 |
| ADAM2 | M12.950 | 2515 | — | 8p11.2 | a disintegrin and metalloproteinase |
| | | | | | domain 2 (fertilin beta) |
| ADAM7 | M12.956 | 8756 | — | 8p21.2 | a disintegrin and metalloproteinase |
| | | | | | domain 7 |
| ADAM18 | M12.957 | 8749 | — | 8p11.22 | a disintegrin and metalloproteinase |
| | | | | | domain 18 |
| ADAM32 | M12.960 | 203102 | — | 8p11.23 | a disintegrin and metalloproteinase |
| | | | | | domain 32 |
| ADAM3A | M12.974 | 1587 | — | 8p21-p12 | a disintegrin and metalloproteinase |
| | | | | | domain 3a (cyritestin 1) |
| ADAM3B | M12.975 | 1596 | — | 16q12.1 | a disintegrin and metalloproteinase |
| | | | | | domain 3b (cyritestin 2) |
| ADAM11 | M12.976 | 4185 | — | 17q21.3 | a disintegrin and metalloproteinase |
| | | | | | domain 11 |
| ADAM22 | M12.978 | 53616 | — | 7q21 | a disintegrin and metalloproteinase |
| | | | | | domain 22 |
| ADAM23 | M12.979 | 8745 | — | 2q33 | a disintegrin and metalloproteinase |
| | | | | | domain 23 |
| ADAM29 | M12.981 | 11086 | — | 4q34 | a disintegrin and metalloproteinase |
| | | | | | domain 29 |
| MME | M13.001 | 4311 | 3.4.24.11 | 3q25.1-q25.2 | membrane metallo-endopeptidase |
| | | | | | (neutral endopeptidase, |
| | | | | | enkephalinase, CALLA, CD10) |
| ECE1 | M13.002 | 1889 | — | 1p36.1 | endothelin converting enzyme 1 |
| ECE2 | M13.003 | 9718 | — | 3q28-q29 | endothelin converting enzyme 2 |
| ECEL1 | M13.007 | 9427 | — | 2q36-q37 | endothelin converting enzyme-like 1 |
| MELL1 | M13.008 | 79258 | — | 1p36 | mel transforming oncogene-like 1 |
| KEL | M13.090 | 3792 | — | 7q33 | Kell blood group |
| PHEX | M13.091 | 5251 | — | xp22.2-p22.1 | phosphate regulating endopeptidase |
| | | | | | homolog, X-linked |
| | | | | | (hypophosphatemia, vitamin D |
| | | | | | resistant rickets) |
| CPA1 | M14.001 | 1357 | 3.4.17.1 | 7q32 | carboxypeptidase A1 (pancreatic) |
| CPA2 | M14.002 | 1358 | 3.4.17.15 | 7q32 | carboxypeptidase A2 (pancreatic) |
| CPB1 | M14.003 | 1360 | 3.4.17.2 | 3q24 | carboxypeptidase B1 (tissue) |
| CPN1 | M14.004 | 1369 | — | 10q24.2 | carboxypeptidase N, polypeptide 1, |
| | | | | | 50 kD |
| CPE | M14.005 | 1363 | 3.4.17.10 | 4q32.3 | carboxypeptidase E |
| CPM | M14.006 | 1368 | 3.4.17.12 | 12q14.3 | carboxypeptidase M |
| CPB2 | M14.009 | 1361 | — | 13q14.11 | carboxypeptidase B2 (plasma, |
| | | | | | carboxypeptidase U) |
| CPA3 | M14.010 | 1359 | 3.4.2.1 | 3q21-q25 | carboxypeptidase A3 (mast cell) |
| CPZ | M14.012 | 8532 | — | 4p16.1 | carboxypeptidase Z |
| CPA4 | M14.017 | 51200 | — | 7q32 | carboxypeptidase A4 |
| CPA6 | M14.018 | 57094 | — | 8q13.2 | carboxypeptidase A6 |
| CPA5 | M14.020 | 93979 | — | 7q32 | carboxypeptidase A5 |
| CPO | M14.021 | 130749 | — | 2q33.3 | carboxypeptidase O |
| AGBL3 | M14.026 | 340351 | — | 7q33 | hypothetical protein LOC340351 |
| AGBL4 | M14.027 | 84871 | — | 1p33 | hypothetical protein FLJ14442 |
| AGTPBP1 | M14.028 | 23287 | — | 9q21.33 | ATP/GTP binding protein 1 |
| AGBL2 | M14.029 | 79841 | — | 11p11.2 | hypothetical protein FLJ23598 |
| AEBP1 | M14.951 | 165 | — | 7p13 | AE binding protein 1 |
| CPXM | M14.952 | 56265 | — | 20p13-p12.3 | carboxypeptidase X (M14 family) |
| CPXM2 | M14.954 | 119587 | — | 10q26.13 | carboxypeptidase X (M14 family), |
| | | | | | member 2 |
| IDE | M16.002 | 3416 | — | 10q23-q25 | insulin-degrading enzyme |
| PMPCB | M16.003 | 9512 | — | 7q22-q32 | peptidase (mitochondrial processing) |
| | | | | | beta |
| NRD1 | M16.005 | 4898 | — | 1p32.2-p32.1 | nardilysin (N-arginine dibasic |
| | | | | | convertase) |
| PITRM1 | M16.009 | 10531 | — | 10p15.2 | pitrilysin metalloproteinase 1 |
| PMPCA | M16.971 | 23203 | — | 9q34.3 | peptidase (mitochondrial processing) |
| | | | | | alpha |
| UQCRC1 | M16.973 | 7384 | 1.10.2.2 | 3p21.3 | ubiquinol-cytochrome c reductase |
| | | | | | core protein I |
| UQCRC2 | M16.974 | 7385 | 1.10.2.2 | 16p12 | ubiquinol-cytochrome c reductase |
| | | | | | core protein II |
| AMPP | M16.976np | 133083 | — | 4q22.2-q22.3 | similar to PMPCA protein |
| LAP3 | M17.001 | 51056 | 3.4.11.1 | 4p15.32 | leucine aminopeptidase 3 |
| NPEPL1 | M17.006 | 79716 | — | 20q13.32 | aminopeptidase-like 1 |
| DNPEP | M18.002 | 23549 | — | 2q35 | aspartyl aminopeptidase |
| DPEP1 | M19.001 | 1800 | 3.4.13.11 | 16q24.3 | dipeptidase 1 (renal) |
| DPEP2 | M19.002 | 64174 | — | 16q22.1 | dipeptidase 2 |
| DPEP3 | M19.004 | 64180 | — | 16q22.1 | dipeptidase 3 |
| CNDP2 | M20.005 | 55748 | 3.4.13.18 | 18q22.3 | CNDP dipeptidase 2 |
| | | | | | (metallopeptidase M20 family) |
| CNDP1 | M20.006 | 84735 | — | 18q22.3 | carnosine dipeptidase 1 |
| | | | | | (metallopeptidase M20 family) |
| ACY1L2 | M20.971 | 135293 | — | 6q15 | aminoacylase 1-like 2 |
| ACY1 | M20.973 | 95 | 3.5.1.14 | 3p21.1 | aminoacylase 1 |
| OSGEP | M22.003 | 55644 | 3.4.24.57 | 14q11.2 | O-sialoglycoprotein endopeptidase |
| OSGEPL1 | M22.004 | 64172 | — | 2q32.2 | O-sialoglycoprotein endopeptidase- |
| | | | | | like 1 |
| METAP1 | M24.001 | 23173 | — | 4q23 | methionyl aminopeptidase 1 |
| METAP2 | M24.002 | 10988 | — | 12q22 | methionyl aminopeptidase 2 |
| XPNPEP2 | M24.005 | 7512 | 3.4.11.9 | xq25 | X-prolyl aminopeptidase |
| | | | | | (aminopeptidase P) 2, membrane- |
| | | | | | bound |
| PEPD | M24.007 | 5184 | 3.4.13.9 | 19q12-q13.2 | peptidase D |
| XPNPEP1 | M24.009 | 7511 | 3.4.11.9 | 10q25.3 | X-prolyl aminopeptidase |
| | | | | | (aminopeptidase P) 1, soluble |
| XPNPEP3 | M24.026 | 63929 | — | 22q13.31-q13.33 | hypothetical protein LOC63929 |
| MAP1D | M24.028 | 254042 | — | 2q31.1 | methionine aminopeptidase 1D |
| PA2G4 | M24.973 | 5036 | — | 12q13 | proliferation-associated 2G4, 38 kDa |
| SUPT16H | M24.974 | 11198 | — | 14q11.2 | suppressor of Ty 16 homolog (S. cerevisiae) |
| FOLH1 | M28.010 | 2346 | — | 11p11.2 | folate hydrolase (prostate-specific |
| | | | | | membrane antigen) 1 |
| NAALADL1 | M28.011 | 10004 | — | 11q12 | N-acetylated alpha-linked acidic |
| | | | | | dipeptidase-like 1 |
| NAALAD2 | M28.012 | 10003 | — | 11q14.3-q21 | N-acetylated alpha-linked acidic |
| | | | | | dipeptidase 2 |
| PGCP | M28.014 | 10404 | — | 8q22.2 | plasma glutamate carboxypeptidase |
| QPCTL | M28.016 | 54814 | — | 19q13.32 | glutaminyl-peptide cyclotransferase- |
| | | | | | like |
| KIAA1815 | M28.018 | 79956 | — | 9p24 | KIAA1815 |
| TFRC | M28.972 | 7037 | — | 3q29 | transferrin receptor (p90, CD71) |
| TFR2 | M28.973 | 7036 | — | 7q22 | transferrin receptor 2 |
| QPCT | M28.974 | 25797 | 2.3.2.5 | 2p22.2 | glutaminyl-peptide cyclotransferase |
| | | | | | (glutaminyl cyclase) |
| NAALADL2 | M28.975 | 254827 | — | 3q26.31 | N-acetylated alpha-linked acidic |
| | | | | | dipeptidase 2 |
| NCLN | M28.978 | 56926 | — | 19p13.3 | nicalin homolog (zebrafish) |
| CAD | M38.972 | 790 | 2.1.3.2, | 2p22-p21 | carbamoyl-phosphate synthetase 2, |
| | | | 3.5.2.— | | aspartate transcarbamylase, and |
| | | | | | dihydroorotase |
| DPYS | M38.973 | 1807 | — | 8q22 | dihydropyrimidinase |
| CRMP1 | M38.974 | 1400 | — | 4p16.1-p15 | collapsin response mediator protein 1 |
| DPYSL2 | M38.975 | 1808 | — | 8p22-p21 | dihydropyrimidinase-like 2 |
| DPYSL3 | M38.976 | 1809 | — | 5q32 | dihydropyrimidinase-like 3 |
| DPYSL4 | M38.977 | 10570 | — | 10q26 | dihydropyrimidinase-like 4 |
| DPYSL5 | M38.978 | 56896 | — | 2p23.3 | dihydropyrimidinase-like 5 |
| GDA | M38.981 | 9615 | — | 9q21.11-21.33 | guanine deaminase |
| YME1L1 | M41.004 | 10730 | — | 10p14 | YME1-like 1 (S. cerevisiae) |
| SPG7 | M41.006 | 6687 | — | 16q24.3 | spastic paraplegia 7, paraplegin (pure |
| | | | | | and complicated autosomal recessive) |
| AFG3L2 | M41.007 | 10939 | — | 18p11 | AFG3 ATPase family gene 3-like 2 |
| | | | | | (yeast) |
| AFG3L1 | M41.010 | 172 | — | 16q24.3 | AFG3 ATPase family gene 3-like 1 |
| | | | | | (yeast) |
| PAPPA | M43.004 | 5069 | — | 9q33.2 | pregnancy-associated plasma protein |
| | | | | | A, pappalysin 1 |
| PAPPA2 | M43.005 | 60676 | — | 1q23-q25 | pappalysin 2 |
| CHMP1A | M47.001 | 5119 | — | 16q24.3 | procollagen (type III) N- |
| | | | | | endopeptidase |
| ZMPSTE24 | M48.003 | 10269 | — | 1p34 | zinc metallopeptidase (STE24 |
| | | | | | homolog, yeast) |
| OMA1 | M48.017 | 115209 | — | 1p32.2-p32.1 | OMA1 homolog, zinc |
| | | | | | metallopeptidase (S. cerevisiae) |
| DPP3 | M49.001 | 10072 | 3.4.14.4 | 11q12-q13.1 | dipeptidylpeptidase 3 |
| MBTPS2 | M50.001 | 51360 | — | xp22.1-p22.2 | membrane-bound transcription factor |
| | | | | | protease, site 2 |
| PSMD14 | M67.001 | 10213 | — | 2q24.2 | proteasome (prosome, macropain) |
| | | | | | 26S subunit, non-ATPase, 14 |
| COPS5 | M67.002 | 10987 | — | 8q13.2 | COP9 constitutive photomorphogenic |
| | | | | | homolog subunit 5 (Arabidopsis) |
| STAMBPL1 | M67.003 | 57559 | — | 10q23.31 | associated molecule with the SH3 |
| | | | | | domain of STAM (AMSH) like |
| | | | | | protein |
| CXorf53 | M67.004 | 79184 | — | xq28 | chromosome X open reading frame 53 |
| MYSM1 | M67.005 | 114803 | — | 1p32.1 | KIAA1915 protein |
| STAMBP | M67.006 | 10617 | — | 2p13.1 | STAM binding protein |
| EIF3S3 | M67.971 | 8667 | — | 8q24.11 | eukaryotic translation initiation factor |
| | | | | | 3, subunit 3 gamma, 40 kDa |
| COPS6 | M67.972 | 10980 | — | 7q22.1 | COP9 constitutive photomorphogenic |
| | | | | | homolog subunit 6 (Arabidopsis) |
| PSMD7 | M67.973 | 5713 | — | 16q23-q24 | proteasome (prosome, macropain) |
| | | | | | 26S subunit, non-ATPase, 7 (Mov34 |
| | | | | | homolog) |
| EIF3F | M67.974 | 8665 | — | 11p15.4 | eukaryotic translation initiation factor |
| | | | | | 3, subunit 5 epsilon, 47 kDa |
| EIF3FP | M67.975 | 83880 | — | 13p13 | IFP38 |
| MPND | M67.xxx | 84954 | — | 19p13.3 | hypothetical protein FLJ14981 |
| PRPF8 | M67.xxxnp | 10594 | — | 17p13.3 | PRP8 pre-mRNA processing factor 8 |
| | | | | | homolog (yeast) |
| ASPA | Mx2.xxxnp | 443 | 3.5.1.15 | 17pter-p13 | aspartoacylase (aminoacylase 2, |
| | | | | | Canavan disease) |
| ACY3 | Mx2.xxxnp | 91703 | — | 11q13.2 | aspartoacylase (aminocyclase) 3 |
| ACE | XM02-001 | 1636 | 3.4.15.1 | 17q23 | angiotensin I converting enzyme |
| | | | | | (peptidyl-dipeptidase A) 1 |
| CPD | XM14-001 | 1362 | — | 17p11.1-q11.2 | carboxypeptidase D |
| GZMB | S01.010 | 3002 | — | 14q11.2 | granzyme B (granzyme 2, cytotoxic |
| | | | | | T-lymphocyte-associated serine |
| | | | | | esterase 1) |
| PRSS21 | S01.011 | 10942 | — | 16p13.3 | protease, serine, 21 (testisin) |
| TPSAB1 | S01.015 | 7177 | — | 16p13.3 | tryptase alpha/beta 1 |
| TPSB2 | S01.015 | 64499 | — | 16p13.3 | tryptase beta 2 |
| KLK5 | S01.017 | 25818 | — | 19q13.3-q13.4 | kallikrein 5 |
| CORIN | S01.019 | 10699 | — | 4p13-p12 | corin, serine protease |
| KLK12 | S01.020 | 43849 | — | 19q13.3-q13.4 | kallikrein 12 |
| TMPRSS11E | S01.021 | 28983 | — | 4q13.2 | DESC1 protein |
| TPSG1 | S01.028 | 25823 | — | 16p13.3 | tryptase gamma 1 |
| KLK14 | S01.029 | 43847 | — | 19q13.3-q13.4 | kallikrein 14 |
| HABP2 | S01.033 | 3026 | — | 10q25.3 | hyaluronan binding protein 2 |
| TMPRSS4 | S01.034 | 56649 | — | 11q23.3 | transmembrane protease, serine 4 |
| TMPRSS11D | S01.047 | 9407 | — | 4q13.2 | airway trypsin-like protease |
| TPSD1 | S01.054 | 23430 | — | 16p13.3 | tryptase delta 1 |
| TMPRSS7 | S01.072 | 344805 | — | 3q13.2 | transmembrane serine protease 7 |
| PRSS27 | S01.074 | 83886 | — | 16p13.3 | pancreasin |
| PRSS33 | S01.075 | 260429 | — | 16p13.3 | protease, serine, 33 |
| TESSP1 | S01.076 | BN000124 | — | — | — |
| TMPRSS3 | S01.079 | 64699 | — | 21q22.3 | transmembrane protease, serine 3 |
| KLK15 | S01.081 | 55554 | — | 19q13.41 | kallikrein 15 |
| TMPRSS13 | S01.087 | 84000 | — | 11q23 | mosaic serine protease |
| PRSS1 | S01.127 | 5644 | 3.4.21.4 | 7q34 | protease, serine, 1 (trypsin 1) |
| ELA2 | S01.131 | 1991 | 3.4.21.37 | 19p13.3 | elastase 2, neutrophil |
| MASP1 | S01.132 | 5648 | — | 3q27-q28 | mannan-binding lectin serine protease |
| | | | | | 1 (C4/C2 activating component of Ra- |
| | | | | | reactive factor) |
| CTSG | S01.133 | 1511 | — | 14q11.2 | cathepsin G |
| PRTN3 | S01.134 | 5657 | — | 19p13.3 | proteinase 3 (serine proteinase, |
| | | | | | neutrophil, Wegener granulomatosis |
| | | | | | autoantigen) |
| GZMA | S01.135 | 3001 | — | 5q11-q12 | granzyme A (granzyme 1, cytotoxic |
| | | | | | T-lymphocyte-associated serine |
| | | | | | esterase 3) |
| GZMM | S01.139 | 3004 | — | 19p13.3 | granzyme M (lymphocyte met-ase 1) |
| CMA1 | S01.140 | 1215 | 3.4.21.39 | 14q11.2 | chymase 1, mast cell |
| GZMK | S01.146 | 3003 | — | 5q11-q12 | granzyme K (serine protease, |
| | | | | | granzyme 3; tryptase II) |
| GZMH | S01.147 | 2999 | — | 14q11.2 | granzyme H (cathepsin G-like 2, |
| | | | | | protein h-CCPX) |
| CTRB1 | S01.152 | 1504 | 3.4.21.1 | 16q23-q24.1 | chymotrypsinogen B1 |
| ELA1 | S01.153 | 1990 | 3.4.21.36 | 12q13 | elastase 1, pancreatic |
| ELA3A | S01.154 | 10136 | — | 1p36.12 | elastase 3A, pancreatic (protease E) |
| ELA2A | S01.155 | 63036 | — | 1p36.21 | elastase 2A |
| PRSS7 | S01.156 | 5651 | — | 21q21.1 | protease, serine, 7 (enterokinase) |
| CTRC | S01.157 | 11330 | — | 1p36.21 | chymotrypsin C (caldecrin) |
| PRSS8 | S01.159 | 5652 | — | 16p11.2 | protease, serine, 8 (prostasin) |
| KLK1 | S01.160 | 3816 | 3.4.21.35 | 19q13.3 | kallikrein 1, renal/pancreas/salivary |
| KLK2 | S01.161 | 3817 | 3.4.21.35 | 19q13.41 | kallikrein 2, prostatic |
| KLK3 | S01.162 | 354 | — | 19q13.41 | kallikrein 3, (prostate specific antigen) |
| PRSS3 | S01.174 | 5646 | 3.4.21.4 | 9p11.2 | protease, serine, 3 (mesotrypsin) |
| C1RL | S01.189 | 51279 | — | 12p13.31 | complement component 1, r |
| | | | | | subcomponent-like |
| DF | S01.191 | 1675 | — | 19p13.3 | D component of complement |
| | | | | | (adipsin) |
| C1R | S01.192 | 715 | 3.4.21.41 | 12p13 | complement component 1, r |
| | | | | | subcomponent |
| C1S | S01.193 | 716 | 3.4.21.42 | 12p13 | complement component 1, s |
| | | | | | subcomponent |
| C2 | S01.194 | 717 | — | 6p21.3 | complement component 2 |
| BF | S01.196 | 629 | 3.4.21.47 | 6p21.3 | B-factor, properdin |
| IF | S01.199 | 3426 | 3.4.21.45 | 4q25 | I factor (complement) |
| ELA3B | S01.205 | 23436 | — | 1p36.12 | elastase 3B, pancreatic |
| ELA2B | S01.206 | 51032 | — | 1p36.21 | elastase 2B |
| F12 | S01.211 | 2161 | 3.4.21.38 | 5q33-qter | coagulation factor XII (Hageman |
| | | | | | factor) |
| KLKB1 | S01.212 | 3818 | — | 4q34-q35 | kallikrein B, plasma (Fletcher factor) 1 |
| F11 | S01.213 | 2160 | 3.4.21.27 | 4q35 | coagulation factor XI (plasma |
| | | | | | thromboplastin antecedent) |
| F9 | S01.214 | 2158 | 3.4.21.22 | xq27.1-q27.2 | coagulation factor IX (plasma |
| | | | | | thromboplastic component, Christmas |
| | | | | | disease, hemophilia B) |
| F7 | S01.215 | 2155 | — | 13q34 | coagulation factor VII (serum |
| | | | | | prothrombin conversion accelerator) |
| F10 | S01.216 | 2159 | 3.4.21.6 | 13q34 | coagulation factor X |
| F2 | S01.217 | 2147 | 3.4.21.5 | 11p11-q12 | coagulation factor II (thrombin) |
| PROC | S01.218 | 5624 | — | 2q13-q14 | protein C (inactivator of coagulation |
| | | | | | factors Va and VIIIa) |
| ACR | S01.223 | 49 | 3.4.21.10 | 22q13.33 | acrosin |
| HPN | S01.224 | 3249 | — | 19q11-q13.2 | hepsin (transmembrane protease, |
| | | | | | serine 1) |
| HGFAC | S01.228 | 3083 | 3.4.21.— | 4p16 | HGF activator |
| MASP2 | S01.229 | 10747 | — | 1p36.3-p36.2 | mannan-binding lectin serine protease 2 |
| PLAU | S01.231 | 5328 | 3.4.21.31 | 10q24 | plasminogen activator, urokinase |
| PLAT | S01.232 | 5327 | — | 8p12 | plasminogen activator, tissue |
| PLG | S01.233 | 5340 | — | 6q26 | plasminogen |
| KLK6 | S01.236 | 5653 | — | 19q13.3 | kallikrein 6 (neurosin, zyme) |
| PRSS12 | S01.237 | 8492 | — | 4q28.1 | protease, serine, 12 (neurotrypsin, |
| | | | | | motopsin) |
| KLK8 | S01.244 | 11202 | — | 19q13.3-q13.4 | kallikrein 8 (neuropsin/ovasin) |
| KLK10 | S01.246 | 5655 | — | 19q13.3-q13.4 | kallikrein 10 |
| TMPRSS2 | S01.247 | 7113 | — | 21q22.3 | transmembrane protease, serine 2 |
| KLK4 | S01.251 | 9622 | — | 19q13.41 | kallikrein 4 (prostase, enamel matrix, |
| | | | | | prostate) |
| PRSS22 | S01.252 | 64063 | — | 16p13.3 | protease, serine, 22 |
| CTRL | S01.256 | 1506 | — | 16q22.1 | chymotrypsin-like |
| KLK11 | S01.257 | 11012 | — | 19q13.3-q13.4 | kallikrein 11 |
| PRSS2 | S01.258 | 5645 | — | 7q34 | protease, serine, 2 (trypsin 2) |
| PRSS11 | S01.277 | 5654 | — | 10q26.3 | protease, serine, 11 (IGF binding) |
| PRSS25 | S01.278 | 27429 | — | 2p12 | protease, serine, 25 |
| HTRA3 | S01.284 | 94031 | — | 4p16.1 | HtrA serine peptidase 3 |
| HTRA4 | S01.285 | 203100 | — | 8p11.13 | HtrA serine peptidase 4 |
| TYSND1 | S01.286 | 219743 | — | 10q22.1 | trypsin domain containing 1 |
| TMPRSS12 | S01.291 | 283471 | — | 12q13.12 | hypothetical protein MGC57341 |
| TMPRSS11A | S01.292 | 339967 | — | 4q13.2 | epidermal type II transmembrane |
| | | | | | serine protease |
| HATL1 | S01.292 | BN000133 | — | — | — |
| TMPRSS8 | S01.298 | AJ488946 | — | — | — |
| KLK7 | S01.300 | 5650 | — | 19q13.41 | kallikrein 7 (chymotryptic, stratum |
| | | | | | corneum) |
| ST14 | S01.302 | 6768 | — | 11q24-q25 | suppression of tumorigenicity 14 |
| | | | | | (colon carcinoma, matriptase, epithin) |
| KLK13 | S01.306 | 26085 | — | 19q13.3-q13.4 | kallikrein 13 |
| KLK9 | S01.307 | 23579 | — | — | — |
| TMPRSS6 | S01.308 | 164656 | — | 22q12.3-q13.1 | transmembrane protease, serine 6 |
| PRSS23 | S01.309 | 11098 | — | 11q14.1 | protease, serine, 23 |
| TMPRSS5 | S01.313 | 80975 | — | 11q | transmembrane protease, serine 5 |
| | | | | | (spinesin) |
| TESSP2 | S01.317 | AJ544583 | — | — | — |
| MPN2 | S01.318 | BN000131 | — | — | — |
| PRSSL1 | S01.319 | 400668 | — | 19p13.3 | protease, serine-like 1 |
| OVCH2 | S01.320 | 341277 | — | 11p15.4 | oviductin protease |
| OVTN | S01.320 | BN000130 | — | — | — |
| TMPRSS11F | S01.321 | 389208 | — | 4q13.2 | FLJ16046 protein |
| OVCH1 | S01.322 | 341350 | — | 12p11.22 | ovochymase 1 |
| OVCH | S01.322 | BN000128 | — | — | — |
| TMPRSS9 | S01.357 | 360200 | — | 19p13.3 | transmembrane serine protease 9 |
| TMPRSS11B | S01.365 | 132724 | — | 4q13.2 | hypothetical protein |
| | | | | | DKFZp686L1818 |
| PRSS36 | S01.414 | 146547 | — | 16p11.2 | polyserase-2 |
| KLKBL2 | S01.415 | 203074 | — | 8p23.1 | tryptophan/serine protease |
| TESSP5 | S01.968np | BN000137 | — | — | — |
| AZU1 | S01.971 | 566 | — | 19p13.3 | azurocidin 1 (cationic antimicrobial |
| | | | | | protein 37) |
| HP | S01.972 | 3240 | — | 16q22.1 | haptoglobin |
| HPR | S01.974 | 3250 | — | 16q22.1 | haptoglobin-related protein |
| MST1 | S01.975 | 4485 | — | 3p21 | macrophage stimulating 1 (hepatocyte |
| | | | | | growth factor-like) |
| HGF | S01.976 | 3082 | — | 7q21.1 | hepatocyte growth factor (hepapoietin |
| | | | | | A; scatter factor) |
| PROZ | S01.979 | 8858 | — | 13q34 | protein Z, vitamin K-dependent |
| | | | | | plasma glycoprotein |
| TRYX2 | S01.989np | 136242 | — | 7q34 | similar to RIKEN cDNA 1700016G05 |
| KLKBL4 | S01.992np | 221191 | — | 16q21 | hypothetical protein FLJ25339 |
| TSP50 | S01.993np | 29122 | — | 3p14-p12 | testes-specific protease 50 |
| PRSS35 | S01.994 | 167681 | — | 6q14.2 | protease, serine, 35 |
| PROCL | S01.998np | 25891 | — | 11p13 | regeneration associated muscle |
| | | | | | protease |
| LPA | S01.999 | 4018 | — | 6q26-q27 | lipoprotein, Lp(a) |
| KLKP1 | S01.P08 | 606293 | — | 19q13.41 | kallikrein pseudogene 1 |
| VKORC1 | S01.xxx | 79001 | — | 16p11.2 | vitamin K epoxide reductase complex, |
| | | | | | subunit 1 |
| ESSPL | S01.xxx | BN000134 | — | — | — |
| PRSS7L | S01.xxx | BQ638967 | — | — | — |
| TMPRSS7 | S01.xxx | BN000125 | — | — | — |
| PCSK9 | S08.039 | 255738 | — | 1p32.3 | proprotein convertase subtilisin/kexin |
| | | | | | type 9 |
| MBTPS1 | S08.063 | 8720 | — | 16q24 | membrane-bound transcription factor |
| | | | | | protease, site 1 |
| FURIN | S08.071 | 5045 | — | 15q26.1 | furin (paired basic amino acid |
| | | | | | cleaving enzyme) |
| PCSK1 | S08.072 | 5122 | — | 5q15-q21 | proprotein convertase subtilisin/kexin |
| | | | | | type 1 |
| PCSK2 | S08.073 | 5126 | — | 20p11.2 | proprotein convertase subtilisin/kexin |
| | | | | | type 2 |
| PCSK4 | S08.074 | 54760 | — | 19p13.3 | proprotein convertase subtilisin/kexin |
| | | | | | type 4 |
| PCSK6 | S08.075 | 5046 | — | 15q26 | proprotein convertase subtilisin/kexin |
| | | | | | type 6 |
| PCSK5 | S08.076 | 5125 | — | 9q21.3 | proprotein convertase subtilisin/kexin |
| | | | | | type 5 |
| PCSK7 | S08.077 | 9159 | — | 11q23-q24 | proprotein convertase subtilisin/kexin |
| | | | | | type 7 |
| TPP2 | S08.090 | 7174 | 3.4.14.10 | 13q32-q33 | tripeptidyl peptidase II |
| PREP | S09.001 | 5550 | 3.4.21.26 | 6q22 | prolyl endopeptidase |
| DPP4 | S09.003 | 1803 | 3.4.14.5 | 2q24.3 | dipeptidylpeptidase 4 (CD26, |
| | | | | | adenosine deaminase complexing |
| | | | | | protein 2) |
| APEH | S09.004 | 327 | 3.4.19.1 | 3p21.31 | N-acylaminoacyl-peptide hydrolase |
| FAP | S09.007 | 2191 | — | 2q23 | fibroblast activation protein, alpha |
| PREPL | S09.015 | 9581 | — | 2p22.1 | putative prolyl oligopeptidase |
| DPP8 | S09.018 | 54878 | — | 15q22 | dipeptidylpeptidase 8 |
| DPP9 | S09.019 | 91039 | — | 19p13.3 | dipeptidylpeptidase 9 |
| C13orf6 | S09.051 | 84945 | — | 13q33.3 | chromosome 13 open reading frame 6 |
| C19orf27 | S09.052 | 81926 | — | 19p13.3 | chromosome 19 open reading frame |
| | | | | | 27 |
| FAM108C1 | S09.053 | 58489 | — | 15q25.1 | hypothetical protein from |
| | | | | | EUROIMAGE 588495 |
| C20orf22 | S09.054 | 26090 | — | 20p11.21 | chromosome 20 open reading frame |
| | | | | | 22 |
| C9orf77 | S09.055 | 51104 | — | 9q21.13 | chromosome 9 open reading frame 77 |
| C14orf29 | S09.061 | 145447 | — | 14q22.1 | chromosome 14 open reading frame |
| | | | | | 29 |
| ABHD10 | S09.062 | 55347 | — | 3q13.2 | abhydrolase domain containing 10 |
| BAT5 | S09.065 | 7920 | — | 6p21.3 | HLA-B associated transcript 5 |
| DPP6 | S09.973 | 1804 | — | 7q36.2 | dipeptidylpeptidase 6 |
| DPP10 | S09.974 | 57628 | — | 2q14.1 | dipeptidylpeptidase 10 |
| C20orf135 | S09.976 | 140701 | — | 20q13.33 | chromosome 20 open reading frame |
| | | | | | 135 |
| AFMID | S09.977 | 125061 | 3.5.1.9 | 17q25.3 | arylformamidase |
| TG | S09.978 | 7038 | — | 8q24.2-q24.3 | thyroglobulin |
| ACHE | S09.979 | 43 | 3.1.1.7 | 7q22 | acetylcholinesterase (YT blood group) |
| BCHE | S09.980 | 590 | 3.1.1.8 | 3q26.1-q26.2 | butyrylcholinesterase |
| CES1 | S09.982 | 1066 | 3.1.1.1 | 16q13-q22.1 | carboxylesterase 1 |
| | | | | | (monocyte/macrophage serine |
| | | | | | esterase 1) |
| CES3 | S09.983 | 23491 | — | 16 | carboxylesterase 3 (brain) |
| CES2 | S09.984 | 8824 | — | 16q22.1 | carboxylesterase 2 (intestine, liver) |
| CEL | S09.985 | 1056 | 3.1.1.3, | 9q34.3 | carboxyl ester lipase (bile salt- |
| | | | 3.1.1.13 | | stimulated lipase) |
| CES4 | S09.986 | 51716 | — | 16q12.2 | carboxylesterase 4-like |
| NLGN3 | S09.987 | 54413 | — | xq13.1 | neuroligin 3 |
| NLGN4X | S09.988 | 57502 | — | xp22.32-p22.31 | neuroligin 4, X-linked |
| NLGN4Y | S09.989 | 22829 | — | yq11.221 | neuroligin 4, Y-linked |
| ESD | S09.990 | 2098 | 3.1.1.1 | 13q14.1-q14.2 | esterase D/formylglutathione |
| | | | | | hydrolase |
| AADAC | S09.991 | 13 | — | 3q21.3-q25.2 | arylacetamide deacetylase (esterase) |
| AADACL1 | S09.992 | 57552 | — | 3q26.31 | KIAA1363 protein |
| LIPE | S09.993 | 3991 | 3.1.1.— | 19q13.2 | lipase, hormone-sensitive |
| NLGN1 | S09.994 | 22871 | — | 3q26.31 | neuroligin 1 |
| NLGN2 | S09.995 | 57555 | — | 17p13.1 | neuroligin 2 |
| PPGB | S10.002 | 5476 | — | 20q13.1 | protective protein for beta- |
| | | | | | galactosidase (galactosialidosis) |
| CPVL | S10.003 | 54504 | — | 7p15-p14 | carboxypeptidase, vitellogenic-like |
| SCPEP1 | S10.013 | 59342 | — | 17q23.2 | serine carboxypeptidase 1 |
| LACTB | S12.004 | 114294 | — | 15q22.1 | lactamase, beta |
| CLPP | S14.003 | 8192 | — | 19p13.3 | ClpP caseinolytic protease, ATP- |
| | | | | | dependent, proteolytic subunit |
| | | | | | homolog (E. coli) |
| PRSS15 | S16.002 | 9361 | — | 19p13.2 | protease, serine, 15 |
| LONP2 | S16.006 | 83752 | — | 16q12.1 | peroxisomal lon protease |
| SEC11L1 | S26.009 | 23478 | — | 15q25.3 | SEC11-like 1 (S. cerevisiae) |
| SEC11L3 | S26.010 | 90701 | — | 18q21.32 | SEC11-like 3 (S. cerevisiae) |
| IMMP2L | S26.012 | 83943 | — | 7q31 | IMP2 inner mitochondrial membrane |
| | | | | | protease-like (S. cerevisiae) |
| IMMP1L | S26.013 | 196294 | — | 11p13 | hypothetical protein FLJ25059 |
| FREM1 | S26.xxx | 158326 | — | 9p22.3 | FRAS1 related extracellular matrix 1 |
| PRCP | S28.001 | 5547 | — | 11q14 | prolylcarboxypeptidase |
| | | | | | (angiotensinase C) |
| DPP7 | S28.002 | 29952 | — | 9q34.3 | dipeptidylpeptidase 7 |
| PRSS16 | S28.003 | 10279 | — | 6p21 | protease, serine, 16 (thymus) |
| ABHD8 | S33.011 | 79575 | — | 19p13.11 | abhydrolase domain containing 8 |
| SERHL | S33.012 | 253190 | — | 22q13 | kraken-like |
| ABHD4 | S33.013 | 63874 | — | 14q11.2 | abhydrolase domain containing 4 |
| EPHX1 | S33.971 | 2052 | 3.3.2.3 | 1q42.1 | epoxide hydrolase 1, microsomal |
| | | | | | (xenobiotic) |
| MEST | S33.972 | 4232 | — | 7q32 | mesoderm specific transcript homolog |
| | | | | | (mouse) |
| EPHX2 | S33.973 | 2053 | — | 8p21-p12 | epoxide hydrolase 2, cytoplasmic |
| ABHD7 | S33.974 | 253152 | — | 1p22.1 | abhydrolase domain containing 7 |
| ABHD5 | S33.975 | 51099 | — | 3p21 | abhydrolase domain containing 5 |
| ABHD11 | S33.976 | 83451 | — | 7q11.23 | abhydrolase domain containing 11 |
| ABHD6 | S33.977 | 57406 | — | 3p14.3 | abhydrolase domain containing 6 |
| ABHD9 | S33.978 | 79852 | — | 19p13.12 | abhydrolase domain containing 9 |
| MGLL | S33.980 | 11343 | — | 3q21.3 | monoglyceride lipase |
| ABHD14A | S33.981 | 25864 | — | 3p21.1 | DKFZP564O243 protein |
| BPHL | S33.982 | 670 | — | 6p25 | biphenyl hydrolase-like (serine |
| | | | | | hydrolase; breast epithelial mucin- |
| | | | | | associated antigen) |
| NDRG4 | S33.986 | 65009 | — | 16q21-q22.1 | NDRG family member 4 |
| NDRG3 | S33.987 | 57446 | — | 20q11.21-q11.23 | NDRG family member 3 |
| NDRG1 | S33.988 | 10397 | — | 8q24.3 | N-myc downstream regulated gene 1 |
| RBP3 | S41.950 | 5949 | — | 10q11.2 | retinol binding protein 3, interstitial |
| TPP1 | S53.003 | 1200 | — | 11p15 | tripeptidyl peptidase I |
| RHBDL2 | S54.002 | 54933 | — | 1p34.3 | rhomboid, veinlet-like 2 (Drosophila) |
| RHBDL1 | S54.005 | 9028 | — | 16p13.3 | rhomboid, veinlet-like 1 (Drosophila) |
| RHBDL4 | S54.006 | 162494 | — | 17q11.2 | rhomboid, veinlet-like 4 (Drosophila) |
| PSARL | S54.009 | 55486 | — | 3q27.1 | presenilin associated, rhomboid-like |
| RHBDF1 | S54.952 | 64285 | — | 16p13.3 | rhomboid family 1 (Drosophila) |
| RHBDL6 | S54.953 | 79651 | — | 17q25.1 | rhomboid, veinlet-like 6 (Drosophila) |
| RHBDD2 | S54.955 | 57414 | — | 7q11.23 | rhomboid, veinlet-like 7 (Drosophila) |
| RHBDD1 | S54.xxx | 84236 | — | 2q36.3 | hypothetical protein DKFZp547E052 |
| RHBDL7 | S54.xxxnp | AC005067 | — | — | — |
| NUP98 | S59.001 | 4928 | — | 11p15.5 | nucleoporin 98 kDa |
| LTF | S60.001 | 4057 | — | 3q21-q23 | lactotransferrin |
| TF | S60.972 | 7018 | — | 3q22.1 | transferrin |
| MFI2 | S60.973 | 4241 | — | 3q28-q29 | antigen p97 (melanoma associated) |
| | | | | | identified by monoclonal antinodies |
| | | | | | 133.2 and 96.5 |
| EMR2 | S63.001 | 30817 | — | 19p13.1 | egf-like module containing, mucin- |
| | | | | | like, hormone receptor-like 2 |
| CD97 | S63.002 | 976 | — | 19p13 | CD97 antigen |
| EMR3 | S63.003 | 84658 | — | 19p13.1 | egf-like module containing, mucin- |
| | | | | | like, hormone receptor-like 3 |
| EMR1 | S63.004 | 2015 | — | 19p13.3 | egf-like module containing, mucin- |
| | | | | | like, hormone receptor-like 1 |
| EMR4 | S63.008 | 326342 | — | 19p13.3 | egf-like module containing, mucin- |
| | | | | | like, hormone receptor-like 4 |
| CELSR2 | S63.009 | 1952 | — | 1p21 | cadherin, EGF LAG seven-pass G- |
| | | | | | type receptor 2 (flamingo homolog, |
| | | | | | Drosophila) |
| RELN | Sx1.xxx | 5649 | — | 7q22 | reelin |
| HSP90B1 | Sx2.xxx | 7184 | — | 12q24.2-q24.3 | tumor rejection antigen (gp96) 1 |
| HSP90AA1 | Sx2.xxxnp | 3320 | — | 14q32.33 | heat shock 90 kDa protein 1, alpha |
| HSP90AB1 | Sx2.xxxnp | 3326 | — | 6p12 | heat shock 90 kDa protein 1, beta |
| TRAP1 | Sx2.xxxnp | 10131 | — | 16p13.3 | TNF receptor-associated protein 1 |
| PSMB6 | T01.010 | 5694 | — | 17p13 | proteasome (prosome, macropain) |
| | | | | | subunit, beta type, 6 |
| PSMB7 | T01.011 | 5695 | — | 9q34.11-q34.12 | proteasome (prosome, macropain) |
| | | | | | subunit, beta type, 7 |
| PSMB5 | T01.012 | 5693 | — | 14q11.2 | proteasome (prosome, macropain) |
| | | | | | subunit, beta type, 5 |
| PSMB9 | T01.013 | 5698 | — | 6p21.3 | proteasome (prosome, macropain) |
| | | | | | subunit, beta type, 9 (large |
| | | | | | multifunctional protease 2) |
| PSMB10 | T01.014 | 5699 | — | 16q22.1 | proteasome (prosome, macropain) |
| | | | | | subunit, beta type, 10 |
| PSMB8 | T01.015 | 5696 | — | 6p21.3 | proteasome (prosome, macropain) |
| | | | | | subunit, beta type, 8 (large |
| | | | | | multifunctional protease 7) |
| LMP7L | T01.016 | 122706 | — | 14q11.2 | similar to RIKEN cDNA 5830406J20 |
| PSMA6 | T101.971 | 5687 | — | 14q13 | proteasome (prosome, macropain) |
| | | | | | subunit, alpha type, 6 |
| PSMA2 | T01.972 | 5683 | — | 7p14.1 | proteasome (prosome, macropain) |
| | | | | | subunit, alpha type, 2 |
| PSMA4 | T01.973 | 5685 | — | 15q25.1 | proteasome (prosome, macropain) |
| | | | | | subunit, alpha type, 4 |
| PSMA7 | T01.974 | 5688 | — | 20q13.33 | proteasome (prosome, macropain) |
| | | | | | subunit, alpha type, 7 |
| PSMA5 | T01.975 | 5686 | — | 1p13 | proteasome (prosome, macropain) |
| | | | | | subunit, alpha type, 5 |
| PSMA1 | T01.976 | 5682 | — | 11p15.1 | proteasome (prosome, macropain) |
| | | | | | subunit, alpha type, 1 |
| PSMA3 | T01.977 | 5684 | — | 14q23 | proteasome (prosome, macropain) |
| | | | | | subunit, alpha type, 3 |
| PSMA8 | T01.978 | 143471 | — | 18q11.2 | proteasome (prosome, macropain) |
| | | | | | subunit, alpha type, 8 |
| PSMB3 | T01.983 | 5691 | — | 17q12 | proteasome (prosome, macropain) |
| | | | | | subunit, beta type, 3 |
| PSMB2 | T01.984 | 5690 | — | 1p34.2 | proteasome (prosome, macropain) |
| | | | | | subunit, beta type, 2 |
| PSMB1 | T01.986 | 5689 | — | 6q27 | proteasome (prosome, macropain) |
| | | | | | subunit, beta type, 1 |
| PSMB4 | T01.987 | 5692 | — | 1q21 | proteasome (prosome, macropain) |
| | | | | | subunit, beta type, 4 |
| PSMB3P | T01.P02 | 121131 | — | 12q13.2 | proteasome (prosome, macropain) |
| | | | | | subunit, beta type, 3 pseudogene |
| AGA | T02.001 | 175 | 3.5.1.26 | 4q32-q33 | aspartylglucosaminidase |
| ASRGL1 | T02.002 | 80150 | — | 11q12.3 | asparaginase like 1 |
| TASP1 | T02.004 | 55617 | 3.4.25.— | 20p12.1 | chromosome 20 open reading frame |
| | | | | | 13 |
| GGTLA1 | T03.002 | 2687 | — | 22q11.23 | gamma-glutamyltransferase-like |
| | | | | | activity 1 |
| GGT1 | T03.006 | 2678 | 2.3.2.2 | 22q11.23 | gamma-glutamyltransferase 1 |
| GGT2 | T03.015 | 2679 | — | 22q11.23 | gamma-glutamyltransferase 2 |
| GGTL4 | T03.016 | 91227 | — | 22q11.22 | gamma-glutamyltransferase-like 4 |
| GGTL3 | T03.017 | 2686 | — | 20q11.22 | gamma-glutamyltransferase-like 3 |
| RCE1 | U48.002 | 9986 | — | 11q13 | RCE1 homolog, prenyl protein |
| | | | | | protease (S. cerevisiae) |
| BDNF | Uxx.xxx | 627 | — | 11p13 | brain-derived neurotrophic factor |
| CST3 | Uxx.xxx | 1471 | — | 20p11.21 | cystatin C (amyloid angiopathy and |
| | | | | | cerebral hemorrhage) |
| KNG1 | Uxx.xxx | 3827 | — | 3q27 | kininogen 1 |
| NEDD8 | Uxx.xxx | 4738 | — | 14q11.2 | neural precursor cell expressed, |
| | | | | | developmentally down-regulated 8 |
| PDGFA | Uxx.xxx | 5154 | — | 7p22 | platelet-derived growth factor alpha |
| | | | | | polypeptide |
| SERPINF2 | Uxx.xxx | 5345 | — | 17p13 | serine (or cysteine) proteinase |
| | | | | | inhibitor, clade F (alpha-2 |
| | | | | | antiplasmin, pigment epithelium |
| | | | | | derived factor), member 2 |
| SFRS2IP | Uxx.xxx | 9169 | — | 12q13.11 | splicing factor, arginine/serine-rich 2, |
| | | | | | interacting protein |
| BIRC8 | Uxx.xxx | 112401 | — | 19q13.3-q13.4 | baculoviral IAP repeat-containing 8 |

TABLE 5
Additional kinases are presented, the concentration and activity of which
may be detected and quantitated using embodiments of the methods of the invention.

| | | | | Map Location ID | |
|---|---|---|---|---|---|
| Kinase Gene | | Entrez | | (cytogenetic or | |
| Name | Family | Gene ID | enzyme ID | genetic location) | Descriptive Name (or default name) |
| AKT1 | AGC, AKT, SK018, | 207 | 2.7.1.37 | 14q32.32 | v-akt murine thymoma viral |
| | AKT1 | | | | oncogene homolog 1 |
| AKT2 | AGC, AKT, SK019, | 208 | 2.7.1.37 | 19q13.1-q13.2 | v-akt murine thymoma viral |
| | AKT2 | | | | oncogene homolog 2 |
| AKT3 | AGC, AKT, SK020, | 10000 | 2.7.1.37 | 1q43-q44 | v-akt murine thymoma viral |
| | AKT3 | | | | oncogene homolog 3 (protein |
| | | | | | kinase B, gamma) |
| CRIK | AGC, DMPK, SK695, | 11113 | — | 12q24 | citron (rho-interacting, |
| | CRIK | | | | serine/threonine kinase 21) |
| DMPK1 | AGC, DMPK, GEK, | 1760 | — | 19q13.3 | dystrophia myotonica-protein |
| | SK111, DMPK1 | | | | kinase |
| MRCKa | AGC, DMPK, GEK, | 8476 | — | 1q42.11 | CDC42 binding protein kinase |
| | SK299, MRCKa | | | | alpha (DMPK-like) |
| MRCKb | AGC, DMPK, GEK, | 9578 | — | 14q32.3 | CDC42 binding protein kinase beta |
| | SK241, MRCKb | | | | (DMPK-like) |
| DMPK2 | AGC, DMPK, GEK, | 55561 | — | 11q13.1 | CDC42 binding protein kinase |
| | SK112, DMPK2 | | | | gamma (DMPK-like) |
| ROCK1 | AGC, DMPK, ROCK, | 6093 | 2.7.1.37 | 18q11.1 | Rho-associated, coiled-coil |
| | SK331, ROCK1 | | | | containing protein kinase 1 |
| ROCK2 | AGC, DMPK, ROCK, | 9475 | 2.7.1.37 | 2p24 | Rho-associated, coiled-coil |
| | SK263, ROCK2 | | | | containing protein kinase 2 |
| BARK1 | AGC, GRK, BARK, | 156 | — | 11q13 | adrenergic, beta, receptor kinase 1 |
| | SK045, BARK1 | | | | |
| BARK2 | AGC, GRK, BARK, | 157 | — | 22q12.1 | adrenergic, beta, receptor kinase 2 |
| | SK478, BARK2 | | | | |
| GPRK4 | AGC, GRK, GRK, SK156, | 2868 | — | 4p16.13 | G protein-coupled receptor kinase 4 |
| | GPRK4 | | | | |
| GPRK5 | AGC, GRK, GRK, SK157, | 2869 | — | 10q24-qter | G protein-coupled receptor kinase 5 |
| | GPRK5 | | | | |
| GPRK6 | AGC, GRK, GRK, SK158 | 2870 | — | 5q35 | G protein-coupled receptor kinase 6 |
| | GPRK6 | | | | |
| RHOK | AGC, GRK, GRK, SK327, | 6011 | 2.7.1.125 | 13q34 | G protein-coupled receptor kinase 1 |
| | RHOK | | | | |
| GPRK7 | AGC, GRK, GRK, SK578, | 131890 | — | 3q21-q23 | G protein-coupled receptor kinase 7 |
| | GPRK7 | | | | |
| MAST1 | AGC, MAST, SK345, | 22983 | — | 19p13.2 | microtubule associated |
| | MAST1 | | | | serine/threonine kinase 1 |
| MAST3 | AGC, MAST, SK196, | 23031 | — | 19p13.11 | microtubule associated |
| | MAST3 | | | | serine/threonine kinase 3 |
| MAST2 | AGC, MAST, SK216, | 23139 | — | 1p34.1 | microtubule associated |
| | MAST2 | | | | serine/threonine kinase 2 |
| MAST4 | AGC, MAST, SK701, | 375449 | — | 5q12.3 | similar to microtubule associated |
| | MAST4 | | | | testis specific serine/threonine |
| | | | | | protein kinase |
| MASTL | AGC, MAST, SK455, | 84930 | — | 10p12.1 | microtubule associated |
| | MASTL | | | | serine/threonine kinase-like |
| LATS1 | AGC, NDR, SK441, | 9113 | — | 6q24-q25.1 | LATS, large tumor suppressor, |
| | LATS1 | | | | homolog 1 (Drosophila) |
| NDR1 | AGC, NDR, SK249, | 11329 | — | 6p21 | serine/threonine kinase 38 |
| | NDR1 | | | | |
| NDR2 | AGC, NDR, SK500, | 23012 | — | 12p11.13 | serine/threonine kinase 38 like |
| | NDR2 | | | | |
| LATS2 | AGC, NDR, SK442, | 26524 | — | 13q11-q12 | LATS, large tumor suppressor, |
| | LATS2 | | | | homolog 2 (Drosophila) |
| PDK1 | AGC, PDK1, SK276, | 5170 | — | 16p13.3 | 3-phosphoinositide dependent |
| | PDK1 | | | | protein kinase-1 |
| PKACa | AGC, PKA, SK300, | 5566 | 2.7.1.37 | 19p13.1 | protein kinase, cAMP-dependent, |
| | PKACa | | | | catalytic, alpha |
| PKACb | AGC, PKA, SK301, | 5567 | 2.7.1.37 | 1p36.1 | protein kinase, cAMP-dependent, |
| | PKACb | | | | catalytic, beta |
| PKACg | AGC, PKA, SK302, | 5568 | 2.7.1.37 | 9q13 | protein kinase, cAMP-dependent, |
| | PKACg | | | | catalytic, gamma |
| PRKX | AGC, PKA, SK313, | 5613 | — | xp22.3 | protein kinase, X-linked |
| | PRKX | | | | |
| PRKY | AGC, PKA, SK320, | 5616 | — | yp11.2 | protein kinase, Y-linked |
| | PRKY | | | | |
| PKCa | AGC, PKC, Alpha, | 5578 | 2.7.1.37 | 17q22-q23.2 | protein kinase C, alpha |
| | SK303, PKCa | | | | |
| PKCb | AGC, PKC, Alpha, | 5579 | 2.7.1.37 | 16p11.2 | protein kinase C, beta 1 |
| | SK304, PKCb | | | | |
| PKCg | AGC, PKC, Alpha, | 5582 | 2.7.1.37 | 19q13.4 | protein kinase C, gamma |
| | SK307, PKCg | | | | |
| PKCd | AGC, PKC, Delta, SK305, | 5580 | 2.7.1.37 | 3p21.31 | protein kinase C, delta |
| | PKCd | | | | |
| PKCt | AGC, PKC, Delta, SK310, | 5588 | 2.7.1.37 | 10p15 | protein kinase C, theta |
| | PKCt | | | | |
| PKCe | AGC, PKC, Eta, SK306, | 5581 | 2.7.1.37 | 2p21 | protein kinase C, epsilon |
| | PKCe | | | | |
| PKCh | AGC, PKC, Eta, SK270, | 5583 | 2.7.1.37 | 14q22-q23 | protein kinase C, eta |
| | PKCh | | | | |
| PKCi | AGC, PKC, Iota, SK308, | 5584 | 2.7.11.13 | 3q26.3 | protein kinase C, iota |
| | PKCi | | | | |
| PKCz | AGC, PKC, Iota, SK311, | 5590 | 2.7.1.37 | 1p36.33-p36.2 | protein kinase C, zeta |
| | PKCz | | | | |
| PKG1 | AGC, PKG, SK073, | 5592 | 2.7.1.37 | 10q11.2 | protein kinase, cGMP-dependent, |
| | PKG1 | | | | type I |
| PKG2 | AGC, PKG, SK075, | 5593 | 2.7.1.37 | 4q13.1-q21.1 | protein kinase, cGMP-dependent, |
| | PKG2 | | | | type II |
| PKN1 | AGC, PKN, SK317, | 5585 | — | 19p13.1-p12 | protein kinase N1 |
| | PKN1 | | | | |
| PKN2 | AGC, PKN, SK318, | 5586 | — | 1p22.2 | protein kinase N2 |
| | PKN2 | | | | |
| PKN3 | AGC, PKN, SK511, | 29941 | — | 9q34.11 | protein kinase N3 |
| | PKN3 | | | | |
| MSK2 | AGC, RSK, MSK, SK243, | 8986 | — | 11q11-q13 | ribosomal protein S6 kinase, |
| | MSK2 | | | | 90 kDa, polypeptide 4 |
| MSK1 | AGC, RSK, MSK, SK242, | 9252 | — | 14q31-q32.1 | ribosomal protein S6 kinase, |
| | MSK1 | | | | 90 kDa, polypeptide 5 |
| p70S6K | AGC, RSK, p70, SK265, | 6198 | — | 17q23.2 | ribosomal protein S6 kinase, |
| | p70S6K | | | | 70 kDa, polypeptide 1 |
| p70S6Kb | AGC, RSK, p70, SK266, | 6199 | — | 11q13.2 | ribosomal protein S6 kinase, |
| | p70S6Kb | | | | 70 kDa, polypeptide 2 |
| RSK3 | AGC, RSK, RSK, SK338, | 6195 | — | 1p | ribosomal protein S6 kinase, |
| | RSK3 | | | | 90 kDa, polypeptide 1 |
| RSK1 | AGC, RSK, RSK, SK336, | 6196 | — | 6q27 | ribosomal protein S6 kinase, |
| | RSK1 | | | | 90 kDa, polypeptide 2 |
| RSK2 | AGC, RSK, RSK, SK337, | 6197 | — | xp22.2-p22.1 | ribosomal protein S6 kinase, |
| | RSK2 | | | | 90 kDa, polypeptide 3 |
| RSK4 | AGC, RSK, RSK, SK518, | 27330 | — | xq21 | ribosomal protein S6 kinase, |
| | RSK4 | | | | 90 kDa, polypeptide 6 |
| RSKL1 | AGC, RSKL, SK517, | 26750 | — | 1q41 | ribosomal protein S6 kinase, |
| | RSKL1 | | | | 52 kDa, polypeptide 1 |
| RSKL2 | AGC, RSKL, SK473, | 83694 | — | 14q24.3 | ribosomal protein S6 kinase-like 1 |
| | RSKL2 | | | | |
| SgK494 | AGC, RSKR, SK491, | 124923 | — | 17q11.2 | hypothetical protein FLJ25006 |
| | SgK494 | | | | |
| SGK1 | AGC, SGK, SK346, | 6446 | — | 6q23 | serum/glucocorticoid regulated |
| | SGK | | | | kinase |
| SGK2 | AGC, SGK, SK523, | 10110 | — | 20q13.2 | serum/glucocorticoid regulated |
| | SGK2 | | | | kinase 2 |
| SGK3 | AGC, SGK, SK525, | 23678 | — | 8q12.3-8q13.1 | serum/glucocorticoid regulated |
| | SGK3 | | | | kinase-like |
| YANK2 | AGC, YANK, SK481, | 55351 | — | 4p16.2 | serine/threonine kinase 32B |
| | YANK2 | | | | |
| YANK1 | AGC, YANK, SK624, | 202374 | — | 5q32 | serine/threonine kinase 32A |
| | YANK1 | | | | |
| YANK3 | AGC, YANK, SK469, | 282974 | — | 10q26.3 | serine/threonine kinase 32C |
| | YANK3 | | | | |
| ADCK3 | Atypical, ABC1, ABC1- | 56997 | — | 1q42.13 | chaperone, ABC1 activity of bc1 |
| | A, SK609, ADCK3 | | | | complex like (S. pombe) |
| ADCK4 | Atypical, ABC1, ABC1- | 79934 | — | 19q13.2 | aarF domain containing kinase 4 |
| | A, SK013, ADCK4 | | | | |
| ADCK1 | Atypical, ABC1, ABC1- | 57143 | — | 14q24.3 | aarF domain containing kinase 1 |
| | B, SK401, ADCK1 | | | | |
| ADCK5 | Atypical, ABC1, ABC1- | 203054 | — | 8q24.3 | aarF domain containing kinase 5 |
| | B, SK780, ADCK5 | | | | |
| ADCK2 | Atypical, ABC1, ABC1- | 90956 | — | 7q32-q34 | aarF domain containing kinase 2 |
| | C, SK712, ADCK2 | | | | |
| AlphaK1 | Atypical, Alpha, SK765, | 57538 | — | 15q25.2 | alpha-kinase 3 |
| | AlphaK1 | | | | |
| AlphaK3 | Atypical, Alpha, SK755, | 80216 | — | 4q25 | alpha-kinase 1 |
| | AlphaK3 | | | | |
| AlphaK2 | Atypical, Alpha, SK754, | 115701 | — | 18q21.31 | alpha-kinase 2 |
| | AlphaK2 | | | | |
| ChaK1 | Atypical, Alpha, ChaK, | 54822 | — | 15q21 | transient receptor potential cation |
| | SK423, ChaK1 | | | | channel, subfamily M, member 7 |
| ChaK2 | Atypical, Alpha, ChaK, | 140803 | — | 9q21.13 | transient receptor potential cation |
| | SK746, ChaK2 | | | | channel, subfamily M, member 6 |
| eEF2K | Atypical, Alpha, eEF2K, | 29904 | — | 16p12.1 | eukaryotic elongation factor-2 |
| | SK117, eEF2K | | | | kinase |
| BCR | Atypical, BCR, SK047, | 613 | — | 22q11.23 | breakpoint cluster region |
| | BCR | | | | |
| BRDT | Atypical, BRD, SK764, | 676 | — | 1p22.1 | bromodomain, testis-specific |
| | BRDT | | | | |
| BRD2 | Atypical, BRD, SK761, | 6046 | — | 6p21.3 | bromodomain containing 2 |
| | BRD2 | | | | |
| BRD3 | Atypical, BRD, SK762, | 8019 | — | 9q34 | bromodomain containing 3 |
| | BRD3 | | | | |
| BRD4 | Atypical, BRD, SK763, | 23476 | — | 19p13.1 | bromodomain containing 4 |
| | BRD4 | | | | |
| FASTK | Atypical, FAST, SK139, | 10922 | — | 7q35 | FAST kinase |
| | FASTK | | | | |
| G11 | Atypical, G11, SK756, | 8859 | — | 6p21.3 | serine/threonine kinase 19 |
| | G11 | | | | |
| H11 | Atypical, H11, SK782, | 26353 | — | 12q24.23 | heat shock 22 kDa protein 8 |
| | H11 | | | | |
| BCKDK | Atypical, PDHK, SK046, | 10295 | — | 16p11.2 | branched chain ketoacid |
| | BCKDK | | | | dehydrogenase kinase |
| PDHK1 | Atypical, PDHK, SK277, | 5163 | — | 2q31.1 | pyruvate dehydrogenase kinase, |
| | PDHK1 | | | | isoenzyme 1 |
| PDHK2 | Atypical, PDHK, SK278, | 5164 | — | 17q21.33 | pyruvate dehydrogenase kinase, |
| | PDHK2 | | | | isoenzyme 2 |
| PDHK3 | Atypical, PDHK, SK279, | 5165 | — | xp22.11 | pyruvate dehydrogenase kinase, |
| | PDHK3 | | | | isoenzyme 3 |
| PDHK4 | Atypical, PDHK, SK280, | 5166 | — | 7q21.3-q22.1 | pyruvate dehydrogenase kinase, |
| | PDHK4 | | | | isoenzyme 4 |
| ATM | Atypical, PIKK, ATM, | 472 | — | 11q22-q23 | ataxia telangiectasia mutated |
| | SK038, ATM | | | | (includes complementation groups |
| | | | | | A, C and D) |
| ATR | Atypical, PIKK, ATR, | 545 | — | 3q22-q24 | ataxia telangiectasia and Rad3 |
| | SK039, ATR | | | | related |
| DNAPK | Atypical, PIKK, DNAPK, | 5591 | — | 8q11 | protein kinase, DNA-activated, |
| | SK113, DNAPK | | | | catalytic polypeptide |
| FRAP | Atypical, PIKK, FRAP, | 2475 | — | 1p36.2 | FK506 binding protein 12- |
| | SK152, FRAP | | | | rapamycin associated protein 1 |
| SMG1 | Atypical, PIKK, SMG1, | 23049 | — | 16p12.3 | PI-3-kinase-related kinase SMG-1 |
| | SK665, SMG1 | | | | |
| TRRAP | Atypical, PIKK, TRRAP, | 8295 | — | 7q21.2-q22.1 | transformation/transcription |
| | SK380, TRRAP | | | | domain-associated protein |
| RIOK1 | Atypical, RIO, RIO1, | 83732 | — | 6p24.3 | RIO kinase 1 (yeast) |
| | SK615, RIOK1 | | | | |
| RIOK2 | Atypical, RIO, RIO2, | 55781 | — | 5q15 | RIO kinase 2 (yeast) |
| | SK753, RIOK2 | | | | |
| RIOK3 | Atypical, RIO, RIO3, | 8780 | — | 18q11.2 | RIO kinase 3 (yeast) |
| | SK606, RIOK3 | | | | |
| TAF1 | Atypical, TAF1, SK772, | 6872 | — | xq13.1 | TAF1 RNA polymerase II, TATA |
| | TAF1 | | | | box binding protein (TBP)- |
| | | | | | associated factor, 250 kDa |
| TAF1L | Atypical, TAF1, SK781, | 138474 | — | 9p21.1 | TAF1-like RNA polymerase II, |
| | TAF1L | | | | TATA box binding protein (TBP)- |
| | | | | | associated factor, 210 kDa |
| TIF1a | Atypical, TIF1, SK783, | 8805 | — | 7q32-q34 | transcriptional intermediary factor 1 |
| | TIF1a | | | | |
| TIF1b | Atypical, TIF1, SK784, | 10155 | — | 19q13.4 | tripartite motif-containing 28 |
| | TIF1b | | | | |
| TIF1g | Atypical, TIF1, SK785, | 51592 | — | 1p13.1 | tripartite motif-containing 33 |
| | TIF1g | | | | |
| CaMK4 | CAMK, CAMK1, SK061, | 814 | 2.7.11.17 | 5q21.3 | calcium/calmodulin-dependent |
| | CaMK4 | | | | protein kinase IV |
| CaMK1a | CAMK, CAMK1, SK056, | 8536 | — | 3p25.3 | calcium/calmodulin-dependent |
| | CaMK1a | | | | protein kinase I |
| CaMK1d | CAMK, CAMK1, SK572, | 57118 | — | 10p13 | calcium/calmodulin-dependent |
| | CaMK1d | | | | protein kinase ID |
| CaMK1g | CAMK, CAMK1, SK021, | 57172 | — | 1q32-q41 | calcium/calmodulin-dependent |
| | CaMK1g | | | | protein kinase IG |
| CaMK1b | CAMK, CAMK1, SK662, | 139728 | — | xq28 | pregnancy upregulated non- |
| | CaMK1b | | | | ubiquitously expressed CaM kinase |
| CaMK2a | CAMK, CAMK2, SK057, | 815 | 2.7.11.17 | 5q32 | calcium/calmodulin-dependent |
| | CaMK2a | | | | protein kinase (CaM kinase) II |
| | | | | | alpha |
| CaMK2b | CAMK, CAMK2, SK058, | 816 | — | 7p14.3-p14.1 | calcium/calmodulin-dependent |
| | CaMK2b | | | | protein kinase (CaM kinase) II beta |
| CaMK2d | CAMK, CAMK2, SK703, | 817 | — | 4q26 | calcium/calmodulin-dependent |
| | CaMK2d | | | | protein kinase (CaM kinase) II |
| | | | | | delta |
| CaMK2g | CAMK, CAMK2, SK060, | 818 | — | 10q22 | calcium/calmodulin-dependent |
| | CaMK2g | | | | protein kinase (CaM kinase) II |
| | | | | | gamma |
| AMPKa1 | CAMK, CAMKL, | 5562 | — | 5p12 | protein kinase, AMP-activated, |
| | AMPK, SK032, AMPKa1 | | | | alpha 1 catalytic subunit |
| AMPKa2 | CAMK, CAMKL, | 5563 | — | 1p31 | protein kinase, AMP-activated, |
| | AMPK, SK033, AMPKa2 | | | | alpha 2 catalytic subunit |
| BRSK2 | CAMK, CAMKL, BRSK, | 9024 | — | 11p15.5 | BR serine/threonine kinase 2 |
| | SK015, BRSK2 | | | | |
| BRSK1 | CAMK, CAMKL, BRSK, | 84446 | — | 19q13.4 | BR serine/threonine kinase 1 |
| | SK598, BRSK1 | | | | |
| CHK1 | CAMK, CAMKL, CHK1, | 1111 | — | 11q24-q24 | CHK1 checkpoint homolog (S. pombe) |
| | SK078, CHK1 | | | | |
| HUNK | CAMK, CAMKL, | 30811 | — | 21q22.1 | hormonally upregulated Neu- |
| | HUNK, SK502, HUNK | | | | associated kinase |
| LKB1 | CAMK, CAMKL, LKB, | 6794 | — | 19p13.3 | serine/threonine kinase 11 (Peutz- |
| | SK208, LKB1 | | | | Jeghers syndrome) |
| MARK2 | CAMK, CAMKL, | 2011 | — | 11q12-q13 | MAP/microtubule affinity- |
| | MARK, SK120, MARK2 | | | | regulating kinase 2 |
| MARK1 | CAMK, CAMKL, | 4139 | — | 1q41 | MAP/microtubule affinity- |
| | MARK, SK215, MARK1 | | | | regulating kinase 1 |
| MARK3 | CAMK, CAMKL, | 4140 | — | 14q32.3 | MAP/microtubule affinity- |
| | MARK, SK096, MARK3 | | | | regulating kinase 3 |
| MARK4 | CAMK, CAMKL, | 57787 | — | 19q13.3 | MAP/microtubule affinity- |
| | MARK, SK515, MARK4 | | | | regulating kinase 4 |
| MELK | CAMK, CAMKL, | 9833 | — | 9p13.2 | maternal embryonic leucine zipper |
| | MELK, SK298, MELK | | | | kinase |
| NIM1 | CAMK, CAMKL, | 167359 | — | 5p12 | hypothetical protein MGC42105 |
| | NIM1, SK449, NIM1 | | | | |
| NuaK1 | CAMK, CAMKL, | 9891 | — | 12q23.3 | AMP-activated protein kinase |
| | NuaK, SK195, NuaK1 | | | | family member 5 |
| NuaK2 | CAMK, CAMKL, | 81788 | — | 1q32.1 | likely ortholog of rat SNF1/AMP- |
| | NuaK, SK472, NuaK2 | | | | activated protein kinase |
| PASK | CAMK, CAMKL, PASK, | 23178 | — | 2q37.3 | PAS domain containing |
| | SK499, PASK | | | | serine/threonine kinase |
| QIK | CAMK, CAMKL, | 23235 | — | 11q23.1 | SNF1-like kinase 2 |
| | QIK, SK513, QIK | | | | |
| QSK | CAMK, CAMKL, | 23387 | — | 11q23.3 | KIAA0999 protein |
| | QIK, SK501, QSK | | | | |
| SIK | CAMK, CAMKL, | 150094 | — | 21q22.3 | SNF-1 like kinase |
| | QIK, SK604, SIK | | | | |
| SNRK | CAMK, CAMKL, SNRK, | 54861 | — | 3p22.1 | SNF-1 related kinase |
| | SK625, SNRK | | | | |
| STK33 | CAMK, CAMK- | 65975 | — | 11p15.3 | serine/threonine kinase 33 |
| | Unique, SK463, STK33 | | | | |
| VACAMKL | CAMK, CAMK- | 79012 | — | 3p21.31 | hypothetical protein MGC8407 |
| | Unique, SK062, VACAMKL | | | | |
| CASK | CAMK, CASK, SK064, | 8573 | — | xp11.4 | calcium/calmodulin-dependent |
| | CASK | | | | serine protein kinase (MAGUK |
| | | | | | family) |
| DAPK1 | CAMK, DAPK, SK103, | 1612 | — | 9q34.1 | death-associated protein kinase 1 |
| | DAPK1 | | | | |
| DAPK3 | CAMK, DAPK, SK716, | 1613 | — | 19p13.3 | death-associated protein kinase 3 |
| | DAPK3 | | | | |
| DAPK2 | CAMK, DAPK, SK104, | 23604 | — | 15q22.31 | death-associated protein kinase 2 |
| | DAPK2 | | | | |
| DRAK2 | CAMK, DAPK, SK487, | 9262 | — | 2q32.3 | serine/threonine kinase 17b |
| | DRAK2 | | | | (apoptosis-inducing) |
| DRAK1 | CAMK, DAPK, SK486, | 9263 | — | 7p12-p14 | serine/threonine kinase 17a |
| | DRAK1 | | | | (apoptosis-inducing) |
| DCLK1 | CAMK, DCAMKL, | 9201 | — | 13q13 | doublecortin and CaM kinase-like 1 |
| | SK063, DCAMKL1 | | | | |
| DCLK3 | CAMK, DCAMKL, | 85443 | — | 3p22.3 | doublecortin and CaM kinase-like 3 |
| | SK459, DCAMKL3 | | | | |
| DCLK2 | CAMK, DCAMKL, | 166614 | — | 4q31.23 | doublecortin and CaM kinase-like 2 |
| | SK527, DCAMKL2 | | | | |
| MAPKAPK3 | CAMK, MAPKAPK, | 7867 | — | 3p21.3 | mitogen-activated protein kinase- |
| | MAPKAPK, SK213, | | | | activated protein kinase 3 |
| | MAPKAPK3 | | | | |
| MAPKAPK5 | CAMK, MAPKAPK, | 8550 | — | 12q24.12 | mitogen-activated protein kinase- |
| | MAPKAPK, SK214, | | | | activated protein kinase 5 |
| | MAPKAPK5 | | | | |
| MAPKAPK2 | CAMK, MAPKAPK, | 9261 | — | 1q32 | mitogen-activated protein kinase- |
| | MAPKAPK, SK212, | | | | activated protein kinase 2 |
| | MAPKAPK2 | | | | |
| MNK2 | CAMK, MAPKAPK, | 2872 | — | 19p13.3 | MAP kinase interacting |
| | MNK, SK236, MNK2 | | | | serine/threonine kinase 2 |
| MNK1 | CAMK, MAPKAPK, | 8569 | — | 1p33 | MAP kinase interacting |
| | MNK, SK235, MNK1 | | | | serine/threonine kinase 1 |
| smMLCK | CAMK, MLCK, SK231, | 4638 | 2.7.11.18 | 3q21 | myosin, light polypeptide kinase |
| | smMLCK | | | | |
| TTN | CAMK, MLCK, SK372, | 7273 | — | 2q31 | titin |
| | TTN | | | | |
| skMLCK | CAMK, MLCK, SK675, | 85366 | 2.7.11.18 | 20q13.31 | myosin light chain kinase 2, |
| | skMLCK | | | | skeletal muscle |
| caMLCK | CAMK, MLCK, SK536, | 91807 | — | 16q11.2 | myosin light chain kinase (MLCK) |
| | caMLCK | | | | |
| SgK085 | CAMK, MLCK, SK709, | 340156 | — | 6p25.2 | hypothetical protein LOC340156 |
| | SgK085 | | | | |
| PHKg1 | CAMK, PHK, SK283, | 5260 | 2.7.1.38 | 7p12-q21 | phosphorylase kinase, gamma 1 |
| | PHKg1 | | | | (muscle) |
| PHKg2 | CAMK, PHK, SK284, | 5261 | — | 16p12.1-p11.2 | phosphorylase kinase, gamma 2 |
| | PHKg2 | | | | (testis) |
| PIM1 | CAMK, PIM, SK291, | 5292 | — | 6p21.2 | pim-1 oncogene |
| | PIM1 | | | | |
| PIM2 | CAMK, PIM, SK292, | 11040 | — | xp11.23 | pim-2 oncogene |
| | PIM2 | | | | |
| PIM3 | CAMK, PIM, SK200, | 415116 | — | 22q13 | pim-3 oncogene |
| | PIM3 | | | | |
| PRKD1 | CAMK, PKD, SK309, | 5587 | 2.7.1.37 | 14q11 | protein kinase D1 |
| | PKD1 | | | | |
| PKD3 | CAMK, PKD, SK489, | 23683 | — | 2p21 | protein kinase D3 |
| | PKD3 | | | | |
| PRKD2 | CAMK, PKD, SK480, | 25865 | — | 19q13.3 | protein kinase D2 |
| | PKD2 | | | | |
| PSKH1 | CAMK, PSK, SK322, | 5681 | — | 16q22.1 | protein serine kinase H1 |
| | PSKH1 | | | | |
| PSKH2 | CAMK, PSK, SK602, | 85481 | — | 8q21.3 | protein serine kinase H2 |
| | PSKH2 | | | | |
| CHK2 | CAMK, RAD53, SK079, | 11200 | — | 22q12.1 | CHK2 checkpoint homolog (S. pombe) |
| | CHK2 | | | | |
| SgK495 | CAMK, CAMK- | 83931 | — | 1p34.3 | Ser/Thr-like kinase |
| | Unique, SK492, SgK495 | | | | |
| Trb1 | CAMK, Trbl, SK014, | 10221 | — | 8q24.13 | tribbles homolog 1 (Drosophila) |
| | Trb1 | | | | |
| Trb2 | CAMK, Trbl, SK160, | 28951 | — | 2p24.3 | tribbles homolog 2 (Drosophila) |
| | Trb2 | | | | |
| Trb3 | CAMK, Trbl, SK694, | 57761 | — | 20p13-p12.2 | tribbles homolog 3 (Drosophila) |
| | Trb3 | | | | |
| Obscn | CAMK, Trio, SK601, | 84033 | — | 1q42.13 | obscurin, cytoskeletal calmodulin |
| | Obscn | | | | and titin-interacting RhoGEF |
| SPEG | CAMK, Trio, SK537, | 729871 | — | 2q35 | SPEG complex locus |
| | SPEG | | | | |
| Trio | CAMK, Trio, SK376, | 7204 | — | 5p15.1-p14 | triple functional domain (PTPRF |
| | Trio | | | | interacting) |
| Trad | CAMK, Trio, SK533, | 8997 | — | 3q21.1-q21.2 | huntingtin-associated protein |
| | Trad | | | | interacting protein (duo) |
| TSSK2 | CAMK, TSSK, SK474, | 23617 | — | 22q11.21 | serine/threonine kinase 22B |
| | TSSK2 | | | | (spermiogenesis associated) |
| TSSK3 | CAMK, TSSK, SK471, | 81629 | — | 1p35-p34 | serine/threonine kinase 22C |
| | TSSK3 | | | | (spermiogenesis associated) |
| TSSK1 | CAMK, TSSK, SK705, | 83942 | — | 5q22.2 | serine/threonine kinase 22D |
| | TSSK1 | | | | (spermiogenesis associated) |
| SSTK | CAMK, TSSK, SK524, | 83983 | — | 19p13.11 | serine/threonine protein kinase |
| | SSTK | | | | SSTK |
| TSSK4 | CAMK, TSSK, SK534, | 283629 | — | 14q11.2 | chromosome 14 open reading |
| | TSSK4 | | | | frame 20 |
| CK1a | CK1, CK1, CK1- | 1452 | — | 5q32 | casein kinase 1, alpha 1 |
| | A, SK082, CK1a | | | | |
| CK1a2 | CK1, CK1, CK1- | 122011 | — | 13q13.3 | casein kinase 1, alpha 1-like |
| | A, SK541, CK1a2 | | | | |
| CK1d | CK1, CK1, CK1- | 1453 | — | 17q25 | casein kinase 1, delta |
| | D, SK083, CK1d | | | | |
| CK1e | CK1, CK1, CK1- | 1454 | — | 22q13.1 | casein kinase 1, epsilon |
| | E, SK084, CK1e | | | | |
| CK1g2 | CK1, CK1, CK1- | 1455 | — | 19p13.3 | casein kinase 1, gamma 2 |
| | G, SK086, CK1g2 | | | | |
| CK1g3 | CK1, CK1, CK1- | 1456 | — | 5q23 | casein kinase 1, gamma 3 |
| | G, SK087, CK1g3 | | | | |
| CK1g1 | CK1, CK1, CK1- | 53944 | — | 15q22.1-q22.31 | casein kinase 1, gamma 1 |
| | G, SK647, CK1g1 | | | | |
| TTBK1 | CK1, TTBK, SK526, | 84630 | — | 6p21.1 | tau tubulin kinase 1 |
| | TTBK1 | | | | |
| TTBK2 | CK1, TTBK, SK453, | 146057 | — | 15q15.2 | tau tubulin kinase 2 |
| | TTBK2 | | | | |
| VRK1 | CK1, VRK, SK389, | 7443 | — | 14q32 | vaccinia related kinase 1 |
| | VRK1 | | | | |
| VRK2 | CK1, VRK, SK390, | 7444 | — | 2p16-p15 | vaccinia related kinase 2 |
| | VRK2 | | | | |
| VRK3 | CK1, VRK, SK535, | 51231 | — | 19q13 | vaccinia related kinase 3 |
| | VRK3 | | | | |
| CCRK | CMGC, CDK, SK483, | 23552 | — | 9q22.1 | cell cycle related kinase |
| | CCRK | | | | |
| CDC2 | CMGC, CDK, CDC2, | 983 | — | 10q21.1 | cell division cycle 2, G1 to S and |
| | SK065, CDC2 | | | | G2 to M |
| CDK2 | CMGC, CDK, CDC2, | 1017 | — | 12q13 | cyclin-dependent kinase 2 |
| | SK067, CDK2 | | | | |
| CDK3 | CMGC, CDK, CDC2, | 1018 | — | 17q22-qter | cyclin-dependent kinase 3 |
| | SK068, CDK3 | | | | |
| CDK10 | CMGC, CDK, CDK10, | 8558 | — | 16q24 | cyclin-dependent kinase (CDC2- |
| | SK294, CDK10 | | | | like) 10 |
| CDK4 | CMGC, CDK, CDK4, | 1019 | — | 12q14 | cyclin-dependent kinase 4 |
| | SK069, CDK4 | | | | |
| CDK6 | CMGC, CDK, CDK4, | 1021 | — | 7q21-q22 | cyclin-dependent kinase 6 |
| | SK071, CDK6 | | | | |
| CDK5 | CMGC, CDK, CDK5, | 1020 | — | 7q36 | cyclin-dependent kinase 5 |
| | SK070, CDK5 | | | | |
| CDK7 | CMGC, CDK, CDK7, | 1022 | — | 5q12.1 | cyclin-dependent kinase 7 (MO15 |
| | SK055, CDK7 | | | | homolog, Xenopus laevis, cdk- |
| | | | | | activating kinase) |
| CDK8 | CMGC, CDK, CDK8, | 1024 | — | 13q12 | cyclin-dependent kinase 8 |
| | SK072, CDK8 | | | | |
| CDK11 | CMGC, CDK, CDK8, | 23097 | — | 6q21 | cell division cycle 2-like 6 (CDK8- |
| | SK443, CDK11 | | | | like) |
| CDK9 | CMGC, CDK, CDK9, | 1025 | — | 9q34.1 | cyclin-dependent kinase 9 (CDC2- |
| | SK295, CDK9 | | | | related kinase) |
| CHED | CMGC, CDK, CRK7, | 8621 | — | 7p13 | cell division cycle 2-like 5 |
| | SK076, CHED | | | | (cholinesterase-related cell division |
| | | | | | controller) |
| CRK7 | CMGC, CDK, CRK7, | 51755 | — | 17q12 | CDC2-related protein kinase 7 |
| | SK485, CRK7 | | | | |
| PCTAIRE1 | CMGC, CDK, TAIRE, | 5127 | — | xp11.3-p11.23 | PCTAIRE protein kinase 1 |
| | SK271, PCTAIRE1 | | | | |
| PCTAIRE2 | CMGC, CDK, TAIRE, | 5128 | — | 12q23.1 | PCTAIRE protein kinase 2 |
| | SK272, PCTAIRE2 | | | | |
| PCTAIRE3 | CMGC, CDK, TAIRE, | 5129 | — | 1q31-q32 | PCTAIRE protein kinase 3 |
| | SK273, PCTAIRE3 | | | | |
| PFTAIRE1 | CMGC, CDK, TAIRE, | 5218 | — | 7q21-q22 | PFTAIRE protein kinase 1 |
| | SK282, PFTAIRE1 | | | | |
| PFTAIRE2 | CMGC, CDK, TAIRE, | 65061 | — | 2q33.2 | amyotrophic lateral sclerosis 2 |
| | SK462, PFTAIRE2 | | | | (juvenile) chromosome region, |
| | | | | | candidate 7 |
| PITSLRE | CMGC, CDK, PITSLRE, | 985 | — | 1p36.3 | cell division cycle 2-like 2 |
| | SK297, PITSLRE | | | | (PITSLRE proteins) |
| CDKL5 | CMGC, CDKL, SK361, | 6792 | — | xp22 | cyclin-dependent kinase-like 5 |
| | CDKL5 | | | | |
| CDKL1 | CMGC, CDKL, SK203, | 8814 | — | 14q21.3 | cyclin-dependent kinase-like 1 |
| | CDKL1 | | | | (CDC2-related kinase) |
| CDKL2 | CMGC, CDKL, SK202, | 8999 | — | 4q21.1 | cyclin-dependent kinase-like 2 |
| | CDKL2 | | | | (CDC2-related kinase) |
| CDKL3 | CMGC, CDKL, SK509, | 51265 | 2.7.11.22 | 5q31 | cyclin-dependent kinase-like 3 |
| | CDKL3 | | | | |
| CDKL4 | CMGC, CDKL, SK466, | 344387 | — | 2p22.1 | cyclin-dependent kinase-like 4 |
| | CDKL4 | | | | |
| CK2a1 | Other, CK2, SK088, | 1457 | — | 20p13 | casein kinase 2, alpha 1 |
| | CK2a1 | | | | polypeptide |
| CK2a2 | Other, CK2, SK089, | 1459 | — | 16p13.3-p13.2 | casein kinase 2, alpha prime |
| | CK2a2 | | | | polypeptide |
| CLK1 | CMGC, CLK, SK090, | 1195 | — | 2q33 | CDC-like kinase 1 |
| | CLK1 | | | | |
| CLK2 | CMGC, CLK, SK091, | 1196 | — | 1q21 | CDC-like kinase 2 |
| | CLK2 | | | | |
| CLK3 | CMGC, CLK, SK092, | 1198 | — | 15q24 | CDC-like kinase 3 |
| | CLK3 | | | | |
| CLK4 | CMGC, CLK, SK484, | 57396 | — | 5q35 | CDC-like kinase 4 |
| | CLK4 | | | | |
| DYRK1A | CMGC, DYRK, DYRK1, | 1859 | — | 21q22.13 | dual-specificity tyrosine-(Y)- |
| | SK234, DYRK1A | | | | phosphorylation regulated kinase |
| | | | | | 1A |
| DYRK1B | CMGC, DYRK, DYRK1, | 9149 | — | 19q12-13.1 | dual-specificity tyrosine-(Y)- |
| | SK114, DYRK1B | | | | phosphorylation regulated kinase |
| | | | | | 1B |
| DYRK3 | CMGC, DYRK, DYRK2, | 8444 | — | 1q32.1 | dual-specificity tyrosine-(Y)- |
| | SK488, DYRK3 | | | | phosphorylation regulated kinase 3 |
| DYRK2 | CMGC, DYRK, DYRK2, | 8445 | — | 12q15 | dual-specificity tyrosine-(Y)- |
| | SK115, DYRK2 | | | | phosphorylation regulated kinase 2 |
| DYRK4 | CMGC, DYRK, DYRK2, | 8798 | — | 12p13.32 | dual-specificity tyrosine-(Y)- |
| | SK116, DYRK4 | | | | phosphorylation regulated kinase 4 |
| HIPK3 | CMGC, DYRK, HIPK, | 10114 | — | 11p13 | homeodomain interacting protein |
| | SK314, HIPK3 | | | | kinase 3 |
| HIPK2 | CMGC, DYRK, HIPK, | 28996 | — | 7q32-q34 | homeodomain interacting protein |
| | SK495, HIPK2 | | | | kinase 2 |
| HIPK4 | CMGC, DYRK, HIPK, | 147746 | — | 19q13.2 | homeodomain interacting protein |
| | SK582, HIPK4 | | | | kinase 4 |
| HIPK1 | CMGC, DYRK, HIPK, | 204851 | — | 1p13.2 | homeodomain interacting protein |
| | SK169, HIPK1 | | | | kinase 1 |
| PRP4 | CMGC, DYRK, PRP4, | 8899 | — | 6p25.2 | PRP4 pre-mRNA processing factor |
| | SK321, PRP4 | | | | 4 homolog B (yeast) |
| GSK3A | CMGC, GSK, SK162, | 2931 | — | 19q13.2 | glycogen synthase kinase 3 alpha |
| | GSK3A | | | | |
| GSK3B | CMGC, GSK, SK163, | 2932 | — | 3q13.3 | glycogen synthase kinase 3 beta |
| | GSK3B | | | | |
| Erk2 | CMGC, MAPK, ERK, | 5594 | 2.7.1.37 | 22q11.21 | mitogen-activated protein kinase 1 |
| | SK135, Erk2 | | | | |
| Erk1 | CMGC, MAPK, ERK, | 5595 | 2.7.1.37 | 16p12-p11.2 | mitogen-activated protein kinase 3 |
| | SK134, Erk1 | | | | |
| Erk4 | CMGC, MAPK, ERK, | 5596 | — | 18q12-q21 | mitogen-activated protein kinase 4 |
| | SK137, Erk4 | | | | |
| Erk3 | CMGC, MAPK, ERK, | 5597 | — | 15q21 | mitogen-activated protein kinase 6 |
| | SK136, Erk3 | | | | |
| Erk5 | CMGC, MAPK, ERK, | 5598 | — | 17p11.2 | mitogen-activated protein kinase 7 |
| | SK408, Erk5 | | | | |
| Erk7 | CMGC, MAPK, Erk7, | 225689 | — | 8q24.3 | extracellular signal-regulated |
| | SK465, Erk7 | | | | kinase 8 |
| MAPK8 | CMGC, MAPK, JNK, | 5599 | 2.7.1.37 | 10q11.22 | mitogen-activated protein kinase 8 |
| | SK188, JNK1 | | | | |
| MAPK9 | CMGC, MAPK, JNK, | 5601 | 2.7.1.37 | 5q35 | mitogen-activated protein kinase 9 |
| | SK189, JNK2 | | | | |
| MAPK10 | CMGC, MAPK, JNK, | 5602 | 2.7.1.37 | 4q22.1-q23 | mitogen-activated protein kinase |
| | SK190, JNK3 | | | | 10 |
| NLK | CMGC, MAPK, nmo, | 51701 | — | 17q11.2 | nemo like kinase |
| | SK255, NLK | | | | |
| p38a | CMGC, MAPK, p38, | 1432 | — | 6p21.3-p21.2 | mitogen-activated protein kinase |
| | SK264, p38a | | | | 14 |
| p38b | CMGC, MAPK, p38, | 5600 | 2.7.1.37 | 22q13.33 | mitogen-activated protein kinase |
| | SK342, p38b | | | | 11 |
| p38d | CMGC, MAPK, p38, | 5603 | 2.7.1.37 | 6p21.31 | mitogen-activated protein kinase |
| | SK344, p38d | | | | 13 |
| p38g | CMGC, MAPK, p38, | 6300 | 2.7.1.37 | 22q13.33 | mitogen-activated protein kinase |
| | SK343, p38g | | | | 12 |
| MAK | CMGC, RCK, SK211, | 4117 | — | 6q22 | male germ cell-associated kinase |
| | MAK | | | | |
| MOK | CMGC, RCK, SK505, | 5891 | — | 14q32 | renal tumor antigen |
| | MOK | | | | |
| ICK | CMGC, RCK, SK497, | 22858 | — | 6p12.3-p11.2 | intestinal cell (MAK-like) kinase |
| | ICK | | | | |
| SRPK1 | CMGC, SRPK, SK358, | 6732 | — | 6p21.3-p21.2 | SFRS protein kinase 1 |
| | SRPK1 | | | | |
| SRPK2 | CMGC, SRPK, SK359, | 6733 | — | 7q22-q31.1 | SFRS protein kinase 2 |
| | SRPK2 | | | | |
| MSSK1 | CMGC, SRPK, SK507, | 26576 | — | xq28 | serine/threonine kinase 23 |
| | MSSK1 | | | | |
| AurA | Other, AUR, SK407, | 6790 | — | 20q13.2-q13.3 | serine/threonine kinase 6 |
| | AurA | | | | |
| AurC | Other, AUR, SK043, | 6795 | — | 19q13.43 | aurora kinase C |
| | AurC | | | | |
| AurB | Other, AUR, SK406, | 9212 | — | 17p13.1 | aurora kinase B |
| | AurB | | | | |
| BUB1 | Other, BUB, SK409, | 699 | — | 2q14 | BUB1 budding uninhibited by |
| | BUB1 | | | | benzimidazoles 1 homolog (yeast) |
| BUBR1 | Other, BUB, SK053, | 701 | — | 15q15 | BUB1 budding uninhibited by |
| | BUBR1 | | | | benzimidazoles 1 homolog beta |
| | | | | | (yeast) |
| PRPK | Other, Bud32, SK464, | 112858 | — | 20q13.2 | TP53 regulating kinase |
| | PRPK | | | | |
| CaMKK2 | Other, CAMKK, Meta, | 10645 | — | 12q24.2 | calcium/calmodulin-dependent |
| | SK482, CaMKK2 | | | | protein kinase kinase 2, beta |
| CaMKK1 | Other, CAMKK, Meta, | 84254 | — | 17p13.2 | calcium/calmodulin-dependent |
| | SK697, CaMKK1 | | | | protein kinase kinase 1, alpha |
| CDC7 | Other, CDC7, SK066, | 8317 | — | 1p22 | CDC7 cell division cycle 7 (S. cerevisiae) |
| | CDC7 | | | | |
| Haspin | Other, Haspin, SK692, | 83903 | — | 17p13 | germ cell associated 2 (haspin) |
| | Haspin | | | | |
| IKKa | Other, IKK, SK175, | 1147 | — | 10q24-q25 | conserved helix-loop-helix |
| | IKKa | | | | ubiquitous kinase |
| IKKb | Other, IKK, SK176, | 3551 | — | 8p11.2 | inhibitor of kappa light polypeptide |
| | IKKb | | | | gene enhancer in B-cells, kinase |
| | | | | | beta |
| IKKe | Other, IKK, SK193, | 9641 | — | 1q32.1 | inhibitor of kappa light polypeptide |
| | IKKe | | | | gene enhancer in B-cells, kinase |
| | | | | | epsilon |
| TBK1 | Other, IKK, SK531, | 29110 | — | 12q14.1 | TANK-binding kinase 1 |
| | TBK1 | | | | |
| IRE1 | Other, IRE, SK182, IRE1 | 2081 | — | 17q24.2 | endoplasmic reticulum to nucleus |
| | | | | | signalling 1 |
| IRE2 | Other, IRE, SK498, IRE2 | 10595 | — | 16p12.2 | endoplasmic reticulum to nucleus |
| | | | | | signalling 2 |
| KIS | Other, Other- | 127933 | — | 1q23.3 | U2AF homology motif (UHM) |
| | Unique, SK661, KIS | | | | kinase 1 |
| MOS | Other, MOS, SK237, | 4342 | — | 8q11 | v-mos Moloney murine sarcoma |
| | MOS | | | | viral oncogene homolog |
| AAK1 | Other, NAK, SK422, | 22848 | — | 2p24.3-p14 | AP2 associated kinase 1 |
| | AAK1 | | | | |
| BIKE | Other, NAK, SK704, | 55589 | — | 4q21.21 | BMP2 inducible kinase |
| | BIKE | | | | |
| GAK | Other, NAK, SK155, | 2580 | — | 4p16 | cyclin G associated kinase |
| | GAK | | | | |
| MPSK1 | Other, NAK, SK506, | 8576 | — | 2q34-q37 | serine/threonine kinase 16 |
| | MPSK1 | | | | |
| NEK1 | Other, NEK, SK250, | 4750 | — | 4q33 | NIMA (never in mitosis gene a)- |
| | NEK1 | | | | related kinase 1 |
| NEK3 | Other, NEK, SK252, | 4752 | — | 13q14.13 | NIMA (never in mitosis gene a)- |
| | NEK3 | | | | related kinase 3 |
| | | | | | similar to Serine/threonine-protein |
| NEK5 | Other, NEK, SK558, | 341676 | — | 13q14.3 | kinase Nek1 (NimA-related protein |
| | NEK5 | | | | kinase 1) |
| NEK10 | Other, NEK, SK645, | 152110 | — | 3p24.1 | hypothetical protein FLJ32685 |
| | NEK10 | | | | |
| NEK11 | Other, NEK, SK574, | 79858 | — | 3q21.3 | NIMA (never in mitosis gene a)- |
| | NEK11 | | | | related kinase 11 |
| NEK2 | Other, NEK, SK251, | 4751 | — | 1q32.2-q41 | NIMA (never in mitosis gene a)- |
| | NEK2 | | | | related kinase 2 |
| NEK4 | Other, NEK, SK256, | 6787 | 2.7.11.1 | 3p21.1 | NIMA (never in mitosis gene a)- |
| | NEK4 | | | | related kinase 4 |
| NEK6 | Other, NEK, SK420, | 10783 | — | 9q33.3-q34.11 | NIMA (never in mitosis gene a)- |
| | NEK6 | | | | related kinase 6 |
| NEK7 | Other, NEK, SK421, | 140609 | — | 1q31.3 | NIMA (never in mitosis gene a)- |
| | NEK7 | | | | related kinase 7 |
| NEK9 | Other, NEK, SK470, | 91754 | — | 14q24.3 | NIMA (never in mitosis gene a)- |
| | NEK9 | | | | related kinase 9 |
| NEK8 | Other, NEK, SK476, | 284086 | — | 17q11.1 | NIMA (never in mitosis gene a)- |
| | NEK8 | | | | related kinase 8 |
| SBK | Other, NKF1, SK650, | 388228 | — | 16p11.2 | SH3-binding domain kinase 1 |
| | SBK | | | | |
| SgK069 | Other, NKF1, SK581, | 646643 | — | — | — |
| | SgK069 | | | | |
| PINK1 | Other, NKF2, SK456, | 65018 | — | 1p36 | PTEN induced putative kinase 1 |
| | PINK1 | | | | |
| SgK269 | Other, NKF3, SK649, | 79834 | — | 15q24.3 | KIAA2002 protein |
| | SgK269 | | | | |
| SgK223 | Other, NKF3, SK643, | 157285 | — | 8p23.1 | hypothetical protein |
| | SgK223 | | | | DKFZp761P0423 |
| CLIK1 | Other, NKF4, SK493, | 140901 | — | 20p13 | serine/threonine kinase 35 |
| | CLIK1 | | | | |
| CLIK1L | Other, NKF4, SK452, | 149420 | — | 1p36.11 | PDLIM1 interacting kinase 1 like |
| | CLIK1L | | | | |
| SgK307 | Other, NKF5, SK699, | 56155 | — | 17q23.2 | testis expressed sequence 14 |
| | SgK307 | | | | |
| NRBP1 | Other, NRBP, SK479, | 29959 | — | 2p23 | nuclear receptor binding protein |
| | NRBP1 | | | | |
| NRBP2 | Other, NRBP, SK520, | 340371 | — | 8q24.3 | nuclear receptor binding protein 2 |
| | NRBP2 | | | | |
| RNAseL | Other, Other- | 6041 | — | 1q25 | ribonuclease L (2′,5′- |
| | Unique, SK729, RNAseL | | | | oligoisoadenylate synthetase- |
| | | | | | dependent) |
| SgK396 | Other, Other- | 56164 | — | 7p15.3 | serine/threonine kinase 31 |
| | Unique, SK652, SgK396 | | | | |
| SgK196 | Other, Other- | 84197 | — | 8p11.21 | hypothetical protein FLJ23356 |
| | Unique, SK628, SgK196 | | | | |
| GCN2 | Other, PEK, GCN2, | 440275 | — | 15q15.1 | similar to GCN2 eIF2alpha kinase |
| | SK490, GCN2 | | | | |
| HRI | Other, PEK, SK496, | 27102 | — | 7p22 | eukaryotic translation initiation |
| | HRI | | | | factor 2-alpha kinase 1 |
| PEK | Other, PEK, PEK, SK281, | 9451 | — | 2p12 | eukaryotic translation initiation |
| | PEK | | | | factor 2-alpha kinase 3 |
| PKR | Other, PEK, SK119, | 5610 | — | 2p22-p21 | eukaryotic translation initiation |
| | PKR | | | | factor 2-alpha kinase 2 |
| PLK1 | Other, PLK, SK315, | 5347 | — | 16p12.1 | polo-like kinase 1 (Drosophila) |
| | PLK1 | | | | |
| PLK3 | Other, PLK, SK316, | 1263 | — | 1p34.1 | polo-like kinase 3 (Drosophila) |
| | PLK3 | | | | |
| PLK2 | Other, PLK, SK353, | 10769 | — | 5q12.1-q13.2 | polo-like kinase 2 (Drosophila) |
| | PLK2 | | | | |
| PLK4 | Other, PLK, SK341, | 10733 | — | 4q27-q28 | polo-like kinase 4 (Drosophila) |
| | PLK4 | | | | |
| SCYL2 | Other, SCY1, SK475, | 55681 | — | 12q23.1 | SCY1-like 2 (S. cerevisiae) |
| | SCYL2 | | | | |
| SCYL3 | Other, SCY1, SK468, | 57147 | — | 1q24.2 | ezrin-binding partner PACE-1 |
| | SCYL3 | | | | |
| SCYL1 | Other, SCY1, SK454, | 57410 | — | 11q13 | SCY1-like 1 (S. cerevisiae) |
| | SCYL1 | | | | |
| SgK071 | Other, Other- | 169436 | — | 9q34.2 | chromosome 9 open reading frame |
| | Unique, SK521, SgK071 | | | | 96 |
| SgK493 | Other, Other- | 91461 | — | 2p21 | hypothetical protein BC007901 |
| | Unique, SK460, SgK493 | | | | |
| SgK496 | Other, Other- | 25778 | — | 1q32.1 | receptor interacting protein kinase 5 |
| | Unique, SK516, SgK496 | | | | |
| Slob | Other, Slob, SK528, | 54899 | — | 3p14.3 | PX domain containing |
| | Slob | | | | serine/threonine kinase |
| TBCK | Other, TBCK, SK664, | 93627 | — | 4q24 | hypothetical protein MGC16169 |
| | TBCK | | | | |
| TLK1 | Other, TLK, SK373, | 9874 | — | 2q31.1 | tousled-like kinase 1 |
| | TLK1 | | | | |
| TLK2 | Other, TLK, SK374, | 11011 | — | 17q23 | tousled-like kinase 2 |
| | TLK2 | | | | |
| PBK | Other, TOPK, SK529, | 55872 | — | 8p21.2 | PDZ binding kinase |
| | PBK | | | | |
| TTK | Other, TTK, SK383, | 7272 | — | 6q13-q21 | TTK protein kinase |
| | TTK | | | | |
| Fused | Other, ULK, SK199, | 27148 | — | 2q35 | serine/threonine kinase 36 (fused |
| | Fused | | | | homolog, Drosophila) |
| ULK1 | Other, ULK, SK387, | 8408 | — | 12q24.3 | unc-51-like kinase 1 (C. elegans) |
| | ULK1 | | | | |
| ULK2 | Other, ULK, SK388, | 9706 | — | 17p11.2 | unc-51-like kinase 2 (C. elegans) |
| | ULK2 | | | | |
| ULK3 | Other, ULK, SK450, | 25989 | — | 15q24.1 | unc-51-like kinase 3 (C. elegans) |
| | ULK3 | | | | |
| ULK4 | Other, ULK, SK457, | 54986 | — | 3p22.1 | unc-51-like kinase 4 (C. elegans) |
| | ULK4 | | | | |
| PIK3R4 | Other, VPS15, SK262, | 30849 | — | 3q21.3 | phosphoinositide-3-kinase, |
| | PIK3R4 | | | | regulatory subunit 4, p150 |
| Wee1 | Other, WEE, SK391, | 7465 | — | 11p15.3-p15.1 | WEE1 homolog (S. pombe) |
| | Wee1 | | | | |
| PKMYT1 | Other, WEE, SK248, | 9088 | — | 16p13.3 | protein kinase, membrane |
| | MYT1 | | | | associated tyrosine/threonine 1 |
| Wee1B | Other, WEE, SK723, | 285962 | — | 7q34 | hypothetical protein FLJ40852 |
| | Wee1B | | | | |
| Wnk1 | Other, Wnk, SK508, | 65125 | — | 12p13.3 | WNK lysine deficient protein |
| | Wnk1 | | | | kinase 1 |
| Wnk4 | Other, Wnk, SK588, | 65266 | — | 17q21-q22 | WNK lysine deficient protein |
| | Wnk4 | | | | kinase 4 |
| Wnk3 | Other, Wnk, SK641, | 65267 | — | xp11.23-p11.21 | WNK lysine deficient protein |
| | Wnk3 | | | | kinase 3 |
| Wnk2 | Other, Wnk, SK016, | 65268 | — | 9q22.3 | WNK lysine deficient protein |
| | Wnk2 | | | | kinase 2 |
| HSER | RGC, RGC, SK171, | 2984 | — | 12p12 | guanylate cyclase 2C (heat stable |
| | HSER | | | | enterotoxin receptor) |
| CYGF | RGC, RGC, SK099, | 2986 | — | xq22 | guanylate cyclase 2F, retinal |
| | CYGF | | | | |
| CYGD | RGC, RGC, SK097, | 3000 | — | 17p13.1 | guanylate cyclase 2D, membrane |
| | CYGD | | | | (retina-specific) |
| ANPa | RGC, RGC, SK034, | 4881 | — | 1q21-q22 | natriuretic peptide receptor |
| | ANPa | | | | A/guanylate cyclase A |
| | | | | | (atrionatriuretic peptide receptor |
| | | | | | A) |
| ANPb | RGC, RGC, SK035, | 4882 | — | 9p21-p12 | natriuretic peptide receptor |
| | ANPb | | | | B/guanylate cyclase B |
| | | | | | (atrionatriuretic peptide receptor B) |
| MAP3K5 | STE, STE11, SK225, | 4217 | — | 6q22.33 | mitogen-activated protein kinase |
| | MAP3K5 | | | | kinase kinase 5 |
| MAP3K6 | STE, STE11, SK503, | 9064 | — | 1p36.11 | mitogen-activated protein kinase |
| | MAP3K6 | | | | kinase kinase 6 |
| MAP3K7 | STE, STE11, SK681, | 389840 | — | xp22.12 | mitogen-activated protein kinase |
| | MAP3K7 | | | | kinase kinase 15 |
| MAP3K1 | STE, STE11, SK221, | 4214 | — | 5q11.2 | mitogen-activated protein kinase |
| | MAP3K1 | | | | kinase kinase 1 |
| MAP3K8 | STE, STE11, SK573, | 80122 | — | 2q21.3 | hypothetical protein FLJ23074 |
| | MAP3K8 | | | | |
| MAP3K3 | STE, STE11, SK223, | 4215 | — | 17q23.3 | mitogen-activated protein kinase |
| | MAP3K3 | | | | kinase kinase 3 |
| MAP3K2 | STE, STE11, SK222, | 10746 | — | 2q14.3 | mitogen-activated protein kinase |
| | MAP3K2 | | | | kinase kinase 2 |
| MAP3K4 | STE, STE11, SK224, | 4216 | — | 6q26 | mitogen-activated protein kinase |
| | MAP3K4 | | | | kinase kinase 4 |
| OXSR1 | STE, STE20, FRAY, | 9943 | — | 3p22-p21.3 | oxidative-stress responsive 1 |
| | SK428, OSR1 | | | | |
| STLK3 | STE, STE20, FRAY, | 27347 | — | 2q24.3 | serine threonine kinase 39 |
| | SK432, STLK3 | | | | (STE20/SPS1 homolog, yeast) |
| MAP4K2 | STE, STE20, KHS, | 5871 | — | 11q13 | mitogen-activated protein kinase |
| | SK048, GCK | | | | kinase kinase kinase 2 |
| KHS2 | STE, STE20, KHS, | 8491 | — | 2p22.1 | mitogen-activated protein kinase |
| | SK427, KHS2 | | | | kinase kinase kinase 3 |
| KHS1 | STE, STE20, KHS, | 11183 | — | 14q11.2-q21 | mitogen-activated protein kinase |
| | SK191, KHS1 | | | | kinase kinase kinase 5 |
| HPK1 | STE, STE20, KHS, | 11184 | — | 19q13.1-q13.4 | mitogen-activated protein kinase |
| | SK170, HPK1 | | | | kinase kinase kinase 1 |
| HGK | STE, STE20, MSN, | 9448 | — | 2q11.2-q12 | mitogen-activated protein kinase |
| | SK437, ZC1 | | | | kinase kinase kinase 4 |
| TNIK | STE, STE20, MSN, | 23043 | — | 3q26.2 | TRAF2 and NCK interacting |
| | SK438, ZC2 | | | | kinase |
| NRK | STE, STE20, MSN, | 203447 | — | xq22.3 | Nik related kinase |
| | SK440, ZC4 | | | | |
| MINK | STE, STE20, MSN, | 50488 | — | 17p13.2 | misshapen-like kinase 1 (zebrafish) |
| | SK439, ZC3 | | | | |
| MST2 | STE, STE20, MST, | 6788 | — | 8q22.2 | serine/threonine kinase 3 (STE20 |
| | SK245, MST2 | | | | homolog, yeast) |
| MST1 | STE, STE20, MST, | 6789 | — | 20q11.2-q13.2 | serine/threonine kinase 4 |
| | SK244, MST1 | | | | |
| MYO3A | STE, STE20, NinaC, | 53904 | — | 10p11.1 | myosin IIIA |
| | SK636, MYO3A | | | | |
| MYO3B | STE, STE20, NinaC, | 140469 | — | 2q31.1-q31.2 | myosin IIIB |
| | SK583, MYO3B | | | | |
| PAK1 | STE, STE20, PAKA, | 5058 | — | 11q13-q14 | p21/Cdc42/Rac1-activated kinase 1 |
| | SK267, PAK1 | | | | (STE20 homolog, yeast) |
| PAK2 | STE, STE20, PAKA, | 5062 | 2.7.11.1 | 3q29 | p21 (CDKN1A)-activated kinase 2 |
| | SK268, PAK2 | | | | |
| PAK3 | STE, STE20, PAKA, | 5063 | — | xq22.3-q23 | p21 (CDKN1A)-activated kinase 3 |
| | SK269, PAK3 | | | | |
| PAK4 | STE, STE20, PAKB, | 10298 | — | 19q13.2 | p21(CDKN1A)-activated kinase 4 |
| | SK430, PAK4 | | | | |
| PAK6 | STE, STE20, PAKB, | 56924 | — | 15q14 | p21(CDKN1A)-activated kinase 6 |
| | SK429, PAK6 | | | | |
| PAK5 | STE, STE20, PAKB, | 57144 | — | 20p12 | p21(CDKN1A)-activated kinase 7 |
| | SK510, PAK5 | | | | |
| LOK | STE, STE20, SLK, SK426, | 6793 | — | 5q35.1 | serine/threonine kinase 10 |
| | LOK | | | | |
| SLK | STE, STE20, SLK, SK348, | 9748 | — | 10q25.1 | STE20-like kinase (yeast) |
| | SLK | | | | |
| STLK6 | STE, STE20, STLK, | 55437 | — | 2q33-q34 | amyotrophic lateral sclerosis 2 |
| | SK434, STLK6 | | | | (juvenile) chromosome region, |
| | | | | | candidate 2 |
| STLK5 | STE, STE20, STLK, | 92335 | — | 17q23.3 | protein kinase LYK5 |
| | SK433, STLK5 | | | | |
| TAO2 | STE, STE20, TAO, | 9344 | — | 16p11.2 | TAO kinase 2 |
| | SK362, TAO2 | | | | |
| TAO3 | STE, STE20, TAO, | 51347 | — | 12q | TAO kinase 3 |
| | SK435, TAO3 | | | | |
| TAO1 | STE, STE20, TAO, | 57551 | — | 17q11.2 | TAO kinase 1 |
| | SK436, TAO1 | | | | |
| MST3 | STE, STE20, YSK, | 8428 | — | 13q31.2-q32.3 | serine/threonine kinase 24 (STE20 |
| | SK246, MST3 | | | | homolog, yeast) |
| YSK1 | STE, STE20, YSK, | 10494 | — | 2q37.3 | serine/threonine kinase 25 (STE20 |
| | SK395, YSK1 | | | | homolog, yeast) |
| MST4 | STE, STE20, YSK, | 51765 | — | xq26.2 | Mst3 and SOK1-related kinase |
| | SK431, MST4 | | | | |
| MAP2K1 | STE, STE7, SK217, | 5604 | 2.7.12.2 | 15q22.1-q22.33 | mitogen-activated protein kinase |
| | MAP2K1 | | | | kinase 1 |
| MAP2K2 | STE, STE7, SK218, | 5605 | 2.7.12.2 | 19p13.3 | mitogen-activated protein kinase |
| | MAP2K2 | | | | kinase 2 |
| MAP2K3 | STE, STE7, SK238, | 5606 | — | 17q11.2 | mitogen-activated protein kinase |
| | MAP2K3 | | | | kinase 3 |
| MAP2K6 | STE, STE7, SK220, | 5608 | — | 17q24.3 | mitogen-activated protein kinase |
| | MAP2K6 | | | | kinase 6 |
| MAP2K4 | STE, STE7, SK239, | 6416 | 2.7.12.2 | 17p11.2 | mitogen-activated protein kinase |
| | MAP2K4 | | | | kinase 4 |
| MAP2K5 | STE, STE7, SK219, | 5607 | — | 15q23 | mitogen-activated protein kinase |
| | MAP2K5 | | | | kinase 5 |
| MAP2K7 | STE, STE7, SK230, | 5609 | 2.7.12.2 | 19p13.3-p13.2 | mitogen-activated protein kinase |
| | MAP2K7 | | | | kinase 7 |
| COT | STE, STE- | 1326 | — | 10p11.23 | mitogen-activated protein kinase |
| | Unique, SK093, COT | | | | kinase kinase 8 |
| NIK | STE, STE- | 9020 | — | 17q21 | mitogen-activated protein kinase |
| | Unique, SK253, NIK | | | | kinase kinase 14 |
| ABL1 | TK, Abl, SK006, ABL | 25 | — | 9q34.1 | v-abl Abelson murine leukemia |
| | | | | | viral oncogene homolog 1 |
| ABL2 | TK, Abl, SK037, ARG | 27 | — | 1q24-q25 | v-abl Abelson murine leukemia |
| | | | | | viral oncogene homolog 2 (arg, |
| | | | | | Abelson-related gene) |
| ACK | TK, Ack, SK009, ACK | 10188 | — | 3q29 | tyrosine kinase, non-receptor, 2 |
| TNK1 | TK, Ack, SK375, TNK1 | 8711 | — | 17p13.1 | tyrosine kinase, non-receptor, 1 |
| ALK | TK, Alk, SK024, ALK | 238 | — | 2p23 | anaplastic lymphoma kinase (Ki-1) |
| LTK | TK, Alk, SK209, LTK | 4058 | 2.7.1.112 | 15q15.1-q21.1 | leukocyte tyrosine kinase |
| AXL | TK, Axl, SK044, AXL | 558 | 2.7.1.112 | 19q13.1 | AXL receptor tyrosine kinase |
| TYRO3 | TK, Axl, SK386, TYRO3 | 7301 | 2.7.1.112 | 15q15.1-q21.1 | TYRO3 protein tyrosine kinase |
| MER | TK, Axl, SK226, MER | 10461 | — | 2q14.1 | c-mer proto-oncogene tyrosine |
| | | | | | kinase |
| CCK4 | TK, CCK4, SK411, | 5754 | 2.7.1.112 | 6p21.1-p12.2 | PTK7 protein tyrosine kinase 7 |
| | CCK4 | | | | |
| CSK | TK, Csk, SK095, CSK | 1445 | 2.7.10.1 | 15q23-q25 | c-src tyrosine kinase |
| CTK | TK, Csk, SK418, CTK | 4145 | — | 19p13.3 | megakaryocyte-associated tyrosine |
| | | | | | kinase |
| DDR1 | TK, DDR, SK400, DDR1 | 780 | 2.7.1.112 | 6p21.3 | discoidin domain receptor family, |
| | | | | | member 1 |
| DDR2 | TK, DDR, SK410, DDR2 | 4921 | 2.7.1.112 | 1q12-q23 | discoidin domain receptor family, |
| | | | | | member 2 |
| EGFR | TK, EGFR, SK118, | 1956 | — | 7p12 | epidermal growth factor receptor |
| | EGFR | | | | (erythroblastic leukemia viral (v- |
| | | | | | erb-b) oncogene homolog, avian) |
| ErbB2 | TK, EGFR, SK166, | 2064 | — | 17q21.1 | v-erb-b2 erythroblastic leukemia |
| | HER2 | | | | viral oncogene homolog 2, |
| | | | | | neuro/glioblastoma derived |
| | | | | | oncogene homolog (avian) |
| ErbB3 | TK, EGFR, SK167, | 2065 | — | 12q13 | v-erb-b2 erythroblastic leukemia |
| | HER3 | | | | viral oncogene homolog 3 (avian) |
| ErbB4 | TK, EGFR, SK168, | 2066 | — | 2q33.3-q34 | v-erb-a erythroblastic leukemia |
| | HER4 | | | | viral oncogene homolog 4 (avian) |
| EphA2 | TK, Eph, SK122, EphA2 | 1969 | 2.7.1.112 | 1p36 | EPH receptor A2 |
| EphA1 | TK, Eph, SK121, EphA1 | 2041 | 2.7.1.112 | 7q34 | EPH receptor A1 |
| EphA3 | TK, Eph, SK123, EphA3 | 2042 | 2.7.1.112 | 3p11.2 | EPH receptor A3 |
| EphA4 | TK, Eph, SK124, EphA4 | 2043 | 2.7.1.112 | 2q36.1 | EPH receptor A4 |
| EphA5 | TK, Eph, SK125, EphA5 | 2044 | — | 4q13.1 | EPH receptor A5 |
| EphA7 | TK, Eph, SK416, EphA7 | 2045 | — | 6q16.1 | EPH receptor A7 |
| EphA8 | TK, Eph, SK126, EphA8 | 2046 | 2.7.1.112 | 1p36.12 | EPH receptor A8 |
| EphB1 | TK, Eph, SK127, EphB1 | 2047 | — | 3q21-q23 | EPH receptor B1 |
| EphB2 | TK, Eph, SK128, EphB2 | 2048 | 2.7.1.112 | 1p36.1-p35 | EPH receptor B2 |
| EphB3 | TK, Eph, SK129, EphB3 | 2049 | — | 3q21-qter | EPH receptor B3 |
| EphB4 | TK, Eph, SK130, EphB4 | 2050 | — | 7q22 | EPH receptor B4 |
| EphB6 | TK, Eph, SK132, EphB6 | 2051 | — | 7q33-q35 | EPH receptor B6 |
| EphA10 | TK, Eph, SK627, EphA10 | 284656 | — | 1p34.3 | EPH receptor A10 |
| EphA6 | TK, Eph, SK646, EphA6 | 285220 | — | 3q11.2 | EPH receptor A6 |
| PYK2 | TK, FAK, SK424, PYK2 | 2185 | — | 8p21.1 | PTK2B protein tyrosine kinase 2 |
| | | | | | beta |
| FAK | TK, FAK, SK138, FAK | 5747 | 2.7.1.112 | 8q24-qter | PTK2 protein tyrosine kinase 2 |
| FER | TK, Fer, SK140, FER | 2241 | 2.7.1.112 | 5q21 | fer (fps/fes related) tyrosine kinase |
| | | | | | (phosphoprotein NCP94) |
| FES | TK, Fer, SK142, FES | 2242 | — | 15q26.1 | feline sarcoma oncogene |
| FGFR1 | TK, FGFR, SK143, | 2260 | 2.7.1.112 | 8p11.2-p11.1 | fibroblast growth factor receptor 1 |
| | FGFR1 | | | | (fms-related tyrosine kinase 2, |
| | | | | | Pfeiffer syndrome) |
| FGFR3 | TK, FGFR, SK145, | 2261 | — | 4p16.3 | fibroblast growth factor receptor 3 |
| | FGFR3 | | | | (achondroplasia, thanatophoric |
| | | | | | dwarfism) |
| FGFR2 | TK, FGFR, SK144, | 2263 | — | 10q26 | fibroblast growth factor receptor 2 |
| | FGFR2 | | | | (bacteria-expressed kinase, |
| | | | | | keratinocyte growth factor |
| | | | | | receptor, craniofacial dysostosis 1, |
| | | | | | Crouzon syndrome, Pfeiffer |
| | | | | | syndrome, Jackson-Weiss |
| | | | | | syndrome) |
| FGFR4 | TK, FGFR, SK147, | 2264 | — | 5q35.1-qter | fibroblast growth factor receptor 4 |
| | FGFR4 | | | | |
| IGF1R | TK, InsR, SK174, IGF1R | 3480 | — | 15q26.3 | insulin-like growth factor 1 |
| | | | | | receptor |
| INSR | TK, InsR, SK178, INSR | 3643 | — | 19p13.3-p13.2 | insulin receptor |
| IRR | TK, InsR, SK183, IRR | 3645 | — | 1q21-q23 | insulin receptor-related receptor |
| JAK1 | TK, JakA, SK185, JAK1 | 3716 | 2.7.1.112 | 1p32.3-p31.3 | Janus kinase 1 (a protein tyrosine |
| | | | | | kinase) |
| JAK2 | TK, JakA, SK186, JAK2 | 3717 | 2.7.1.112 | 9p24 | Janus kinase 2 (a protein tyrosine |
| | | | | | kinase) |
| JAK3 | TK, JakA, SK187, JAK3 | 3718 | — | 19p13.1 | Janus kinase 3 (a protein tyrosine |
| | | | | | kinase, leukocyte) |
| TYK2 | TK, JakA, SK385, TYK2 | 7297 | 2.7.1.112 | 19p13.2 | tyrosine kinase 2 |
| LMR1 | TK, Lmr, SK413, LMR1 | 9625 | — | 17q25.3 | apoptosis-associated tyrosine |
| | | | | | kinase |
| LMR2 | TK, Lmr, SK414, LMR2 | 22853 | — | 7q21.3 | lemur tyrosine kinase 2 |
| LMR3 | TK, Lmr, SK415, LMR3 | 114783 | — | 19q13.32 | lemur tyrosine kinase 3 |
| MET | TK, Met, SK227, MET | 4233 | — | 7q31 | met proto-oncogene (hepatocyte |
| | | | | | growth factor receptor) |
| RON | TK, Met, SK332, RON | 4486 | — | 3p21.3 | macrophage stimulating 1 receptor |
| | | | | | (c-met-related tyrosine kinase) |
| MUSK | TK, Musk, SK247, | 4593 | — | 9q31.3-q32 | muscle, skeletal, receptor tyrosine |
| | MUSK | | | | kinase |
| FMS | TK, PDGFR, SK094, | 1436 | — | 5q33-q35 | colony stimulating factor 1 |
| | FMS | | | | receptor, formerly McDonough |
| | | | | | feline sarcoma viral (v-fms) |
| | | | | | oncogene homolog |
| FLT3 | TK, PDGFR, SK149, | 2322 | 2.7.1.112 | 13q12 | fms-related tyrosine kinase 3 |
| | FLT3 | | | | |
| KIT | TK, PDGFR, SK201, | 3815 | — | 4q11-q12 | v-kit Hardy-Zuckerman 4 feline |
| | KIT | | | | sarcoma viral oncogene homolog |
| PDGFRa | TK, PDGFR, SK274, | 5156 | — | 4q11-q13 | platelet-derived growth factor |
| | PDGFRa | | | | receptor, alpha polypeptide |
| PDGFRb | TK, PDGFR, SK275, | 5159 | — | 5q31-q32 | platelet-derived growth factor |
| | PDGFRb | | | | receptor, beta polypeptide |
| RET | TK, Ret, SK326, RET | 5979 | — | 10q11.2 | ret proto-oncogene (multiple |
| | | | | | endocrine neoplasia and medullary |
| | | | | | thyroid carcinoma 1, Hirschsprung |
| | | | | | disease) |
| ROR1 | TK, Ror, SK333, ROR1 | 4919 | — | 1p32-p31 | receptor tyrosine kinase-like |
| | | | | | orphan receptor 1 |
| ROR2 | TK, Ror, SK334, ROR2 | 4920 | — | 9q22 | receptor tyrosine kinase-like |
| | | | | | orphan receptor 2 |
| RYK | TK, Ryk, SK340, RYK | 6259 | 2.7.1.112 | 3q22 | RYK receptor-like tyrosine kinase |
| ROS | TK, Sev, SK335, ROS | 6098 | — | 6q22 | v-ros UR2 sarcoma virus oncogene |
| | | | | | homolog 1 (avian) |
| FRK | TK, Src, SK419, FRK | 2444 | 2.7.1.112 | 6q21-q22.3 | fyn-related kinase |
| FGR | TK, Src, SK148, FGR | 2268 | — | 1p36.2-p36.1 | Gardner-Rasheed feline sarcoma |
| | | | | | viral (v-fgr) oncogene homolog |
| FYN | TK, Src, SK153, FYN | 2534 | — | 6q21 | FYN oncogene related to SRC, |
| | | | | | FGR, YES |
| SRC | TK, Src, SK357, SRC | 6714 | — | 20q12-q13 | v-src sarcoma (Schmidt-Ruppin A- |
| | | | | | 2) viral oncogene homolog (avian) |
| YES | TK, Src, SK393, YES | 7525 | — | 18p11.31-p11.21 | v-yes-1 Yamaguchi sarcoma viral |
| | | | | | oncogene homolog 1 |
| BLK | TK, Src, SK049, BLK | 640 | — | 8p23-p22 | B lymphoid tyrosine kinase |
| HCK | TK, Src, SK164, HCK | 3055 | — | 20q11-q12 | hemopoietic cell kinase |
| LCK | TK, Src, SK206, LCK | 3932 | 2.7.1.112 | 1p34.3 | lymphocyte-specific protein |
| | | | | | tyrosine kinase |
| LYN | TK, Src, SK210, LYN | 4067 | — | 8q13 | v-yes-1 Yamaguchi sarcoma viral |
| | | | | | related oncogene homolog |
| BRK | TK, Src, SK051, BRK | 5753 | 2.7.1.112 | 20q13.3 | PTK6 protein tyrosine kinase 6 |
| SRM | TK, Src, SK425, SRM | 6725 | — | 20q13.33 | src-related kinase lacking C- |
| | | | | | terminal regulatory tyrosine and N- |
| | | | | | terminal myristylation sites |
| SYK | TK, Syk, SK363, SYK | 6850 | — | 9q22 | spleen tyrosine kinase |
| ZAP70 | TK, Syk, SK397, ZAP70 | 7535 | — | 2q12 | zeta-chain (TCR) associated |
| | | | | | protein kinase 70 kDa |
| BMX | TK, Tec, SK417, BMX | 660 | — | xp22.2 | BMX non-receptor tyrosine kinase |
| BTK | TK, Tec, SK052, BTK | 695 | 2.7.1.112 | xq21.33-q22 | Bruton agammaglobulinemia |
| | | | | | tyrosine kinase |
| ITK | TK, Tec, SK184, ITK | 3702 | — | 5q31-q32 | IL2-inducible T-cell kinase |
| TEC | TK, Tec, SK366, TEC | 7006 | — | 4p12 | tec protein tyrosine kinase |
| TXK | TK, Tec, SK384, TXK | 7294 | 2.7.1.112 | 4p12 | TXK tyrosine kinase |
| TIE2 | TK, Tie, SK367, TIE2 | 7010 | — | 9p21 | TEK tyrosine kinase, endothelial |
| | | | | | (venous malformations, multiple |
| | | | | | cutaneous and mucosal) |
| TIE1 | TK, Tie, SK370, TIE1 | 7075 | 2.7.1.112 | 1p34-p33 | tyrosine kinase with |
| | | | | | immunoglobulin-like and EGF-like |
| | | | | | domains 1 |
| SuRTK106 | TK, TK- | 55359 | — | 12p13.2 | serine/threonine/tyrosine kinase 1 |
| | Unique, SK530, SuRTK106 | | | | |
| TRKA | TK, Trk, SK377, TRKA | 4914 | 2.7.1.112 | 1q21-q22 | neurotrophic tyrosine kinase, |
| | | | | | receptor, type 1 |
| TRKB | TK, Trk, SK378, TRKB | 4915 | 2.7.1.112 | 9q22.1 | neurotrophic tyrosine kinase, |
| | | | | | receptor, type 2 |
| TRKC | TK, Trk, SK379, TRKC | 4916 | 2.7.1.112 | 15q25 | neurotrophic tyrosine kinase, |
| | | | | | receptor, type 3 |
| FLT1 | TK, VEGFR, SK150, | 2321 | 2.7.1.112 | 13q12 | fms-related tyrosine kinase 1 |
| | FLT1 | | | | (vascular endothelial growth |
| | | | | | factor/vascular permeability factor |
| | | | | | receptor) |
| FLT4 | TK, VEGFR, SK151, | 2324 | 2.7.1.112 | 5q34-q35 | fms-related tyrosine kinase 4 |
| | FLT4 | | | | |
| KDR | TK, VEGFR, SK402, | 3791 | 2.7.1.112 | 4q11-q12 | kinase insert domain receptor (a |
| | KDR | | | | type III receptor tyrosine kinase) |
| IRAK1 | TKL, IRAK, SK179, | 3654 | — | xq28 | interleukin-1 receptor-associated |
| | IRAK1 | | | | kinase 1 |
| IRAK2 | TKL, IRAK, SK180, | 3656 | — | 3p25.3 | interleukin-1 receptor-associated |
| | IRAK2 | | | | kinase 2 |
| IRAK3 | TKL, IRAK, SK181, | 11213 | — | 12q14.3 | interleukin-1 receptor-associated |
| | IRAK3 | | | | kinase 3 |
| IRAK4 | TKL, IRAK, SK257, | 51135 | — | 12q12 | interleukin-1 receptor-associated |
| | IRAK4 | | | | kinase 4 |
| LIMK1 | TKL, LISK, LIMK, | 3984 | — | 7q11.23 | LIM domain kinase 1 |
| | SK412, LIMK1 | | | | |
| LIMK2 | TKL, LISK, LIMK, | 3985 | — | 22q12.2 | LIM domain kinase 2 |
| | SK207, LIMK2 | | | | |
| TESK1 | TKL, LISK, TESK, | 7016 | EC, | 9p13 | testis-specific kinase 1 |
| | SK368, TESK1 | | 2.7.12.1 | | |
| TESK2 | TKL, LISK, TESK, | 10420 | — | 1p32 | testis-specific kinase 2 |
| | SK532, TESK2 | | | | |
| LRRK1 | TKL, LRRK, SK698, | 79705 | — | 15q26.3 | leucine-rich repeat kinase 1 |
| | LRRK1 | | | | |
| LRRK2 | TKL, LRRK, SK690, | 120892 | — | 12q12 | leucine-rich repeat kinase 2 |
| | LRRK2 | | | | |
| HH498 | TKL, MLK, HH498, | 51086 | — | 1p31.1 | TNNI3 interacting kinase |
| | SK494, HH498 | | | | |
| ILK | TKL, MLK, ILK, SK177, | 3611 | — | 11p15.5-p15.4 | integrin-linked kinase |
| | ILK | | | | |
| DLK | TKL, MLK, LZK, SK110, | 7786 | — | 12q13 | mitogen-activated protein kinase |
| | DLK | | | | kinase kinase 12 |
| LZK | TKL, MLK, LZK, SK398, | 9175 | — | 3q27 | mitogen-activated protein kinase |
| | LZK | | | | kinase kinase 13 |
| MLK1 | TKL, MLK, MLK, SK232, | 4293 | — | 14q24.3-q31 | mitogen-activated protein kinase |
| | MLK1 | | | | kinase kinase 9 |
| MLK2 | TKL, MLK, MLK, SK233, | 4294 | — | 19q13.2 | mitogen-activated protein kinase |
| | MLK2 | | | | kinase kinase 10 |
| MLK3 | TKL, MLK, MLK, SK356, | 4296 | 2.7.10.1 | 11q13.1-q13.3 | mitogen-activated protein kinase |
| | MLK3 | | | | kinase kinase 11 |
| MLK4 | TKL, MLK, MLK, SK691, | 84451 | — | 1q42 | mixed lineage kinase 4 |
| | MLK4 | | | | |
| TAK1 | TKL, MLK, TAK1, | 6885 | — | 6q16.1-q16.3 | mitogen-activated protein kinase |
| | SK364, TAK1 | | | | kinase kinase 7 |
| ZAK | TKL, MLK, MLK, SK504, | 51776 | — | 2q24.2 | sterile alpha motif and leucine |
| | ZAK | | | | zipper containing kinase AZK |
| KSR1 | TKL, RAF, SK205, | 8844 | — | 17q11.2 | kinase suppressor of ras |
| | KSR1 | | | | |
| KSR2 | TKL, RAF, SK605, | 283455 | — | 12q24.22-q24.23 | kinase suppressor of ras 2 |
| | KSR2 | | | | |
| ARAF | TKL, RAF, SK036, | 369 | — | xp11.4-p11.2 | v-raf murine sarcoma 3611 viral |
| | ARAF | | | | oncogene homolog |
| BRAF | TKL, RAF, SK050, | 673 | — | 7q34 | v-raf murine sarcoma viral |
| | BRAF | | | | oncogene homolog B1 |
| RAF1 | TKL, RAF, SK324, | 5894 | — | 3p25 | v-raf-1 murine leukemia viral |
| | RAF1 | | | | oncogene homolog 1 |
| RIPK1 | TKL, RIPK, SK328, | 8737 | — | 6p25.2 | receptor (TNFRSF)-interacting |
| | RIPK1 | | | | serine-threonine kinase 1 |
| RIPK2 | TKL, RIPK, SK329, | 8767 | — | 8q21 | receptor-interacting serine- |
| | RIPK2 | | | | threonine kinase 2 |
| RIPK3 | TKL, RIPK, SK330, | 11035 | — | 14q11.2 | receptor-interacting serine- |
| | RIPK3 | | | | threonine kinase 3 |
| ANKRD3 | TKL, RIPK, SK546, | 54101 | — | 21q22.3 | receptor-interacting serine- |
| | ANKRD3 | | | | threonine kinase 4 |
| SgK288 | TKL, RIPK, SK658, | 255239 | — | 11q23.2 | ankyrin repeat and kinase domain |
| | SgK288 | | | | containing 1 |
| ALK2 | TKL, STKR, Type1, | 90 | — | 2q23-q24 | activin A receptor, type I |
| | SK026, ALK2 | | | | |
| ALK4 | TKL, STKR, Type1, | 91 | — | 12q13 | activin A receptor, type IB |
| | SK028, ALK4 | | | | |
| ALK1 | TKL, STKR, Type1, | 94 | — | 12q11-q14 | activin A receptor type II-like 1 |
| | SK025, ALK1 | | | | |
| BMPR1A | TKL, STKR, Type1, | 657 | — | 10q22.3 | bone morphogenetic protein |
| | SK027, BMPR1A | | | | receptor, type IA |
| BMPR1B | TKL, STKR, Type1, | 658 | — | 4q22-q24 | bone morphogenetic protein |
| | SK030, BMPR1B | | | | receptor, type IB |
| TGFbR1 | TKL, STKR, Type1, | 7046 | — | 9q22 | transforming growth factor, beta |
| | SK029, TGFbR1 | | | | receptor I (activin A receptor type |
| | | | | | II-like kinase, 53 kDa) |
| ALK7 | TKL, STKR, Type1, | 130399 | — | 2q24.1 | activin A receptor, type IC |
| | SK405, ALK7 | | | | |
| ACVR2A | TKL, STKR, Type2, | 92 | — | 2q22.2-q23.3 | activin A receptor, type II |
| | SK010, ACTR2 | | | | |
| ACTR2B | TKL, STKR, Type2, | 93 | — | 3p22 | activin A receptor, type IIB |
| | SK011, ACTR2B | | | | |
| MISR2 | TKL, STKR, Type2, | 269 | — | 12q13 | anti-Mullerian hormone receptor, |
| | SK228, MISR2 | | | | type II |
| BMPR2 | TKL, STKR, Type2, | 659 | — | 2q33-q34 | bone morphogenetic protein |
| | SK365, BMPR2 | | | | receptor, type II (serine/threonine |
| | | | | | kinase) |
| TGFbR2 | TKL, STKR, Type2, | 7048 | — | 3p22 | transforming growth factor, beta |
| | SK369, TGFbR2 | | | | receptor II (70/80 kDa) |
| MLKL | TKL, TKL- | 197259 | — | 16q22.3 | mixed lineage kinase domain-like |
| | Unique, SK458, MLKL | | | | |
| ABCB10 | others | 23456 | — | 1q42 | ATP-binding cassette, sub-family |
| | | | | | B (MDR/TAP), member 10 |
| ABCB8 | others | 11194 | — | 7q36 | ATP-binding cassette, sub-family |
| | | | | | B (MDR/TAP), member 8 |
| ABCG1 | others | 9619 | — | 21q22.3 | ATP-binding cassette, sub-family |
| | | | | | G (WHITE), member 1 |
| ACTR2 | others | 10097 | — | 2p14 | ARP2 actin-related protein 2 |
| | | | | | homolog (yeast) |
| ADCY3 | others | 109 | 4.6.1.1 | 2p24-p22 | adenylate cyclase 3 |
| ADCY6 | others | 112 | 4.6.1.1 | 12q12-q13 | adenylate cyclase 6 |
| ADCY7 | others | 113 | 4.6.1.1 | 16q12-q13 | adenylate cyclase 7 |
| ADCY8 | others | 114 | 4.6.1.1 | 8q24 | adenylate cyclase 8 (brain) |
| ADCY9 | others | 115 | 4.6.1.1 | 16p13.3 | adenylate cyclase 9 |
| ADK | others | 132 | 2.7.1.20 | 10q22 | adenosine kinase |
| AK3L1 | others | 205 | 2.7.4.10 | 1p31.3 | adenylate kinase 3 |
| ALDH18A1 | others | 5832 | — | 10q24.3 | aldehyde dehydrogenase 18 family, |
| | | | | | member A1 |
| ALS2CR11 | others | 151254 | — | 2q33.1 | amyotrophic lateral sclerosis 2 |
| | | | | | (juvenile) chromosome region, |
| | | | | | candidate 11 |
| ALS2CR12 | others | 130540 | — | 2q33.1 | amyotrophic lateral sclerosis 2 |
| | | | | | (juvenile) chromosome region, |
| | | | | | candidate 12 |
| ALS2CR13 | others | 150864 | — | 2q33.2 | amyotrophic lateral sclerosis 2 |
| | | | | | (juvenile) chromosome region, |
| | | | | | candidate 13 |
| ICA1L | others | 130026 | — | 2q33.2 | amyotrophic lateral sclerosis 2 |
| | | | | | (juvenile) chromosome region, |
| | | | | | candidate 15 |
| PARD3B | others | 117583 | — | 2q33.3 | amyotrophic lateral sclerosis 2 |
| | | | | | (juvenile) chromosome region, |
| | | | | | candidate 19 |
| TRAK2 | others | 66008 | — | 2q33 | amyotrophic lateral sclerosis 2 |
| | | | | | (juvenile) chromosome region, |
| | | | | | candidate 3 |
| ALS2CR4 | others | 65062 | — | 2q33.2 | amyotrophic lateral sclerosis 2 |
| | | | | | (juvenile) chromosome region, |
| | | | | | candidate 4 |
| ALS2CR8 | others | 79800 | — | 2q33.2 | amyotrophic lateral sclerosis 2 |
| | | | | | (juvenile) chromosome region, |
| | | | | | candidate 8 |
| DBF4 | others | 10926 | — | 7q21.3 | activator of S phase kinase |
| MAGI1 | others | 9223 | — | 3p14.1 | BAI1-associated protein 1 |
| BUB3 | others | 9184 | — | 10q26 | BUB3 budding uninhibited by |
| | | | | | benzimidazoles 3 homolog (yeast) |
| IPPK | others | 64768 | — | 9q21.33-q22.31 | chromosome 9 open reading frame |
| | | | | | 12 |
| CARD11 | others | 84433 | — | 7p22 | caspase recruitment domain family, |
| | | | | | member 11 |
| CARD14 | others | 79092 | — | 17q25 | caspase recruitment domain family, |
| | | | | | member 14 |
| CARKL | others | 23729 | 2.7.1.14 | 17p13 | carbohydrate kinase-like |
| CHKB | others | 1120 | — | 22q13.33 | choline kinase beta |
| CINP | others | 51550 | — | 14q32.32 | cyclin-dependent kinase 2- |
| | | | | | interacting protein |
| CKB | others | 1152 | 2.7.3.2 | 14q32 | creatine kinase, brain |
| CKM | others | 1158 | 2.7.3.2 | 19q13.2-q13.3 | creatine kinase, muscle |
| CKMT1A | others | 548596 | 2.7.3.2 | 15q15 | creatine kinase, mitochondrial 1A |
| CKMT1B | others | 1159 | 2.7.3.2 | 15q15 | creatine kinase, mitochondrial 1 |
| | | | | | (ubiquitous) |
| CKMT2 | others | 1160 | 2.7.3.2 | 5q13.3 | creatine kinase, mitochondrial 2 |
| | | | | | (sarcomeric) |
| CKS1B | others | 1163 | — | 1q21.2 | CDC28 protein kinase regulatory |
| | | | | | subunit 1B |
| CKS2 | others | 1164 | — | 9q22 | CDC28 protein kinase regulatory |
| | | | | | subunit 2 |
| CMPK | others | 51727 | 2.7.4.14 | 1p34.1-p33 | UMP-CMP kinase |
| CNKSR2 | others | 22866 | — | xp22.12 | connector enhancer of kinase |
| | | | | | suppressor of Ras 2 |
| COASY | others | 80347 | 2.7.7.3 | 17q12-q21 | Coenzyme A synthase |
| COL4A3BP | others | 10087 | — | 5q13.3 | collagen, type IV, alpha 3 |
| | | | | | (Goodpasture antigen) binding |
| | | | | | protein |
| COPB1 | others | 1315 | — | 11p15.2 | coatomer protein complex, subunit |
| | | | | | beta |
| COPB2 | others | 9276 | — | 3q23 | coatomer protein complex, subunit |
| | | | | | beta 2 (beta prime) |
| DCK | others | 1633 | 2.7.1.74 | 4q13.3-q21.1 | deoxycytidine kinase |
| DDX1 | others | 1653 | — | 2p24 | DEAD (Asp-Glu-Ala-Asp) box |
| | | | | | polypeptide 1 |
| DGKA | others | 1606 | 2.7.1.107 | 12q13.3 | diacylglycerol kinase, alpha 80 kDa |
| DGKB | others | 1607 | 2.7.1.107 | 7p21.3 | diacylglycerol kinase, beta 90 kDa |
| DGKD | others | 8527 | — | 2q37.1 | diacylglycerol kinase, delta |
| | | | | | 130 kDa |
| DGKE | others | 8526 | — | 17q22 | diacylglycerol kinase, epsilon |
| | | | | | 64 kDa |
| DGKH | others | 160851 | — | 13q14.11 | diacylglycerol kinase, eta |
| DGKG | others | 1608 | 2.7.1.107 | 3q27-q28 | diacylglycerol kinase, gamma |
| | | | | | 90 kDa |
| DGKI | others | 9162 | — | 7q32.3-q33 | diacylglycerol kinase, iota |
| DGKQ | others | 1609 | — | 4p16.3 | diacylglycerol kinase, theta |
| | | | | | 110 kDa |
| DGKZ | others | 8525 | — | 11p11.2 | diacylglycerol kinase, zeta 104 kDa |
| DGUOK | others | 1716 | 2.7.1.113 | 2p13 | deoxyguanosine kinase |
| DLG1 | others | 1739 | — | 3q29 | discs, large homolog 1 |
| | | | | | (Drosophila) |
| DLG2 | others | 1740 | — | 11q21 | discs, large homolog 2, chapsyn- |
| | | | | | 110 (Drosophila) |
| DLG3 | others | 1741 | — | xq13.1 | discs, large homolog 3 |
| | | | | | (neuroendocrine-dlg, Drosophila) |
| DLG4 | others | 1742 | — | 17p13.1 | discs, large homolog 4 |
| | | | | | (Drosophila) |
| DLG5 | others | 9231 | — | 10q23 | discs, large homolog 5 |
| | | | | | (Drosophila) |
| DTYMK | others | 1841 | 2.7.4.9 | 2q37.3 | deoxythymidylate kinase |
| | | | | | (thymidylate kinase) |
| ETNK1 | others | 55500 | — | 12p12.1 | ethanolamine kinase 1 |
| EVI1 | others | 2122 | — | 3q24-q28 | ecotropic viral integration site 1 |
| ETNK2 | others | 55224 | — | 1q32.1 | ethanolamine kinase 2 |
| OXSM | others | 54995 | 2.3.1.41 | 3p24.2 | hypothetical protein FLJ20604 |
| FN3K | others | 64122 | — | 17q25.3 | fructosamine 3 kinase |
| FXN | others | 2395 | — | 9q13-q21.1 | frataxin |
| GALK2 | others | 2585 | 2.7.1.6 | 15q21.1 | galactokinase 2 |
| GK | others | 2710 | 2.7.1.30 | xp21.3 | glycerol kinase |
| GK2 | others | 2712 | — | 4q13 | glycerol kinase 2 |
| GNE | others | 10020 | — | 9p13.2 | glucosamine (UDP-N-acetyl)-2- |
| | | | | | epimerase/N-acetylmannosamine |
| | | | | | kinase |
| GUCY1A2 | others | 2977 | 4.6.1.2 | 11q21-q22 | guanylate cyclase 1, soluble, alpha 2 |
| GUCY1A3 | others | 2982 | 4.6.1.2 | 4q31.1-q31.2 | guanylate cyclase 1, soluble, alpha 3 |
| GUCY1B3 | others | 2983 | 4.6.1.2 | 4q31.3-q33 | guanylate cyclase 1, soluble, beta 3 |
| GUK1 | others | 2987 | 2.7.4.8 | 1q32-q41 | guanylate kinase 1 |
| IHPK2 | others | 51447 | — | 3p21.31 | inositol hexaphosphate kinase 2 |
| IKBKAP | others | 8518 | — | 9q31 | inhibitor of kappa light polypeptide |
| | | | | | gene enhancer in B-cells, kinase |
| | | | | | complex-associated protein |
| CNKSR1 | others | 10256 | — | 1p36.11 | connector enhancer of kinase |
| | | | | | suppressor of Ras 1 |
| MBIP | others | 51562 | — | 14q13.3 | MAP3K12 binding inhibitory |
| | | | | | protein 1 |
| KCNE1 | others | 3753 | — | 21q22.12 | potassium voltage-gated channel, |
| | | | | | Isk-related family, member 1 |
| MPP1 | others | 4354 | — | xq28 | membrane protein, palmitoylated |
| | | | | | 1, 55 kDa |
| MPP2 | others | 4355 | — | 17q12-q21 | membrane protein, palmitoylated 2 |
| | | | | | (MAGUK p55 subfamily member |
| | | | | | 2) |
| MPP3 | others | 4356 | — | 17q12-q21 | membrane protein, palmitoylated 3 |
| | | | | | (MAGUK p55 subfamily member |
| | | | | | 3) |
| MPP4 | others | 58538 | — | 2q33.2 | membrane protein, palmitoylated 4 |
| | | | | | (MAGUK p55 subfamily member |
| | | | | | 4) |
| MPP5 | others | 64398 | — | 14q23.3 | membrane protein, palmitoylated 5 |
| | | | | | (MAGUK p55 subfamily member |
| | | | | | 5) |
| MPP6 | others | 51678 | — | 7p15 | membrane protein, palmitoylated 6 |
| | | | | | (MAGUK p55 subfamily member |
| | | | | | 6) |
| MPP7 | others | 143098 | — | 10p12.1 | membrane protein, palmitoylated 7 |
| | | | | | (MAGUK p55 subfamily member |
| | | | | | 7) |
| MVK | others | 4598 | 2.7.1.36 | 12q24 | mevalonate kinase (mevalonic |
| | | | | | aciduria) |
| NAGK | others | 55577 | 2.7.1.59 | 2p13.3 | N-acetylglucosamine kinase |
| NDUFA10 | others | 4705 | — | 2q37.3 | NADH dehydrogenase |
| | | | | | (ubiquinone) 1 alpha subcomplex, |
| | | | | | 10, 42 kDa |
| NME1 | others | 4830 | — | 17q21.3 | non-metastatic cells 1, protein |
| | | | | | (NM23A) expressed in |
| NME2 | others | 4831 | — | 17q21.3 | non-metastatic cells 2, protein |
| | | | | | (NM23B) expressed in |
| NME3 | others | 4832 | — | 16q13 | non-metastatic cells 3, protein |
| | | | | | expressed in |
| NME4 | others | 4833 | — | 16p13.3 | non-metastatic cells 4, protein |
| | | | | | expressed in |
| NME5 | others | 8382 | — | 5q31 | non-metastatic cells 5, protein |
| | | | | | expressed in (nucleoside- |
| | | | | | diphosphate kinase) |
| NME6 | others | 10201 | — | 3p21 | non-metastatic cells 6, protein |
| | | | | | expressed in (nucleoside- |
| | | | | | diphosphate kinase) |
| NME7 | others | 29922 | — | 1q24 | non-metastatic cells 7, protein |
| | | | | | expressed in (nucleoside- |
| | | | | | diphosphate kinase) |
| NPR3 | others | 4883 | — | 5p14-p13 | natriuretic peptide receptor |
| | | | | | C/guanylate cyclase C |
| | | | | | (atrionatriuretic peptide receptor C) |
| NSF | others | 4905 | — | 17q21 | N-ethylmaleimide-sensitive factor |
| NUBP1 | others | 4682 | — | 16p13.13 | nucleotide binding protein 1 (MinD |
| | | | | | homolog, E. coli) |
| NUBP2 | others | 10101 | — | 16p13.3 | nucleotide binding protein 2 (MinD |
| | | | | | homolog, E. coli) |
| PACSIN1 | others | 29993 | — | 6p21.3 | protein kinase C and casein kinase |
| | | | | | substrate in neurons 1 |
| PANK1 | others | 53354 | — | 10q23.31 | pantothenate kinase 1 |
| PANK2 | others | 80025 | — | 20p13 | pantothenate kinase 2 |
| | | | | | (Hallervorden-Spatz syndrome) |
| PANK3 | others | 79646 | — | 5q34 | pantothenate kinase 3 |
| PANK4 | others | 55229 | — | 1p36.32 | pantothenate kinase 4 |
| PAPSS1 | others | 9061 | 2.7.7.4, 2.7 | 4q24 | 3′-phosphoadenosine 5′- |
| | | | | | phosphosulfate synthase 1 |
| PAPSS2 | others | 9060 | 2.7.7.4, | 10q23-q24 | 3′-phosphoadenosine 5′- |
| | | | 2.7.1.25 | | phosphosulfate synthase 2 |
| PCK1 | others | 5105 | 4.1.1.32 | 20q13.31 | phosphoenolpyruvate |
| | | | | | carboxykinase 1 (soluble) |
| PCK2 | others | 5106 | 4.1.1.32 | 14q11.2 | phosphoenolpyruvate |
| | | | | | carboxykinase 2 (mitochondrial) |
| PDXK | others | 8566 | 2.7.1.35 | 21q22.3 | pyridoxal (pyridoxine, vitamin B6) |
| | | | | | kinase |
| PFKL | others | 5211 | 2.7.1.11 | 21q22.3 | phosphofructokinase, liver |
| PFKM | others | 5213 | 2.7.1.11 | 12q13.3 | phosphofructokinase, muscle |
| PFKP | others | 5214 | 2.7.1.11 | 10p15.3-p15.2 | phosphofructokinase, platelet |
| PI4K2B | others | 55300 | — | 4p15.2 | phosphatidylinositol 4-kinase type- |
| | | | | | II beta |
| PI4K2A | others | 55361 | — | 10q24 | phosphatidylinositol 4-kinase type |
| | | | | | II |
| PIK3C2A | others | 5286 | 2.7.1.137 | 11p15.5-p14 | phosphoinositide-3-kinase, class 2, |
| | | | | | alpha polypeptide |
| PIK3C2B | others | 5287 | 2.7.1.137 | 1q32 | phosphoinositide-3-kinase, class 2, |
| | | | | | beta polypeptide |
| PIK3C2G | others | 5288 | 2.7.1.137 | 12p12 | phosphoinositide-3-kinase, class 2, |
| | | | | | gamma polypeptide |
| PIK3C3 | others | 5289 | — | 18q12.3 | phosphoinositide-3-kinase, class 3 |
| PIK3CA | others | 5290 | 2.7.1.137 | 3q26.3 | phosphoinositide-3-kinase, |
| | | | | | catalytic, alpha polypeptide |
| PIK3CB | others | 5291 | 2.7.1.137 | 3q22.3 | phosphoinositide-3-kinase, |
| | | | | | catalytic, beta polypeptide |
| PIK3CD | others | 5293 | — | 1p36.2 | phosphoinositide-3-kinase, |
| | | | | | catalytic, delta polypeptide |
| PIK3CG | others | 5294 | 2.7.1.137 | 7q22.3 | phosphoinositide-3-kinase, |
| | | | | | catalytic, gamma polypeptide |
| PIK3R2 | others | 5296 | — | 19q13.2-q13.4 | phosphoinositide-3-kinase, |
| | | | | | regulatory subunit 2 (p85 beta) |
| PIK4CA | others | 5297 | — | 22q11.21 | phosphatidylinositol 4-kinase, |
| | | | | | catalytic, alpha polypeptide |
| PIK4CB | others | 5298 | — | 1q21 | phosphatidylinositol 4-kinase, |
| | | | | | catalytic, beta polypeptide |
| PIP5K1A | others | 8394 | — | 1q22-q24 | phosphatidylinositol-4-phosphate |
| | | | | | 5-kinase, type I, alpha |
| PIP5K1B | others | 8395 | — | 9q13 | phosphatidylinositol-4-phosphate |
| | | | | | 5-kinase, type I, beta |
| PIP5K2A | others | 5305 | — | 10p12.32 | phosphatidylinositol-4-phosphate |
| | | | | | 5-kinase, type II, alpha |
| PIP5K2B | others | 8396 | 2.7.1.149 | 17q12 | phosphatidylinositol-4-phosphate |
| | | | | | 5-kinase, type II, beta |
| PIP5K2C | others | 79837 | — | 12q13.3 | phosphatidylinositol-4-phosphate |
| | | | | | 5-kinase, type II, gamma |
| PKD1 | others | 5310 | — | 16p13.3 | polycystic kidney disease 1 |
| | | | | | (autosomal dominant) |
| PKD2 | others | 5311 | — | 4q21-q23 | polycystic kidney disease 2 |
| | | | | | (autosomal dominant) |
| EXOSC10 | others | 5394 | — | 1p36.22 | exosome component 10 |
| PMVK | others | 10654 | 2.7.4.2 | 1p13-q23 | phosphomevalonate kinase |
| PRKAG3 | others | 53632 | — | 2q35 | protein kinase, AMP-activated, |
| | | | | | gamma 3 non-catalytic subunit |
| PRPF4 | others | 9128 | — | 9q31-q33 | PRP4 pre-mRNA processing factor |
| | | | | | 4 homolog (yeast) |
| PRPS1 | others | 5631 | 2.4.2.17 | xq21-q27 | phosphoribosyl pyrophosphate |
| | | | | | synthetase 1 |
| PRPS2 | others | 5634 | 2.4.2.17 | xp22.3-p22.2 | phosphoribosyl pyrophosphate |
| | | | | | synthetase 2 |
| PRPSAP1 | others | 5635 | — | 17q24-q25 | phosphoribosyl pyrophosphate |
| | | | | | synthetase-associated protein 1 |
| PRPSAP2 | others | 5636 | — | 17p11.2-p12 | phosphoribosyl pyrophosphate |
| | | | | | synthetase-associated protein 2 |
| LONP1 | others | 9361 | — | 19p13.2 | protease, serine, 15 |
| TWF1 | others | 5756 | — | 12q12 | PTK9 protein tyrosine kinase 9 |
| TWF2 | others | 11344 | — | 3p21.1 | PTK9L protein tyrosine kinase 9- |
| | | | | | like (A6-related protein) |
| PTPRN | others | 5798 | — | 2q35-q36.1 | protein tyrosine phosphatase, |
| | | | | | receptor type, N |
| PTPRT | others | 11122 | — | 20q12-q13 | protein tyrosine phosphatase, |
| | | | | | receptor type, T |
| RAPGEF4 | others | 11069 | — | 2q31-q32 | Rap guanine nucleotide exchange |
| | | | | | factor (GEF) 4 |
| RBM19 | others | 9904 | — | 12q24.13-q24.21 | RNA binding motif protein 19 |
| RBKS | others | 64080 | 2.7.1.15 | 2p23.3 | ribokinase |
| RCE1 | others | 9986 | — | 11q13 | RCE1 homolog, prenyl protein |
| | | | | | protease (S. cerevisiae) |
| RECQL5 | others | 9400 | — | 17q25.2-q25.3 | RecQ protein-like 5 |
| RFK | others | 55312 | — | 9q21.13 | riboflavin kinase |
| SLC6A14 | others | 11254 | — | xq23-q24 | solute carrier family 6 (amino acid |
| | | | | | transporter), member 14 |
| SPHK1 | others | 8877 | — | 17q25.2 | sphingosine kinase 1 |
| SPHK2 | others | 56848 | — | 19q13.2 | sphingosine kinase 2 |
| SEPHS1 | others | 22929 | — | 10p14 | selenophosphate synthetase 1 |
| SEPHS2 | others | 22928 | — | 16p11.2 | selenophosphate synthetase 2 |
| MAP3K7IP1 | others | 10454 | — | 22q13.1 | mitogen-activated protein kinase |
| | | | | | kinase kinase 7 interacting protein 1 |
| MAP3K7IP2 | others | 23118 | — | 6q25.1-q25.3 | mitogen-activated protein kinase |
| | | | | | kinase kinase 7 interacting protein 2 |
| TAS2R14 | others | 50840 | — | 12p13 | taste receptor, type 2, member 14 |
| TJP1 | others | 7082 | — | 15q13 | tight junction protein 1 (zona |
| | | | | | occludens 1) |
| TJP2 | others | 9414 | — | 9q13-q21 | tight junction protein 2 (zona |
| | | | | | occludens 2) |
| TJP3 | others | 27134 | — | 19p13.3 | tight junction protein 3 (zona |
| | | | | | occludens 3) |
| TK1 | others | 7083 | 2.7.1.21 | 17q23.2-q25.3 | thymidine kinase 1, soluble |
| TK2 | others | 7084 | 2.7.1.21 | 16q22-q23.1 | thymidine kinase 2, mitochondrial |
| TPK1 | others | 27010 | — | 7q34-q35 | thiamin pyrophosphokinase 1 |
| TRIP13 | others | 9319 | — | 5p15.33 | thyroid hormone receptor |
| | | | | | interactor 13 |
| UCK2 | others | 7371 | 2.7.4.— | 1q23 | uridine-cytidine kinase 2 |
| UCKL1 | others | 54963 | — | 20q13.33 | uridine-cytidine kinase 1-like 1 |
| XYLB | others | 9942 | — | 3p22-p21.3 | xylulokinase homolog (H. influenzae) |
| MAGI2 | others | 9863 | — | 7q21 | atrophin-1 interacting protein 1 |
| ADPGK | others | 83440 | — | 15q24.1 | ADP-dependent glucokinase |
| AGK | others | 55750 | 2.7.1.94 | 7q34 | multiple substrate lipid kinase |
| AK1 | others | 203 | 2.7.4.3 | 9q34.1 | adenylate kinase 1 |
| AK2 | others | 204 | 2.7.4.3 | 1p34 | adenylate kinase 2 |
| AK3 | others | 50808 | — | 9p24.1-p24.3 | adenylate kinase 3 like 1 |
| AK5 | others | 26289 | — | 1p31 | adenylate kinase 5 |
| AK7 | others | 122481 | — | 14q32.2 | adenylate kinase 7 |
| CALM2 | others | 805 | — | 2p21 | calmodulin 2 (phosphorylase |
| | | | | | kinase, delta) |
| CDK5R1 | others | 8851 | — | 17q11.2 | cyclin-dependent kinase 5, |
| | | | | | regulatory subunit 1 (p35) |
| CDK5R2 | others | 8941 | — | 2q35 | cyclin-dependent kinase 5, |
| | | | | | regulatory subunit 2 (p39) |
| CDKN3 | others | 1033 | — | 14q22 | cyclin-dependent kinase inhibitor 3 |
| | | | | | (CDK2-associated dual specificity |
| | | | | | phosphatase) |
| CERK | others | 64781 | — | 22q13.31 | ceramide kinase |
| CERKL | others | 375298 | — | 2q31.3 | ceramide kinase-like |
| CHKA | others | 1119 | 2.7.1.32 | 11q13.2 | choline kinase alpha |
| DAK | others | 26007 | — | 11q12.2 | DKFZP586B1621 protein |
| DCAKD | others | 79877 | — | 17q21.31 | hypothetical protein FLJ22955 |
| DGKK | others | 139189 | — | xp11.22 | similar to C130007D14 protein |
| DOLK | others | 22845 | — | 9q34.11 | transmembrane protein 15 |
| FASTKD1 | others | 79675 | — | 2q31 | hypothetical protein FLJ21901 |
| FASTKD2 | others | 22868 | — | 2q33.3 | KIAA0971 |
| FASTKD3 | others | 79072 | — | 5p15.3-p15.2 | hypothetical protein MGC5297 |
| FASTKD5 | others | 60493 | — | 20p13 | hypothetical protein FLJ13149 |
| FUK | others | 197258 | 2.7.1.52 | 16q22.1 | fucokinase |
| GCK | others | 2645 | 2.7.1.2, | 7p15.3-p15.1 | glucokinase (hexokinase 4, |
| | | | 2.7.1.1 | | maturity onset diabetes of the |
| | | | | | young 2) |
| HK1 | others | 3098 | 2.7.1.1 | 10q22 | hexokinase 1 |
| HK2 | others | 3099 | 2.7.1.1 | 2p13 | hexokinase 2 |
| HK3 | others | 3101 | 2.7.1.1 | 5q35.2 | hexokinase 3 (white cell) |
| HKDC1 | others | 80201 | — | 10q22.1 | hypothetical protein FLJ22761 |
| IHPK1 | others | 9807 | — | 3p21.31 | inositol hexaphosphate kinase 1 |
| IHPK3 | others | 117283 | — | 6p21.31 | inositol hexaphosphate kinase 3 |
| IPMK | others | 253430 | — | 10q21.1 | inositol polyphosphate multikinase |
| ITPK1 | others | 3705 | — | 14q31 | inositol 1,3,4-triphosphate 5/6 |
| | | | | | kinase |
| ITPKA | others | 3706 | 2.7.1.— | 15q14-q21 | inositol 1,4,5-trisphosphate 3- |
| | | | | | kinase A |
| ITPKB | others | 3707 | 2.7.1.— | 1q42.13 | inositol 1,4,5-trisphosphate 3- |
| | | | | | kinase B |
| ITPKC | others | 80271 | — | 19q13.1 | inositol 1,4,5-trisphosphate 3- |
| | | | | | kinase C |
| NADK | others | 65220 | — | 1p36.33-p36.21 | NAD kinase |
| PHKB | others | 5257 | 2.7.1.38 | 16q12-q13 | phosphorylase kinase, beta |
| PIP5K1C | others | 23396 | — | 19p13.3 | phosphatidylinositol-4-phosphate |
| | | | | | 5-kinase, type I, gamma |
| PIP5KL1 | others | 138429 | — | 9q34.11 | phosphatidylinositol-4-phosphate |
| | | | | | 5-kinase-like 1 |
| PKLR | others | 5313 | 2.7.1.40 | 1q21 | pyruvate kinase, liver and RBC |
| PKM2 | others | 5315 | 2.7.1.40 | 15q22 | pyruvate kinase, muscle |
| PLAU | others | 5328 | 3.4.21.31 | 10q24 | plasminogen activator, urokinase |
| PSTK | others | 118672 | — | 10q26.13 | chromosome 10 open reading |
| | | | | | frame 89 |
| UCK1 | others | 83549 | 2.7.1.48 | 9q34.13 | uridine-cytidine kinase 1 |
| CALM1 | others | 801 | 2.7.1.38 | 14q24-q31 | calmodulin 1 (phosphorylase |
| | | | | | kinase, delta) |
| CALM3 | others | 808 | — | 19q13.2-q13.3 | calmodulin 3 (phosphorylase |
| | | | | | kinase, delta) |
| CSNK2B | others | 1460 | 2.7.1.37 | 6p21.3 | casein kinase 2, beta polypeptide |
| GALK1 | others | 2584 | 2.7.1.6 | 17q24 | galactokinase 1 |
| KHK | others | 3795 | 2.7.1.3 | 2p23.3-p23.2 | ketohexokinase (fructokinase) |
| MAGI3 | others | 260425 | — | 1p12-p11.2 | membrane-associated guanylate |
| | | | | | kinase-related (MAGI-3) |
| PFKFB1 | others | 5207 | 2.7.1.105, | xp11.21 | 6-phosphofructo-2-kinase/fructose- |
| | | | 3.1.—.— | | 2,6-biphosphatase 1 |
| PFKFB2 | others | 5208 | 2.7.1.105, | 1q31 | 6-phosphofructo-2-kinase/fructose- |
| | | | 3.1.—.— | | 2,6-biphosphatase 2 |
| PFKFB3 | others | 5209 | — | 10p14-p15 | 6-phosphofructo-2-kinase/fructose- |
| | | | | | 2,6-biphosphatase 3 |
| PFKFB4 | others | 5210 | — | 3p22-p21 | 6-phosphofructo-2-kinase/fructose- |
| | | | | | 2,6-biphosphatase 4 |
| PGK1 | others | 5230 | 2.7.2.3 | xq13 | phosphoglycerate kinase 1 |
| PGK2 | others | 5232 | — | 6p12.3 | phosphoglycerate kinase 2 |
| PHKA1 | others | 5255 | 2.7.1.38 | xq12-q13 | phosphorylase kinase, alpha 1 |
| | | | | | (muscle) |
| PHKA2 | others | 5256 | 2.7.1.38 | xp22.2-p22.1 | phosphorylase kinase, alpha 2 |
| | | | | | (liver) |
| PRKAB1 | others | 5564 | — | 12q24.1 | protein kinase, AMP-activated, |
| | | | | | beta 1 non-catalytic subunit |
| PRKAB2 | others | 5565 | — | 1q21.1 | protein kinase, AMP-activated, |
| | | | | | beta 2 non-catalytic subunit |
| PRKAG1 | others | 5571 | — | 12q12-q14 | protein kinase, AMP-activated, |
| | | | | | gamma 1 non-catalytic subunit |
| PRKAG2 | others | 51422 | — | 7q35-q36 | protein kinase, AMP-activated, |
| | | | | | gamma 2 non-catalytic subunit |
| PRKAR1A | others | 5573 | 2.7.1.37 | 17q23-q24 | protein kinase, cAMP-dependent, |
| | | | | | regulatory, type I, alpha (tissue |
| | | | | | specific extinguisher 1) |
| PRKAR2A | others | 5576 | 2.7.1.37 | 3p21.3-p21.2 | protein kinase, cAMP-dependent, |
| | | | | | regulatory, type II, alpha |
| PRKAR2B | others | 5577 | 2.7.1.37 | 7q22 | protein kinase, cAMP-dependent, |
| | | | | | regulatory, type II, beta |
| PRKRA | others | 11108 | — | 12q23-q24.1 | PR domain containing 4 |
| PRKRIR | others | 5612 | — | 11q13.5 | protein-kinase, interferon-inducible |
| | | | | | double stranded RNA dependent |
| | | | | | inhibitor, repressor of (P58 |
| | | | | | repressor) |
| CDC2L2 | others | 728642 | — | 1p36.33 | cell division cycle 2-like 2 |
| | | | | | (PITSLRE proteins) |
| PIP5K3 | others | 200576 | — | 2q33.3 | phosphatidylinositol-3- |
| | | | | | phosphate/phosphatidylinositol 5- |
| | | | | | kinase, type III |
| PRKAR1B | others | 645590 | — | — | similar to cAMP-dependent protein |
| | | | | | kinase type I-beta regulatory |
| | | | | | subunit |
| CKS1A | others | 137529 | — | 8q21.13 | CDC28 protein kinase regulatory |
| | | | | | subunit 1A |
| FCGR3A | others | 2214 | — | 1q23 | Fc fragment of IgG, low affinity |
| | | | | | IIIa, receptor (CD16a) |
| BCAT2 | others | 587 | 2.6.1.26 | 19q13 | branched chain aminotransferase 2, |
| | | | | | mitochondrial |
| CCNA2 | others | 890 | — | 4q25-q31 | cyclin A2 |
| CCNE1 | others | 898 | — | 19q12 | cyclin E1 |
| GCKR | others | 2646 | — | 2p13 | glucokinase (hexokinase 4) |
| | | | | | regulator |
| CCND2 | others | 894 | — | 12p13 | cyclin D2 |
| MNAT1 | others | 4331 | — | 14q23 | menage a trois 1 (CAK assembly |
| | | | | | factor) |
| RAD17 | others | 5884 | — | 5q13 | RAD17 homolog (S. pombe) |
| SHB | others | 6461 | — | 9p12-p11 | SHB (Src homology 2 domain |
| | | | | | containing) adaptor protein B |
| SHC1 | others | 6464 | — | 1q21 | SHC (Src homology 2 domain |
| | | | | | containing) transforming protein 1 |
| SLPI | others | 6590 | — | 20q12 | secretory leukocyte protease |
| | | | | | inhibitor (antileukoproteinase) |
| CAD | others | 790 | 2.1.3.2, | 2p22-p21 | carbamoyl-phosphate synthetase 2, |
| | | | 3.5.2.— | | aspartate transcarbamylase, and |
| | | | | | dihydroorotase |
| MYT1 | others | 4661 | — | 20q13.33 | myelin transcription factor 1 |
| CRK | others | 1398 | — | 17p13.3 | v-crk sarcoma virus CT10 |
| | | | | | oncogene homolog (avian) |
| GTH2H1 | others | 2965 | — | 11p15.1-p14 | general transcription factor IIH, |
| | | | | | polypeptide 1, 62 kDa |
| ZRANB2 | others | 9406 | — | 1p31 | zinc finger protein 265 |
| BACE2 | others | 25825 | — | 21q22.3 | beta-site APP-cleaving enzyme 2 |
| CCNB1 | others | 891 | — | 5q12 | cyclin B1 |
| OSR1 | others | 130497 | — | 2p24.1 | odd-skipped related 1 (Drosophila) |
| MAPKNS | others | AAA74301 | — | — | MAP kinase |
| AAA36585 | others | AAA36585 | — | — | rac protein kinase-beta |
| AAB05036 | others | AAB05036 | — | — | p38B MAP kinase |
| AAC16273 | others | AAC16273 | — | — | mitogen-activated protein kinase |
| | | | | | kinase 7b |
| AAC24716 | others | AAC24716 | — | — | p21 activated kinase 1B |
| AAC98920 | others | AAC98920 | — | — | cell cycle related kinase |
| AAH13051 | others | AAH13051 | — | — | LIM domain kinase 2 |
| AAO12758 | others | AAO12758 | — | — | casein kinase I gamma 1 isoform |
| BAB62909 | others | BAB62909 | — | — | testicular protein kinase 2 |
| BAD18671 | others | BAD18671 | — | — | — |
| NME1- | others | 654364 | — | 17q21.3 | NME1-NME2 |
| NME2 | | | | | |
| PTPN11 | others | 5781 | — | 12q24 | protein tyrosine phosphatase, non- |
| | | | | | receptor type 11 (Noonan |
| | | | | | syndrome 1) |
| TSSK1A | others | 23752 | — | 22q11.21 | serine/threonine kinase 22A |
| | | | | | (spermiogenesis associated) |

The preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

That which is claimed is:

1. An apparatus configured for analysis of a sample, the apparatus comprising:
a chamber configured to receive the sample via an inlet port, and to discharge the sample via an outlet port, wherein the inlet and outlet ports are positioned on a first side of the chamber;
a plurality of enzymatic substrate extensions coupled to a surface on the first side of the chamber, the surface having a nanoparticle structure;
an illuminator positioned on a second side of the chamber, the second side being opposite the first side, the illuminator being positioned to provide an excitation beam to a selected one of the plurality of enzymatic substrate extensions; and
an analysis module configured to receive a reflected beam from the selected enzymatic substrate extension, and to determine therefrom whether a modification of the selected enzymatic substrate extension by the sample has occurred.

2. The apparatus of claim 1, further comprising a step control motor configured to position the illuminator and the analysis module relative to the selected enzymatic substrate extension.

3. The apparatus of claim 1, wherein the analysis module comprises a mirror and a spectrometer.

4. The apparatus of claim 3, wherein a waveform peak in the spectrometer indicates modification of the selected enzymatic substrate extension by the sample.

5. The apparatus of claim 1, wherein the nanoparticle structure comprises a metal deposited on a nanopyramid array.

6. The apparatus of claim 1, wherein the excitation beam comprises a laser.

7. The apparatus of claim 1, wherein the analysis module comprises a digital light processor (DLP).

8. The apparatus of claim 1, wherein at least one of the plurality of enzymatic substrate extensions comprises a polypeptide.

9. The apparatus of claim 1, wherein at least one of the plurality of enzymatic substrate extensions comprises a nucleic acid.

10. The apparatus of claim 1, wherein at least one of the plurality of enzymatic substrate extensions comprises a polysaccharide.

11. The apparatus of claim 1, wherein the modification comprises a phosphorylation event between the selected enzymatic substrate extension and the enzyme from the sample.

12. The apparatus of claim 1, wherein the modification comprises a dephosphorylation event between the selected enzymatic substrate extension and the enzyme from the sample.

13. The apparatus of claim 1, wherein the modification comprises a cleavage event between the selected enzymatic substrate extension and the enzyme from the sample.

14. A method of making a microfluidic optical device, comprising:
depositing polycrystalline silicon layers on each side of a silicon wafer;
forming via-holes through the silicon wafer;
patterning a frontside of the silicon wafer;
etching silicon nanostructures in areas formed by the patterning of the frontside;
depositing metal in areas formed by the etched silicon nanostructures;
removing remaining photoresist and annealing the deposited metal; and
integrating a chip separated from the silicon wafer with handling units and a transparent window coupled to a chamber in the microfluidic optical device.

15. The method of claim 14, wherein the forming of the via-holes comprises using chemical etching.

16. The method of claim 14, wherein the forming of the via-holes comprises using laser drilling.

17. The method of claim 14, wherein the integrating of the chip comprises coupling inlet and outlet ports to the via-hole formation.

18. A method of characterizing a liquid sample, comprising:
receiving the liquid sample via an inlet port, and discharging the sample via an outlet port, wherein the inlet and outlet ports are positioned on a first side of the chamber;
providing an excitation beam to a selected one of a plurality of enzymatic substrate extensions, the enzymatic substrate extensions being coupled to a surface on the first side of the chamber, the surface having a nanoparticle structure;
receiving a reflected beam from the selected enzymatic substrate extension in an analysis module; and
determining from the received reflected beam whether a modification of the selected enzymatic substrate extension by the sample has occurred.

19. The method of claim 18, further comprising adjusting a voltage proximate to the selected enzymatic substrate extension.

20. The method of claim 18, further comprising positioning the analysis module relative to the selected enzymatic substrate extension.

21. A method for determining the activity of a target biomolecule using a surface enhanced Raman spectroscopy (SERS) system, comprising:
introducing a fluid sample into a microfluidic optical chamber wherein said optical chamber comprises a Raman active surface with a plurality of substrates extending therefrom;
allowing for specific interaction between a biomolecule in the fluid sample and a plurality of said substrates;
directing a laser at the fluid sample, wherein the interaction of the laser with the fluid sample produces a SERS signal that is specific for the interaction between the biomolecule and the substrate; and
detecting the activity of the biomolecule by detecting a change in the Raman scattering spectrum of the biomolecule as compared to the Raman scattering spectrum of a control sample.

22. The method of claim 21 wherein the target biomolecule is a protein.

23. The method of claim 21 wherein the target biomolecule is an enzyme.

24. The method of claim 21 wherein the target biomolecule is a kinase.

25. The method of claim 21 wherein the target biomolecule is an antibody.

26. The method of claim 21 wherein the target biomolecule is a substrate for an enzymatic reaction.

27. The method of claim 21 wherein the target biomolecule is a DNA binding protein and the substrate is a nucleic acid.

28. The method of claim 21 wherein the interaction between the target biomolecule the plurality of substrates is a protein-ligand binding interaction.

29. The method of claim 21 wherein the interaction between the target biomolecule the plurality of substrates is a protein-protein binding interaction.
